(19) United States
(12) Patent Application Publication
(10) Pub. No.: US 2007/0099096 A1
(43) Pub. Date: May 3, 2007

(54) Dye-containing curable composition, color filter and method of producing thereof

(75) Inventors: Tomoya Sasaki, Shizuoka-ken (JP); Hideki Takakuwa, Shizuoka-ken (JP); Kazuto Shimada, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation

(21) Appl. No.: 11/589,235

(22) Filed: Oct. 30, 2006

(30) Foreign Application Priority Data
Nov. 1, 2005 (JP) 2005-318445

(51) Int. Cl. G03F 1/00

(52) U.S. Cl. 430/7

(57) ABSTRACT

A dye-containing curable composition comprising at least (A) an organic solvent-soluble dye, (B) a radiation-sensitive compound, (C) a transition metal complex, wherein the maximum value of the molar absorption coefficient ε in the visible light range is lower than the molar absorption coefficient ε of the organic solvent-soluble dye, and (D) other than the (A) to (C), a compound containing at least two functional groups having an unshared electron pair per molecule.

### CROSS-REFERENCE TO RELATED APPLICATION

This application claims priority under 35 USC 119 from Japanese Patent Application, No. 2005-318445, the disclosures of which are incorporated by reference herein.

### BACKGROUND OF THE INVENTION

(i) Field of the Invention

The present invention relates to a dye-containing curable composition constituting a color filter used for liquid crystal display elements and solid state image pick-up elements and suitable for forming colored images, as well as to a color filter using the dye-containing curable composition and a process of preparing the color filter.

(ii) Description of the Related Art

As processes for preparing a color filter used for liquid crystal display elements and solid state image pick-up elements, a staining process, a printing process, an electrodeposition process and a pigment dispersion process are known.

In the pigment dispersion process, the color filter is prepared by a photolithographic process using a colored radiation-sensitive composition prepared by dispersing a pigment in a photosensitive composition. The color filter prepared by this process is stable with respect to light, heat and the like since pigments are used. A sufficient degree of positional accuracy can be obtained in this process since the pigment is patterned by the photolithographic process, and this process has been widely used as a process suitable for preparing the color filter for a large screen and high accuracy color display.

In preparing a color filter by the pigment dispersion process, the radiation-sensitive composition is first coated on a substrate with a spin coater or roll coater and dried to form a coating film. Then, colored pixels are obtained by patterned-exposure and development of the coating film. The color filter can be prepared by repeating this operation a number of times corresponding to the number of hues.

As the pigment dispersion process, a negative photosensitive composition in which photopolymerizable monomer and photopolymerization initiator are combined with alkali soluble resin is described (e.g., see Japanese Patent Application Laid-Open (JP-A) Nos. 1-102469, 2-181704, 2-199403, 4-76062, 5-273411, 6-184482 and 7-140654). Recently, in the color filter for solid state image pick-up elements, even higher resolution is desired, but the conventional pigment dispersions have difficulties in further improving the resolution. Because of the problem such as generation of color irregularities due to coarse particles of the pigment, it is not suitable for the use which requires fine patterns such as solid state image pick-up elements.

Due to those problems, a technique of using a dye instead of the conventional pigment has been suggested. However, there is a problem that the composition containing a dye has low light-fastness as compared with a pigment, in general. In order to improve the light-fastness, techniques in which an alcohol-soluble metal compounds such as Ni or Co are added to vitreous color filter and a metal complex is added to a triphenylmethane-based dye in a resin pattern are suggested (e.g., see Japanese Patent No. 2986796 and JP-A No. 11-223720).

### SUMMARY OF THE INVENTION

However, the above-described techniques relate to techniques which do not require alkali development. The light-fastness of the dye has tendency to decrease in the process of exposure/alkali development/post-heating, as compared with the case where this process is not necessary. Therefore, an addition technique which has an excellent light-fastness even after the alkali development is demanded.

On the other hand, when a metal complex is added, the stability of a photosensitive composition is over time reduced. Moreover, there is a problem that change in the performances such as change in the sensitivity or change in the pattern size occurs.

The invention provides a dye-containing curable composition having good stability over time and reduced rate of the pattern linewidth variation with fluctuation of exposure amounts, a color filter with excellent color hue and resolution, and a method of producing a color filter which has a reduced rate of pattern linewidth variation over time or fluctuation with the exposure amounts and which has good color hue and resolution.

A first aspect of the invention provides a dye-containing curable composition comprising at least the following components (A) to (D).

(A) an organic solvent-soluble dye;

(B) a radiation-sensitive compound;

(C) a transition metal complex, wherein in the visible light range the maximum value of the molar absorption coefficient ε is lower than the maximum value of molar absorption coefficient ε of the organic solvent-soluble dye; and

(D) a compound other than the (A) to (C), containing at least two functional groups having an unshared electron pair per molecule.

A second aspect of the invention provides a color filter which uses the dye-containing curable composition comprising the following components (A) to (D).

(A) an organic solvent-soluble dye;

(B) a radiation-sensitive compound;

(C) a transition metal complex, wherein in the visible light range the maximum value of the molar absorption coefficient ε is lower than the maximum value of molar absorption coefficient ε of the organic solvent-soluble dye; and

(D) a compound other than the (A) to (C), containing at least two functional groups having an unshared electron pair per molecule.

A third aspect of the invention provides a method of producing a color filter comprising: coating the dye-containing curable composition comprising the following components (A) to (D) on a support; then exposing through a mask; and developing to form a pattern image.

(A) an organic solvent-soluble dye;

(B) a radiation-sensitive compound;

(C) a transition metal complex, wherein in the visible light range the maximum value of the molar absorption coefficient ε is lower than the maximum value of molar absorption coefficient ε of the organic solvent-soluble dye; and

(D) a compound other than the (A) to (C), containing at least two functional groups having an unshared electron pair per molecule.

### DETAILED DESCRIPTION OF THE INVENTION

Hereinbelow, the dye-containing curable composition, the color filter and the method of producing thereof of the invention will be described in detail.

<<Dye-containing curable composition>>

The dye-containing curable composition of the invention comprises at least (A) an organic solvent-soluble dye, (B) a radiation-sensitive compound, (C) a transition metal complex, wherein in the visible light range the maximum value of the molar absorption coefficient ε is lower than the maximum value of molar absorption coefficient ε of the organic solvent-soluble dye, and (D) a compound other than the (A) to (C), containing at least two functional groups having an unshared electron pair per molecule. The dye-containing curable composition of the invention typically contains an organic solvent.

The dye-containing curable composition of the invention can contain a photopolymerization initiator and/or a photo-acid generator as a preferred (B) radiation-sensitive compound when composing a negative working composition. Moreover, when composing a positive working composition, the dye-containing curable composition of the invention can contain a photo-acid generator or an o-quinonediazide compound. The dye-containing curable composition of the invention can further contain (E) an alkali-soluble binder or other components such as a monomer and a cross-linking agent. Even when composing a positive working composition, the dye-containing curable composition of the invention can contain the monomer or the photopolymerization initiator, if necessary.

(A) organic solvent-soluble dye

The dye-containing curable composition of the invention comprises at least one kind selected from the organic solvent-soluble dyes (simply referred to as “dye” hereinafter). The organic solvent-soluble dyes are not particularly restricted, and dyes which have been known for color filter dyes can be used.

The dyes available include dyes described in JP-A Nos. 64-90403, 64-91102, 1-94301, 6-11614, 5-333207, 6-35183, 6-51115 and 6-194828; Japanese Patent No. 2592207; and U.S. Pat. Nos. 4,808,501, 5,667,920 and 5,059,500.

As the chemical structure, dyes based on azos such as pyrazole azo, anilinoazo, pyrazolqtriazole azo and pyridone azo, triphenylmethane, anthraquinone, benzylidene, oxonol, phenothiazine, pyrrolopyrazole azomethine, xanthene, phthalocyanine, benzopyran, indigo, anthrapyridone, and the like can be used. Dyes based on azos such as pyrazole azo, anilinoazo, pyrazolotriazole azo and pyridone azo, pyrrolopyrazole azomethine, anthraquinone, anthrapyridone and phthalocyanine are particularly preferred.

When the composition is formulated as a resist system for developing with water or an alkali, at least one kind selected from acid dyes and derivatives thereof may be suitably used from the viewpoint of completely removing the binder and dye by development. Otherwise, it is preferable to use at least one of the dye appropriately selected from direct dyes, basic dyes, mordant dyes, acid mordant dyes, azoic dyes, disperse dyes, oil soluble dyes and food dyes, and derivatives thereof.

The acid dye and derivatives thereof will be described below. The acid dye is not particularly restricted, so long as it is a dye having acidic groups such as sulfonic acid, carboxylic acid and phenolic hydroxyl groups. However, the acid dye should be soluble in the organic solvent and developer used for preparation and development of the composition, be able to form salts with basic compounds, interact with other component in the curable composition, and have enough light absorbance, light fastness and heat resistance. Therefore, the acid dye is selected by taking all these characteristics into consideration.

While specific examples of the acid dye are described below, the invention is not restricted to these examples. They are the following dyes, and derivatives of these dyes:

acid alizarin violet N;

acid black 1, 2, 24, 48;

acid blue 1, 7, 9, 15, 18, 23, 25, 27, 29, 40, 42, 45, 51, 62, 70, 74, 80, 83, 86, 87, 90, 92, 96, 103, 108, 112, 113, 120, 129, 138, 147, 150, 158, 171, 182, 192, 210, 242, 243, 249, 256, 259, 267, 278, 280, 285, 290, 296, 315, 324:1, 335, 340;

acid chrome violet K;

acid Fuchsin;

acid green 1, 3, 5, 9, 16, 25, 27, 50, 58, 63, 65, 80, 104, 105, 106, 109;

acid orange 6, 7, 8, 10, 12, 26, 50, 51, 52, 56, 62, 63, 64, 74, 75, 94, 95107, 108, 169, 173;

acid red 1,4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 182, 183, 198, 206, 211, 215, 216, 217, 227, 228, 249, 252, 257, 258, 260, 261, 266, 268, 270, 274, 277, 280, 281, 195, 308, 312, 315, 316, 339, 341, 345, 346, 349, 382, 383, 394, 401, 412, 417, 418, 422, 426;

acid violet 6B, 7, 9, 17, 19, 49;

acid yellow 1, 3, 7, 9, 11, 17, 23, 25, 29, 34, 36, 38, 40, 42, 54, 65, 72, 73, 76, 79, 98, 99, 111, 112, 113, 114, 116, 119, 123, 128, 134, 135, 138, 139, 140, 144, 150, 155, 157, 160, 161, 163, 168, 169, 172, 177, 178, 179, 184, 190, 193, 196, 197, 199, 202, 203, 204, 205, 207, 212, 214, 220, 221, 228, 230, 232, 235, 238, 240, 242, 243, 251;

Direct Yellow 2, 33, 34, 35, 38, 39, 43, 47, 50, 54, 58, 68, 69, 70, 71, 86, 93, 94, 95, 98, 102, 108, 109, 129, 136, 138, 141;

Direct Orange 34, 39, 41, 46, 50, 52, 56, 57, 61, 64, 65, 68, 70, 96, 97, 106, 107;

Direct Red 79, 82, 83, 84, 91, 92, 96, 97, 98, 99, 105, 106, 107, 172, 173, 176, 177, 179, 181, 182, 184, 204, 207, 211, 213, 218, 220, 221, 222, 232, 233, 234, 241, 243, 246, 250;

Direct Violet 47, 52, 54, 59, 60, 65, 66, 79, 80, 81, 82, 84, 89, 90, 93, 95, 96, 103, 104;

Direct Blue 57, 77, 80, 81, 84, 85, 86, 90, 93, 94, 95, 97, 98, 99, 100, 101, 106, 107, 108, 109, 113, 114, 115, 117, 119, 137, 149, 150, 153, 155, 156, 158, 159, 160, 161, 162, 163, 164, 166, 167, 170, 171, 172, 173, 188, 189, 190, 192, 193, 194, 196, 198, 199, 200, 207, 209, 210, 212, 213, 214, 222, 228, 229, 237, 238, 242, 243, 244, 245, 247, 248, 250, 251, 252, 256, 257, 259, 260, 268, 274, 275, 293;

Direct Green 25, 27, 31, 32, 34, 37, 63, 65, 66, 67, 68, 69, 72, 77, 79, 82;

Mordant Yellow 5, 8, 10, 16, 20, 26, 30, 31, 33, 42, 43, 45, 56, 50, 61, 62, 65;

Mordant Orange 3, 4, 5, 8, 12, 13, 14, 20, 21, 23, 24, 28, 29, 32, 34, 35, 36, 37, 42, 43, 47, 48;

Mordant Red 1, 2, 3, 4, 9, 11, 12, 14, 17, 18, 19, 22, 23, 24, 25, 26, 30, 32, 33, 36, 37, 38, 39, 41, 43, 45, 46, 48, 53, 56, 63, 71, 74, 85, 86, 88, 90, 94, 95;

Mordant Violet 1, 2, 4, 5, 7, 14, 22, 24, 30, 31, 32, 37, 40, 41, 44, 45, 47, 48, 53, 58;

Mordant Blue 1, 2, 3, 7, 8, 9, 12, 13, 15, 16, 19, 20, 21, 22, 23, 24, 26, 30, 31, 32, 39, 40, 41, 43, 44, 48, 49, 53, 61, 74, 77, 83, 84;

Mordant Green 1, 3, 4, 5, 10, 15, 19, 26, 29, 33, 34, 35, 41, 43, 53;

Food Yellow 3;

Solvent Yellow 14, 23, 38, 62, 63, 64, 68, 78, 82, 89, 90, 91, 92, 94, 98, 99, 104, 105, 106, 126, 128, 129, 130, 132, 133, 134, 138, 139, 140, 144, 145, 156, 160, 161, 162, 163, 164, 165, 168, 169, 170, 171;

Solvent Red 9, 37, 39, 49, 85, 90, 91, 92, 111, 112, 113, 135, 136, 143, 144, 146, 147, 148, 151, 152, 179, 180, 181, 184, 194, 195, 202, 203, 207, 208, 212, 213, 214, 220, 225, 226, 227, 228, 230;

Solvent Violet 5, 22, 30, 31, 33, 36, 37, 39, 40, 46, 49;

Solvent Blue 25, 26, 35, 36, 37, 38, 45, 55, 59, 65, 67, 75, 82, 84, 90, 93, 94, 95, 97, 104, 105, 108, 109, 110, 119, 122, 130, 131, 132, 133;

Solvent Green 19, 20, 24, 25, 26, 28, 29

Solvent Orange 2, 7, 11, 15, 26, 56; ,and derivatives thereof.

Among these, acid black 24; acid blue 23, 25, 29, 62, 80, 86, 87, 92, 138, 158, 182, 243, 324:1; acid orange 8, 51, 56, 74, 63, 74; acid red 1, 4, 8, 34, 37, 42, 52, 57, 80, 97, 114, 143, 145, 151, 183, 217, 249; acid violet 7; acid yellow 17, 25, 29, 34, 42, 72, 76, 99, 111, 112, 114, 116, 134, 155, 169, 172, 184, 220, 228, 230, 232, 243; acid green 25; and derivatives thereof are preferred.

Acid dyes based on azos, xanthenes, phthalocyanines other than those described above are preferred. Examples of these dyes include acid dyes such as C.I. solvent blue 44 and 38, C. I. Solvent orange 45, rhodamine B, rhodamine 110, 3-[(5-chloro-2-phenoxyphenyl)hydrazono]-3,4-dihydro-4-oxo-5-[(phenylsulfonyl)amino]-2,7-Naphthalenedisulfonic acid, and derivatives of these dyes.

The acid dyes may be used as derivatives when the acid dye is incorporated into the composition as a constituent so that the dye has a sufficient solubility in the organic solvent used for preparation.

The derivatives of the acid dye available include inorganic salts of the acid dye having acidic groups such as sulfonic acid and carboxylic acid groups, salts of the acid dye with nitrogen containing compounds, and sulfonamides of the acid dye. The derivative is not particularly restricted so long as it is soluble in a solution of the dye-containing curable composition prepared. However, the derivatives of the acid dye should be soluble in the organic solvent and developer used for preparation and development of the composition, and interact with other component in the dye-containing curable composition, and have enough light absorbance, light fastness and heat resistance. Therefore, the acid dye is selected by taking all these characteristics into consideration.

The salt of the acid dye with the nitrogen-containing compound will be described below. Forming a salt between the acid dye and nitrogen-containing compound may be effective for improving solubility (solubility in organic solvents) of the acid dye, heat resistance and light fastness.

The nitrogen containing compound that forms a salt with the acid dye, and the nitrogen containing compound that forms an amide bond with the acid dye to afford a sulfonamide of the acid dye will be described below.

The nitrogen containing compound is selected considering all the characteristics such as solubility of the salt or amide compound in the organic solvent or the developer used for preparation and development, salt forming ability, light absorbance, color value of the dye, interaction between the nitrogen containing compound and other components in the dye-containing curable composition, and heat resistance and light fastness as a coloring agent. The molecular weight of the nitrogen-containing compound is preferably as small as possible when the compound is selected considering only the light absorbance and color value. The molecular weight is preferably 300 or less, more preferably 280 or less, and particularly preferably 250 or less.

While specific examples of the nitrogen-containing compound are listed below, the invention is not restricted to these examples. The compounds having no —NH—groups are not the nitrogen containing-compound that forms an amide bond in the compounds listed below.

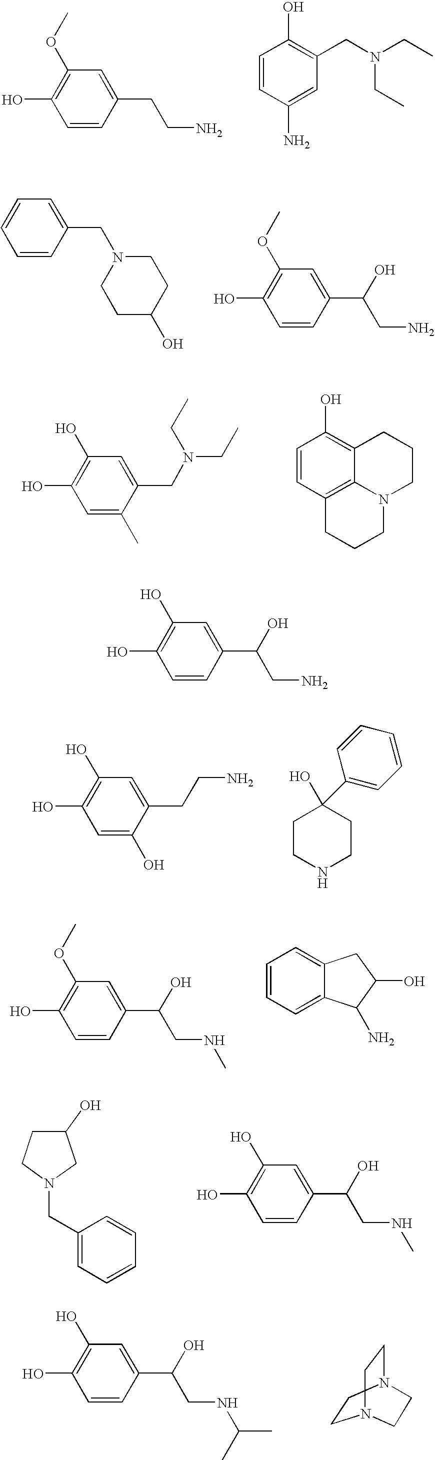

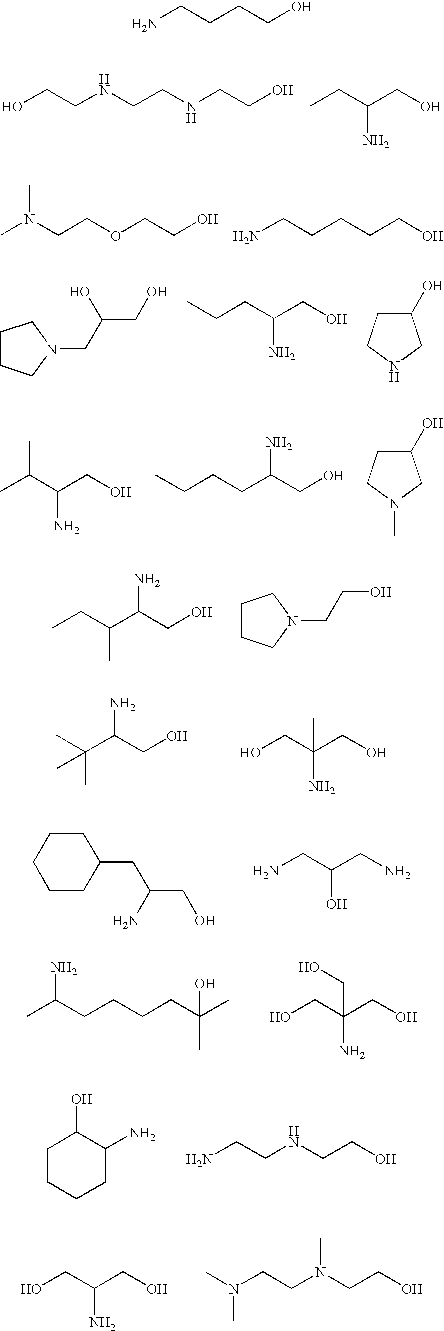

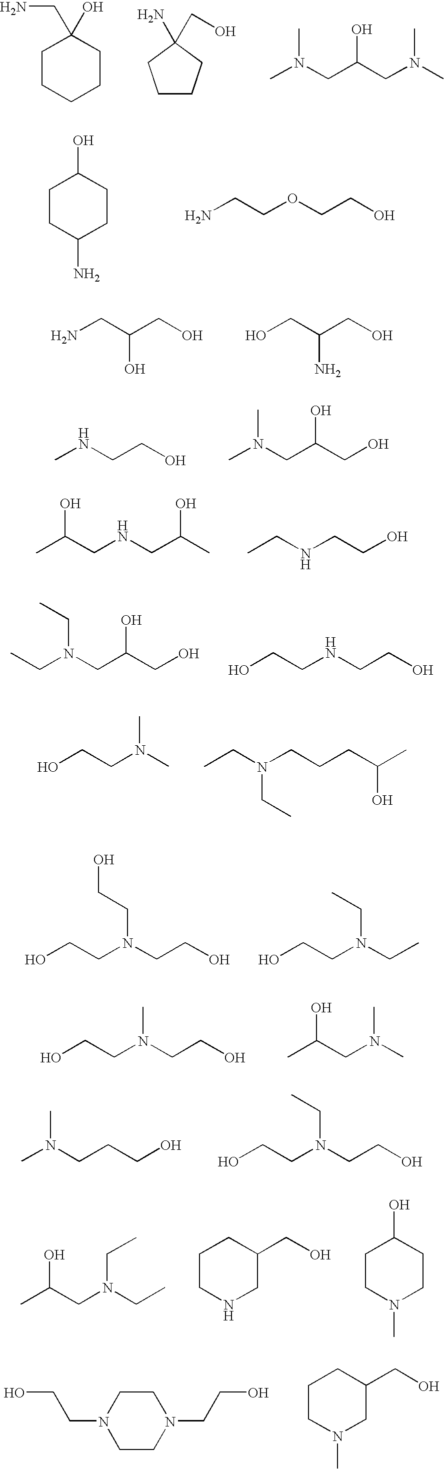

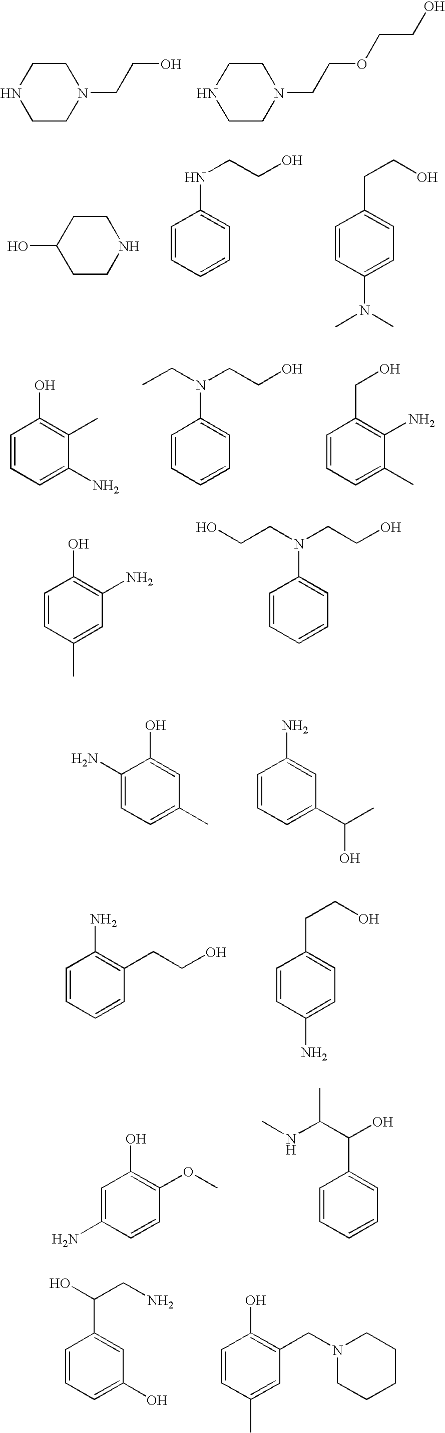

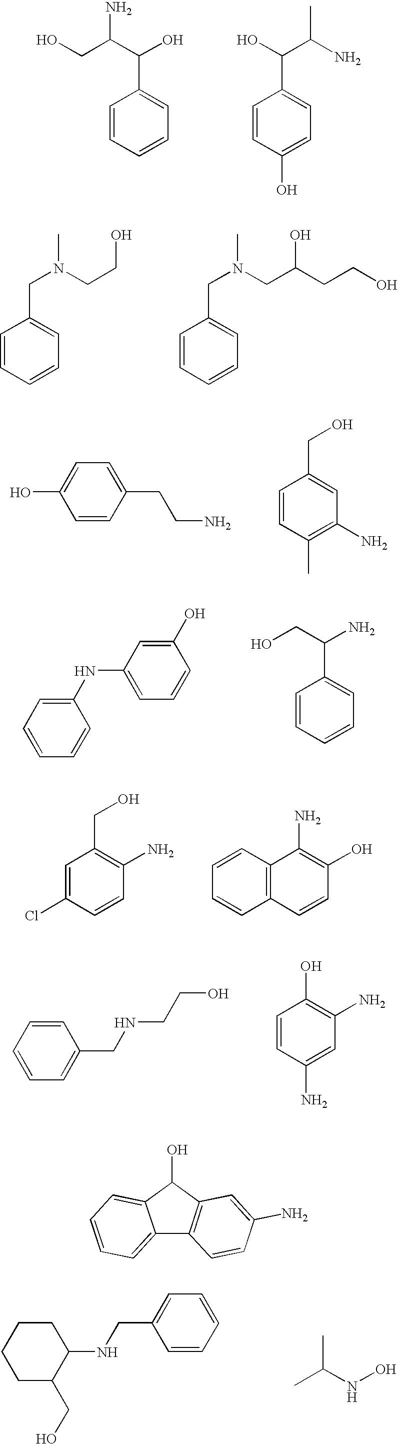

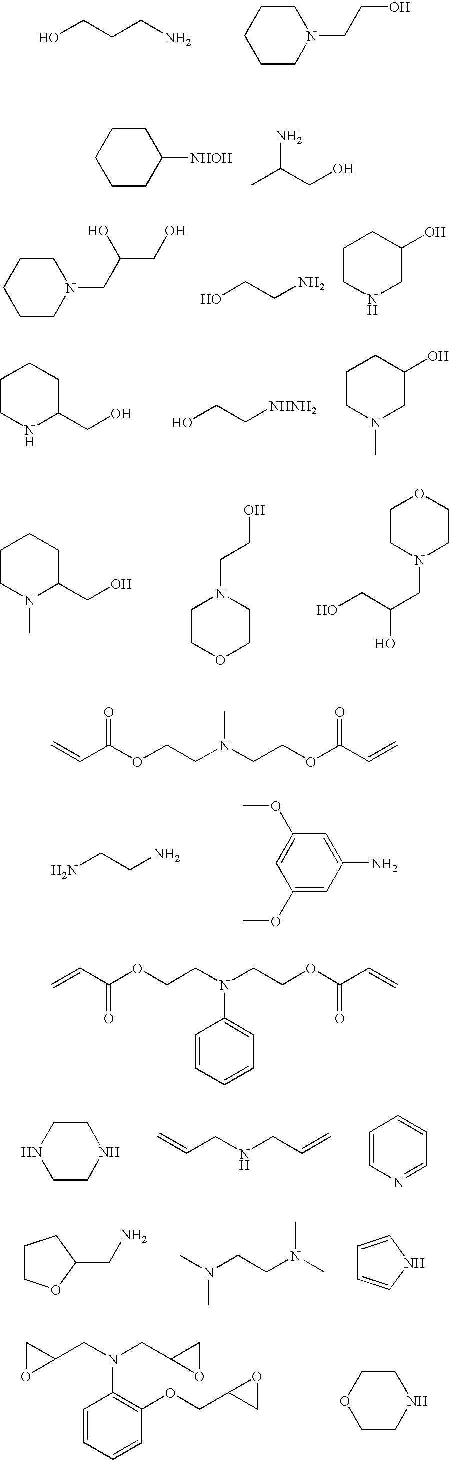

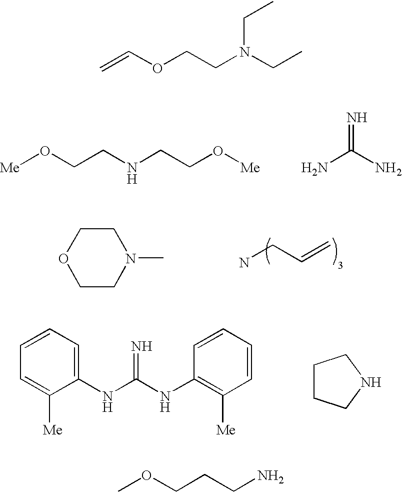

The molar ratio (abbreviated as “n” hereinafter) of the nitrogen-containing compound to the acid dye in the salt between the acid dye and nitrogen containing compound will be described below. The molar ratio n denotes the ratio of the acid dye molecule to an amine compound as a counter ion. The molar ratio n may be freely selected depending on the salt forming condition between the acid dye and amine compound. For example, n is a value satisfying the relation of 0<n<10 of the number of the functional groups in the acid of the acid dye in most practical cases, and may be selected considering all the required characteristics such as solubility in the organic solvent used and developer, salt forming ability, light absorbance, interaction with other components in the dye-containing curable composition, and light fastness and heat resistance. When n is selected considering only the light absorbance, it satisfies the relation of preferably 0<n≦4.5, more preferably 0<n≦4, and particularly 0<n≦3.5.

The organic solvent-soluble dye in the invention containing at least one of phthalocyanine-based dye (phthalocyanine dye) is particularly preferred. Examples of the phthalocyanine dye include dyes described in JP-A Nos. 5-333207, 6-51115 and 6-194828.

Among these, particularly preferable examples of the phthalocyanine dye include a dye compound represented by the following formula (I) or a dye compound represented by the following formula (II).

Dye Compound Represented by the Formula (I)

The dye compound represented by the following formula (I) is an organic solvent-soluble phthalocyanine dye having good molar absorption coefficient ε and color value. Such a dye is a compound which provides a high light-fastness and high heat resistance at the same time.

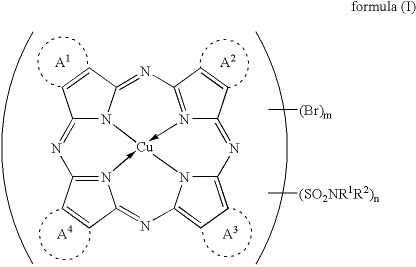

In the formula (I), ring A¹, ring A², ring A³ and ring A⁴ each independently represent the following aromatic ring. The aromatic ring has many isomers depending on the condensed ring direction of the aromatic ring and the substitution position of a substituent bound thereto.

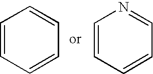

Further, at least one of ring A¹, ring A², ring A³ and ring A⁴ represents the following aromatic ring.

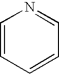

Specific examples of the base skeleton of the formula (I) include five kinds of structures in the following formulas (1) to (5). Depending on the difference in the condensation direction of a pyridine ring, there are isomers with the N position in different positions. Further, there are also respective isomers in which the substitution position of a substituent such as bromine is different.

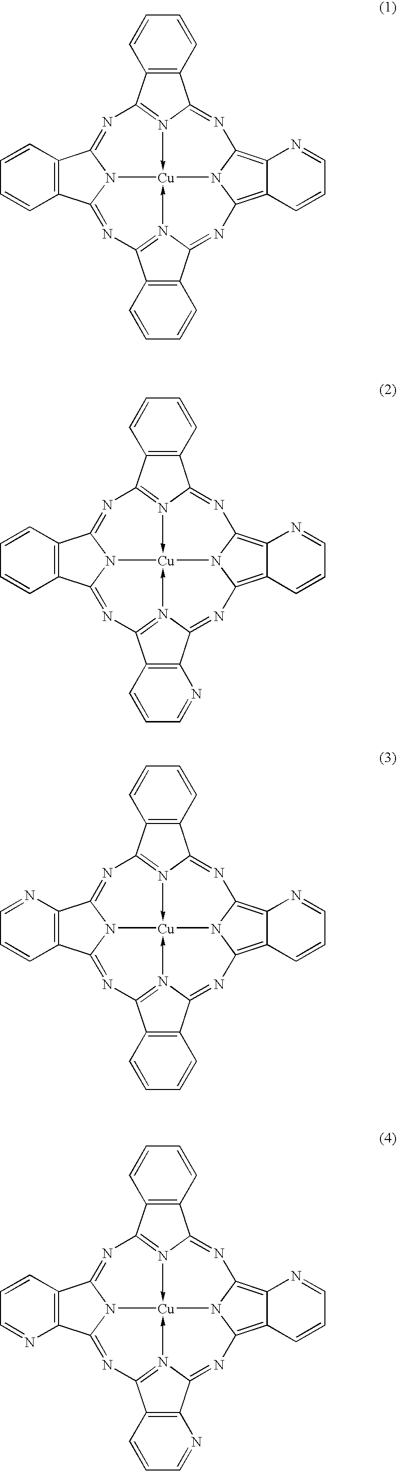

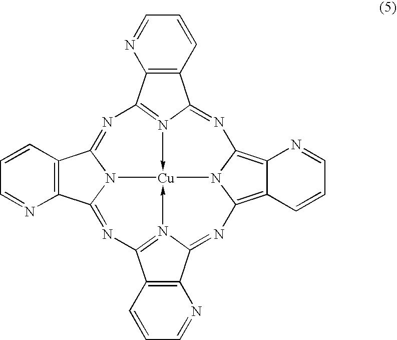

In the formula (I), R¹ and R² each independently represent hydrogen atom or a substituted or unsubstituted alkyl group; while R¹ and R² are not a hydrogen atom at the same time. Further, m is an integer of 1 to 8 and n is an integer of 1 to 4.

As the unsubstituted alkyl group represented by R¹ or R², an alkyl group having 1 to 12 carbon atoms is preferred. Examples thereof include straight chained or branched alkyl groups such as methyl group, ethyl group, n-propyl group, isopropyl group, n-butyl group, isobutyl group, n-hexyl group, 2-ethylhexyl group, n-octyl group and n-dodecyl group, and among these straight-chained or branched alkyl group having 4 to 12 carbon atoms is preferred.

As the substituted alkyl group represented by R¹ or R², “a substituted alkyl group containing an oxygen atom in at least one form of an ether bond, a carbonyl bond and an ester bond” is preferred, and a straight-chained, branched or cyclic substituted alkyl group having 2 to 12 carbon atoms containing 1 to 4 oxygen atoms in at least one form of the above is particularly preferred. Examples of the substituted alkyl group include methoxymethyl group, ethoxymethyl group, butoxymethyl group, methoxyethyl group, ethoxyethyl group, 3-methoxypropyl group, 3-ethoxypropyl group, 3-butoxypropyl group, methoxyethoxyethyl group, ethoxyethoxyethyl group, butoxyethoxyethyl group, methoxyethoxyethoxyethyl group, ethoxyethoxyethoxyethyl group, butoxyethoxyethoxyethyl group, acetylmethyl group, acetylethyl group, propionylmethyl group, propionylethyl group, tetrahydrofurfuryloxymethyl group, 2,2-dimethyl-1,3-dioxolane-4-methoxymethyl group, 2-(1,3-dioxolane)ethoxymethyl group, 2-(1,3-dioxane)ethoxymethyl group, methoxycarbonylmethyl group, ethoxycarbonylethyl group,

propoxycarbonylethyl group, butoxycarbonylethyl group, pentoxycarbonylbutyl group, 1-(butoxymethyl)ethyl group, 1-(methoxymethyl)propyl group, 1-(ethoxymethyl)propyl group, 1-(butoxymethyl)propyl group, 1-(2-methoxy-ethoxy-methyl)propyl group, 1-(2-ethoxy-ethoxy-methyl)propyl group, 1-(2-methoxy-2-ethoxy-2-ethoxymethyl)ethyl group, 1-(2-ethoxy-2-ethoxy-2-ethoxymethyl)ethyl group, 1-(2-butoxy-2-ethoxy-2-ethoxymethyl)ethyl group, 1-(2-methoxy-2-ethoxy-2-ethoxymethyl)propyl group, 1-(2-ethoxy-2-ethoxy-2-ethoxymethyl)propyl group, 1-(2-propoxy-2-ethoxy-2-ethoxymethyl)propyl group, 1-(2-butoxy-2-ethoxy-2-ethoxymethyl)propyl group, 1-(2-methoxy-2-ethoxy-2-ethoxymethyl)butyl group, 1-(2-ethoxy-2-ethoxy-2-ethoxymethyl)butyl group, 1-(2-propoxy-2-ethoxy-2-ethoxymethyl)butyl group,

1-(2-methoxy-2-ethoxy-2-ethoxymethyl)pentyl group, 1-(2-ethoxy-2-ethoxy-2-ethoxymethyl)pentyl group, 1-(2-methoxy-2-ethoxy-2-ethoxy-2-ethoxymethyl)ethyl group, 1-(2-ethoxy-2-ethoxy-2-ethoxy-2-ethoxymethyl)ethyl group, 1-(2-methoxy-2-ethoxy-2-ethoxy-2-ethoxymethyl)propyl group, 1-(2-ethoxy-2-ethoxy-2-ethoxy-2-ethoxymethyl)propyl group, 1-(2-methoxy-2-ethoxy-2-ethoxy-2-ethoxymethyl)butyl group, 1-(2-methoxy-2-ethoxy-2-ethoxy-2-ethoxyethyl)ethyl group, 1-(2-ethoxy-2-ethoxy-2-ethoxy-2-ethoxyethyl)ethyl group, 1-(2-methoxy-2-ethoxy-2-ethoxy-2-ethoxyethyl)propyl group, 1,1-di(methoxymethyl)methyl group, 1,1-di(ethoxymethyl)methyl group, 1,1-di(propoxymethyl)methyl group, 1,1-di(butoxymethyl)methyl group, 1,1-di(2-methoxy-ethoxymethyl)methyl group, 1,1-di(2-ethoxy-ethoxymethyl)methyl group, 1,1-di(2-propoxy-ethoxymethyl)methyl group and 1,1-di(2-butoxy-ethoxymethyl)methyl group.

The above-described R¹ and R² in the form of each independently a hydrogen atom (R¹ and R² are not a hydrogen atom at the same time), an unsubstituted alkyl group or “a substituted alkyl group containing oxygen atom in at least one form of ether bond, carbonyl bond and an ester bond” is preferred.

Among the above, R¹ and R² in the form of each independently a hydrogen atom (R¹ and R2 are not a hydrogen atom at the same time), an unsubstituted alkyl group having 1 to 12 carbon atoms or “a substituted alkyl group having 2 to 12 carbon atoms containing 1 to 4 oxygen atoms in at least one form of an ether bond, a carbonyl bond and an ester bond” is particularly preferred, and among these, at least one of R¹ and R² in a form of “a substituted alkyl group having 2 to 12 carbon atoms containing 1 to 4 oxygen atoms in at least one form of an ether bond, a carbonyl bond and an ester bond” is preferred in the point of having strong solubility to a polar organic solvent.

At least one of R¹ and R² being a substituted alkyl group represented by the following formula (I-a) such as tetraazaporphyrin compounds is particularly preferred.

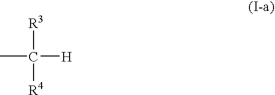

In the formula (I-a), R³ and R⁴ are each independently a hydrogen atom, an unsubstituted alkyl group, “a substituted alkyl group containing an oxygen atom in at least one form of an ether bond, a carbonyl bond and an ester bond”, an alkylcarbonyl group or an alkoxycarbonyl group, while at least one of R³ and R⁴ is “a substituted alkyl group containing an oxygen atom in at least one form of an ether bond, a carbonyl bond and an ester bond,” an alkylcarbonyl group or an alkoxycarbonyl group.

As the unsubstituted alkyl group represented by R³ or R⁴, an alkyl group having 1 to 8 carbon atoms is preferred. Examples thereof include methyl group, ethyl group, propyl group, isopropyl group, butyl group, isobutyl group, pentyl group, hexyl group and octyl group.

As “the substituted alkyl group containing an oxygen atom in at least one form of an ether bond, a carbonyl bond and an ester bond” represented by R³ or R⁴, a substituted alkyl group having 2 to 10 carbon atoms containing 1 to 4 oxygen atoms is preferred. Examples thereof include methoxymethyl group, ethoxymethyl group, propoxymethyl group, butoxymethyl group, methoxyethoxymethyl group, ethoxyethoxymethyl group, propoxyethoxymethyl group, butoxyethoxymethyl group, methoxyethoxyethoxymethyl group, ethoxyethoxyethoxymethyl group, propoxyethoxyethoxymethyl group, butoxyethoxyethoxymethyl group, methoxyethoxyethoxyethoxymethyl group, ethoxyethoxyethoxyethoxymethyl group, propoxyethoxyethoxyethoxymethyl group, butoxyethoxyethoxyethoxymethyl group, acetylmethyl group, propionylmethyl group, tetrahydrofurfuryloxymethyl group, 2,2-dimethyl-1,3-dioxolane-4-methoxymethyl group, 2-(1,3-dioxolane)ethoxymethyl group, 2-(1,3-dioxane)ethoxymethyl group, methoxycarbonylmethyl group, ethoxycarbonylmethyl group, propoxycarbonylmethyl group, butoxycarbonylmethyl group and pentoxycarbonylmethyl group.

As the alkylcarbonyl group and the alkoxycarbonyl group represented by R³ or R⁴, an alkyl carbonyl group having 2 to 10 carbon atoms and an alkoxycarbonyl group having 2 to 10 carbon atoms are preferred. Examples thereof include acetyl group, propionyl group, propylcarbonyl group, methoxycarbonyl group, ethoxycarbonyl group, propoxycarbonyl group, butoxycarbonyl group and pentoxycarbonyl group.

In the formula (I), m is an integer of 1 to 8. Among these an integer of 1 to 6 is preferred, and an integer of 1 to 4 is particularly preferred in the point of having high absorbance. In addition, n is an integer of 1 to 4. Among these, 2 or 3 is preferred, and 2 is particularly preferred.

A tetraazaporphyrin compound represented by the formula (I) is a compound containing a portion or a whole of these many isomers.

Exemplified compounds (specific examples 1 to 157) of the tetraazaporphyrin compound represented by the formula (I) are presented below. The invention is not limited to these specific examples.

| | 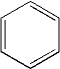 | 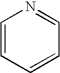 | m | n | R¹ | R² |
|---|---|---|---|---|---|---|
| 1 | 3 | 1 | 1 | 1 | H | —C₂H₄OC₂H₅ |
| 2 | 3 | 1 | 2 | 2 | H | —C₂H₄OC₂H₅ |
| 3 | 3 | 1 | 3 | 3 | H | —C₂H₄OC₂H₅ |
| 4 | 3 | 1 | 1 | 4 | H | —C₂H₄OC₂H₅ |
| 5 | 3 | 1 | 1 | 1 | —C₂H₄OC₂H₅ | —C₂H₄OC₂H₅ |
| 6 | 3 | 1 | 1 | 1 | H | —C₃H₆OC₄H₉ |
| 7 | 3 | 1 | 1 | 2 | H | —C₃H₆OC₄H₉ |
| 8 | 3 | 1 | 1 | 3 | H | —C₃H₆OC₄H₉ |
| 9 | 3 | 1 | 1 | 4 | H | —C₃H₆OC₄H₉ |
| 10 | 3 | 1 | 1 | 1 | —C₂H₄OCH₃ | —C₂H₄OCH₃ |
| 11 | 3 | 1 | 1 | 2 | —C₂H₄OCH₃ | —C₂H₄OCH₃ |
| 12 | 3 | 1 | 1 | 3 | —C₂H₄OCH₃ | —C₂H₄OCH₃ |
| 13 | 3 | 1 | 1 | 4 | —C₂H₄OCH₃ | —C₂H₄OCH₃ |
| 14 | 3 | 1 | 1 | 2 | —C₄H₉ | —C₄H₉ |
| 15 | 3 | 1 | 1 | 1 | H | 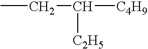 |
| 16 | 3 | 1 | 1 | 2 | H | 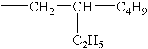 |
| 17 | 3 | 1 | 1 | 3 | H | 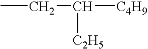 |
| 18 | 3 | 1 | 1 | 4 | H | 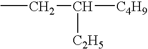 |
| 19 | 3 | 1 | 1 | 1 | H | 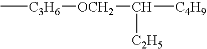 |
| 20 | 3 | 1 | 1 | 2 | H | 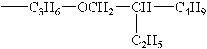 |
| 21 | 3 | 1 | 1 | 3 | H | 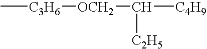 |
| 22 | 3 | 1 | 4 | 2 | H | 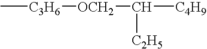 |
| 23 | 3 | 1 | 5 | 2 | H | —C₂H₄OC₂H₄OC₂H₅ |
| 24 | 3 | 1 | 6 | 1 | —C₂H₅ | —C₂H₄OC₂H₅ |
| 25 | 3 | 1 | 8 | 1 | -i-C₃H₇ | 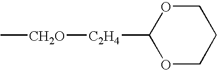 |
| 26 | 3 | 1 | 3 | 2 | H | 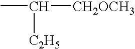 |
| 27 | 3 | 1 | 1 | 1 | H | 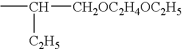 |
| 28 | 3 | 1 | 1 | 2 | H | 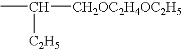 |
| 29 | 3 | 1 | 2 | 2 | H | 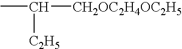 |
| 30 | 3 | 1 | 3 | 2 | H | 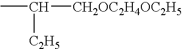 |
| 31 | 3 | 1 | 1 | 1 | H | 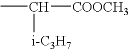 |
| 32 | 3 | 1 | 1 | 2 | H | 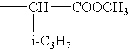 |
| 33 | 3 | 1 | 1 | 2 | H | 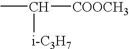 |
| 34 | 3 | 1 | 1 | 1 | H | 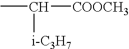 |
| 35 | 3 | 1 | 3 | 2 | -n-C₈H₁₇ | 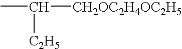 |
| 36 | 3 | 1 | 4 | 2 | H | 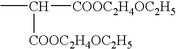 |
| 37 | 3 | 1 | 1 | 1 | —C₂H₄OC₂H₄OC₂H₅ | —C₂H₄OC₂H₄OC₂H₅ |
| 38 | 2 | 2 | 1 | 1 | H | —C₂H₄OC₂H₅ |
| 39 | 2 | 2 | 1 | 2 | H | —C₂H₄OC₂H₅ |
| 40 | 2 | 2 | 1 | 3 | H | —C₂H₄OC₂H₅ |
| 41 | 2 | 2 | 1 | 4 | H | —C₂H₄OC₂H₅ |
| 42 | 2 | 2 | 1 | 2 | —C₂H₄OC₂H₅ | —C₂H₄OC₂H₅ |
| 43 | 2 | 2 | 1 | 1 | H | —C₃H₆OC₄H₉ |
| 44 | 2 | 2 | 1 | 2 | H | —C₃H₆OC₄H₉ |
| 45 | 2 | 2 | 1 | 3 | H | —C₃H₆OC₄H₉ |
| 46 | 2 | 2 | 1 | 4 | H | —C₃H₆OC₄H₉ |
| 47 | 2 | 2 | 1 | 1 | —C₂H₄OCH₃ | —C₂H₄OCH₃ |
| 48 | 2 | 2 | 1 | 2 | —C₂H₄OCH₃ | —C₂H₄OCH₃ |
| 49 | 2 | 2 | 1 | 3 | —C₂H₄OCH₃ | —C₂H₄OCH₃ |
| 50 | 2 | 2 | 1 | 4 | —C₂H₄OCH₃ | —C₂H₄OCH₃ |
| 51 | 2 | 2 | 1 | 3 | —C₄H₉ | —C₄H₉ |
| 52 | 2 | 2 | 1 | 1 | H | 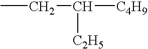 |
| 53 | 2 | 2 | 1 | 2 | H | 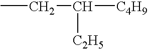 |
| 54 | 2 | 2 | 1 | 3 | H | 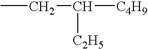 |
| 55 | 2 | 2 | 1 | 4 | H | 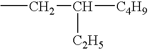 |
| 56 | 2 | 2 | 1 | 1 | H | 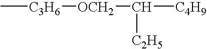 |
| 57 | 2 | 2 | 1 | 2 | H | 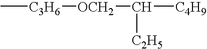 |
| 58 | 2 | 2 | 1 | 3 | H | 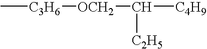 |
| 59 | 2 | 2 | 1 | 4 | H | 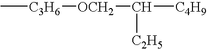 |
| 60 | 2 | 2 | 1 | 4 | H | —C₂H₄OC₂H₄OC₂H₅ |
| 61 | 2 | 2 | 1 | 1 | —C₂H₅ | —C₂H₄OC₂H₅ |
| 62 | 2 | 2 | 2 | 2 | -i-C₃H₇ | 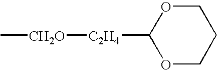 |
| 63 | 2 | 2 | 3 | 3 | H | 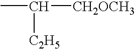 |
| 64 | 2 | 2 | 1 | 1 | H | 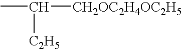 |
| 65 | 2 | 2 | 1 | 2 | H | 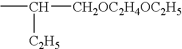 |
| 66 | 2 | 2 | 3 | 3 | H | 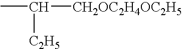 |
| 67 | 2 | 2 | 1 | 4 | H | 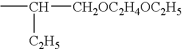 |
| 68 | 2 | 2 | 1 | 1 | H | 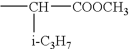 |
| 69 | 2 | 2 | 2 | 2 | H | 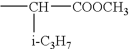 |
| 70 | 2 | 2 | 3 | 3 | H | 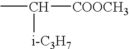 |
| 71 | 2 | 2 | 1 | 4 | H | 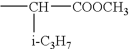 |
| 72 | 2 | 2 | 1 | 4 | -n-C₈H₁₇ | 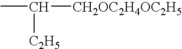 |
| 73 | 2 | 2 | 1 | 1 | H | 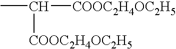 |
| 74 | 2 | 2 | 2 | 2 | —C₂H₄OC₂H₄OC₂H₅ | —C₂H₄OC₂H₄OC₂H₅ |
| 75 | 1 | 3 | 1 | 1 | H | —C₂H₄OC₂H₅ |
| 76 | 1 | 3 | 2 | 2 | H | —C₂H₄OC₂H₅ |
| 77 | 1 | 3 | 1 | 3 | H | —C₂H₄OC₂H₅ |
| 78 | 1 | 3 | 1 | 4 | H | —C₂H₄OC₂H₅ |
| 79 | 1 | 3 | 1 | 3 | —C₂H₄OC₂H₅ | —C₂H₄OC₂H₅ |
| 80 | 1 | 3 | 1 | 1 | H | —C₃H₆OC₄H₉ |
| 81 | 1 | 3 | 1 | 2 | H | —C₃H₆OC₄H₉ |
| 82 | 1 | 3 | 1 | 3 | H | —C₃H₆OC₄H₉ |
| 83 | 1 | 3 | 1 | 4 | H | —C₃H₆OC₄H₉ |
| 84 | 1 | 3 | 1 | 1 | —C₂H₄OCH₃ | —C₂H₄OCH₃ |
| 85 | 1 | 3 | 1 | 2 | —C₂H₄OCH₃ | —C₂H₄OCH₃ |
| 86 | 1 | 3 | 1 | 3 | —C₂H₄OCH₃ | —C₂H₄OCH₃ |
| 87 | 1 | 3 | 1 | 4 | —C₂H₄OCH₃ | —C₂H₄OCH₃ |
| 88 | 1 | 3 | 1 | 4 | —C₄H₉ | —C₄H₉ |
| 89 | 1 | 3 | 1 | 1 | H | 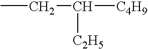 |
| 90 | 1 | 3 | 1 | 2 | H | 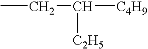 |
| 91 | 1 | 3 | 1 | 3 | H | 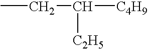 |
| 92 | 1 | 3 | 1 | 4 | H | 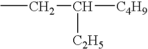 |
| 93 | 1 | 3 | 1 | 1 | H | 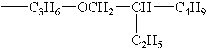 |
| 94 | 1 | 3 | 1 | 2 | H | 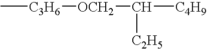 |
| 95 | 1 | 3 | 1 | 3 | H | 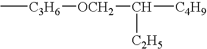 |
| 96 | 1 | 3 | 1 | 4 | H | 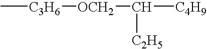 |
| 97 | 1 | 3 | 1 | 1 | H | —C₂H₄OC₂H₄OC₂H₅ |
| 98 | 1 | 3 | 1 | 2 | —C₂H₅ | —C₂H₄OC₂H₅ |
| 99 | 1 | 3 | 3 | 3 | -i-C₃H₇ | 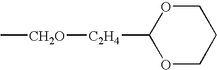 |
| 100 | 1 | 3 | 1 | 4 | H | 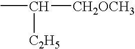 |
| 101 | 1 | 3 | 1 | 1 | H | 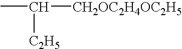 |
| 102 | 1 | 3 | 4 | 2 | H | 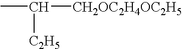 |
| 103 | 1 | 3 | 4 | 3 | H | 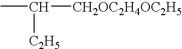 |
| 104 | 1 | 3 | 4 | 3 | H | 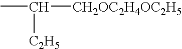 |
| 105 | 1 | 3 | 1 | 1 | H | —CH₂—C₂H₄COCH₃ |
| 106 | 1 | 3 | 2 | 2 | H | —CH₂—C₂H₄COCH₃ |
| 107 | 1 | 3 | 3 | 3 | H | —CH₂—C₂H₄COC₃H₇ |
| 108 | 1 | 3 | 1 | 4 | H | —CH₂—C₂H₄COC₃H₇ |
| 109 | 1 | 3 | 1 | 1 | -n-C₈H₁₇ | 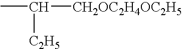 |
| 110 | 1 | 3 | 2 | 2 | H | 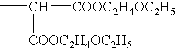 |
| 111 | 1 | 3 | 1 | 3 | —C₂H₄OC₂H₄OC₂H₅ | —C₂H₄OC₂H₄OC₂H₅ |
| 112 | 0 | 4 | 1 | 1 | H | —C₂H₄OC₂H₅ |
| 113 | 0 | 4 | 1 | 2 | H | —C₂H₄OC₂H₅ |
| 114 | 0 | 4 | 1 | 3 | H | —C₂H₄OC₂H₅ |
| 115 | 0 | 4 | 1 | 4 | H | —C₂H₄OC₂H₅ |
| 116 | 0 | 4 | 1 | 4 | —C₂H₄OC₂H₅ | —C₂H₄OC₂H₅ |
| 117 | 0 | 4 | 1 | 1 | H | —C₃H₆OC₄H₉ |
| 118 | 0 | 4 | 1 | 2 | H | —C₃H₆OC₄H₉ |
| 119 | 0 | 4 | 1 | 3 | H | —C₃H₆OC₄H₉ |
| 120 | 0 | 4 | 1 | 4 | H | —C₃H₆OC₄H₉ |
| 121 | 0 | 4 | 1 | 1 | —C₂H₄OCH₃ | —C₂H₄OCH₃ |
| 122 | 0 | 4 | 1 | 2 | —C₂H₄OCH₃ | —C₂H₄OCH₃ |
| 123 | 0 | 4 | 1 | 3 | —C₂H₄OCH₃ | —C₂H₄OCH₃ |
| 124 | 0 | 4 | 1 | 4 | —C₂H₄OCH₃ | —C₂H₄OCH₃ |
| 125 | 0 | 4 | 1 | 1 | —C₄H₉ | —C₄H₉ |
| 126 | 0 | 4 | 1 | 1 | H | 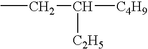 |
| 127 | 0 | 4 | 1 | 2 | H | 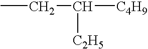 |
| 128 | 0 | 4 | 1 | 2 | H | 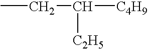 |
| 129 | 0 | 4 | 1 | 4 | H | 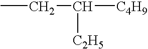 |
| 130 | 0 | 4 | 1 | 1 | H | —CHCOCH₃ |
| 131 | 0 | 4 | 1 | 2 | H | —CHCOCH₃ |
| 132 | 0 | 4 | 1 | 3 | H | —CHCOOC₃H₇ |
| 133 | 0 | 4 | 1 | 4 | H | —CHCOOC₃H₇ |
| 134 | 0 | 4 | 1 | 2 | H | —C₂H₄OC₂H₄OC₂H₅ |
| 135 | 0 | 4 | 1 | 3 | —C₂H₅ | —C₂H₄OC₂H₅ |
| 136 | 0 | 4 | 1 | 4 | -i-C₃H₇ | 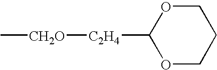 |
| 137 | 0 | 4 | 1 | 1 | H | 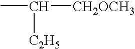 |
| 138 | 0 | 4 | 1 | 1 | H | 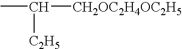 |
| 139 | 0 | 4 | 1 | 1 | H | 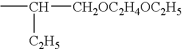 |
| 140 | 0 | 4 | 1 | 3 | H | 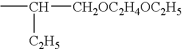 |
| 141 | 0 | 4 | 1 | 4 | H | 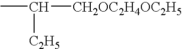 |
| 142 | 0 | 4 | 1 | 1 | H | 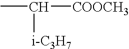 |
| 143 | 0 | 4 | 1 | 2 | H | 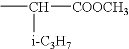 |
| 144 | 0 | 4 | 1 | 3 | H | 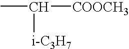 |
| 145 | 0 | 4 | 1 | 4 | H | 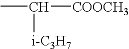 |
| 146 | 0 | 4 | 1 | 2 | -n-C₈H₁₇ | 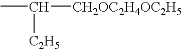 |
| 147 | 0 | 4 | 1 | 3 | H | 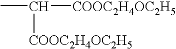 |
| 148 | 0 | 4 | 1 | 4 | —C₂H₄OC₂H₄OC₂H₅ | —C₂H₄OC₂H₄OC₂H₅ |
| 149 | 3 | 1 | 1 | 4 | —C₁₀H₂₁ | H |
| 150 | 3 | 1 | 1 | 3 | —C₁₂H₂₅ | —C₁₂H₂₅ |
| 151 | 3 | 1 | 1 | 4 | —C₁₂H₂₅ | —C₂H₄OC₂H₅ |
| 152 | 3 | 1 | 1 | 1 | 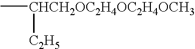 | H |
| 153 | 3 | 1 | 1 | 3 | 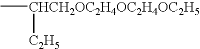 | —C₂H₅ |
| 154 | 3 | 1 | 1 | 1 | 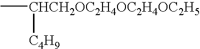 | H |
| 155 | 3 | 1 | 1 | 1 | 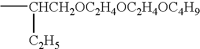 | H |
| 156 | 3 | 1 | 1 | 2 | 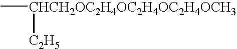 | H |
| 157 | 3 | 1 | 1 | 3 | 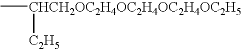 | H |

Dye Compound Represented by the Formula (II)

Next, a dye compound represented by the following formula (II) will be described.

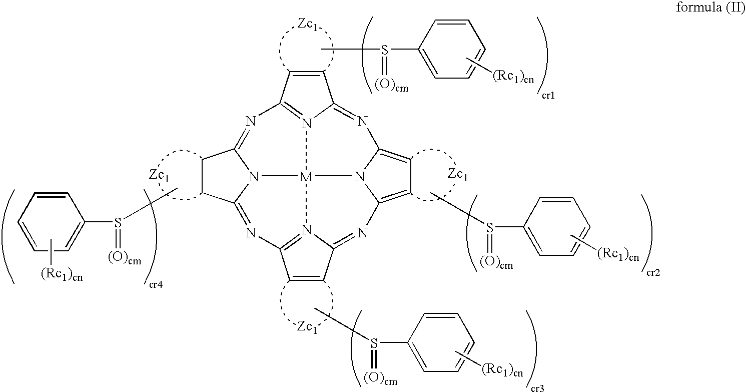

In the formula (II), Rc₁ is a halogen atom, an aliphatic group, an aryl group, a heterocyclic group, a cyano group, a carboxyl group, a carbamoyl group, an aliphatic oxycarbonyl group, an aryloxycarbonyl group, an acyl group, a hydroxyl group, an aliphatic oxygroup, an aryloxy group, acyloxy group, a carbamoyloxy group, a heterocyclic oxy group, an aliphatic oxycarbonyloxy group, an N-alkylacylamino group, a carbamoyl amino group, a sulfamoylamino group, an aliphatic oxycarbonylamino group, an aryloxycarbonylamino group, an aliphatic sulfonylamino group, an arylsulfonylamino group, an aliphatic thio group, an arylthio group, an aliphatic sulfonyl group, an arylsulfonyl group, a sulfamoyl group, a sulfo group, an imido group or a heterocyclic thio group.

Zc₁ is a nonmetal atom group required in forming a 6-membered ring together with carbon atoms, and four Zc₁'s may be identical with or different from each other.

M is two hydrogen atoms, a divalent metal atom, a divalent metal oxide, a divalent metal hydroxide or a divalent metal chloride.

cm is 0, 1 or 2, cn is 0 or an integer of 1 to 5, and four cn's may be identical with or different from each other. One cn is an integer of 1 to 5, and a plurality of Rc₁'s in a molecule may be identical with or different from each other. cr1, cr2, cr3 and cr4 are 0 or 1, and cr1+cr2+cr3+cr4≧1 is satisfied.

In the formula (II), the aliphatic portion of “aliphatic” may be straight-chained, branched or cyclic and may be saturated or unsaturated. Examples of “aliphatic” include an alkyl group, alkenyl group, cycloalkyl group and cycloalkenyl group, and “aliphatic” may be unsubstituted or substituted with a substituent. Moreover, “aryl” may be any one of a monocyclic ring or a condensed ring, and may be unsubstituted or substituted with a substituent. The heterocyclic portion of a “heterocyclic ring” contains a hetero atom (e.g., a nitrogen atom, a sulfur atom and an oxygen atom) in a ring, and may be any one of a saturated ring or an unsaturated ring. The “heterocyclic ring” may be any one of a monocyclic ring or a condensed ring, and may be unsubstituted or substituted with a substituent.

In the formula (II), the “substituent” may be a group capable of substitution. Examples thereof include an aliphatic group, an aryl group, a heterocyclic group, an acyl group, an imido group, an azo group, an acyloxy group, an acylamino group, a N-alkylacylamino group, an aliphatic oxy group, an aryloxy group, a heterocyclic oxy group, an aliphatic oxycarbonyl group, an aryloxycarbonyl group, a heterocyclic-oxycarbonyl group, a carbamoyl group, an aliphatic sulfonyl group, an arylsulfonyl group, a heterocyclic sulfonyl group, an aliphatic sulfonyloxy group, an arylsulfonyloxy group, a heterocyclic sulfonyloxy group, a sulfamoyl group, an aliphatic sulfonamide group, an arylsulfonamide group, a heterocyclic sulfonamide group, an amino group, an aliphatic amino group, an arylamino group, a heterocyclic amino group, an aliphatic oxycarbonylamino group, an aryloxycarbonylamino group, a heterocyclic-oxycarbonylamino group, an aliphatic sulfinyl group, an arylsulfinyl group, an aliphatic thio group, an arylthio group, a heterocyclic thio, a hydroxyl group, a cyano group, a sulfo group, a carboxyl group, an aliphatic oxyamino group, an aryloxyamino group, a carbamoylamino group, a sulfamoylamino group, a halogen atom, a sulfamoylcarbamoyl group, a carbamoylsulfamoyl group, a dialiphatic oxyphosphinyl group and a diaryloxyphosphinyl group.

In the formula (II), Rc₁ is a halogen atom, an aliphatic group, an aryl group, a heterocyclic group, a cyano group, a carboxyl group, a carbamoyl group, an aliphatic oxycarbonyl group, an aryloxycarbonyl group, an acyl group, a hydroxyl group, an aliphatic oxy group, an aryloxy group, acyloxy group, a carbamoyloxy group, a heterocyclic oxy group, an aliphatic oxycarbonyloxy group, an N-alkylacylamino group, a carbamoylamino group, a sulfamoylamino group, an aliphatic oxycarbonylamino group, an aryloxycarbonylamino group, an aliphatic sulfonylamino group, an arylsulfonylamino group, an aliphatic thio group, an aryl thio group, an aliphatic sulfonyl group, an arylsulfonyl group, a sulfamoyl group, a sulfo group, an imido group or a heterocyclic thio group.

Examples of the halogen group represented by Rc₁ include a fluorine atom, a chlorine atom and a bromine atom.

The aliphatic group represented by Rc₁ may be unsubstituted or substituted with a substituent. The aliphatic group may be saturated or unsaturated, and may be cyclic. As the aliphatic group, an aliphatic group having 1 to 15 carbon atoms is preferred, and examples thereof include methyl group, ethyl group, vinyl group, allyl group, ethynyl group, isopropenyl group and 2-ethylhexyl group.

The aryl group represented by Rc₁ may be unsubstituted or substituted with a substituent. As the aryl group, an aryl group having 6 to 16 carbon atoms is preferred and an aryl group having 6 to 12 carbon atoms is more preferred. Examples thereof include phenyl group, 4-nitrophenyl group, 2-nitrophenyl group, 2-chlorophenyl group, 2,4-dichlorophenyl group, 2,4-dimethylphenyl group, 2-methylphenyl group, 4-methoxyphenyl group, 2-methoxyphenyl group and 2-methoxycarbonyl-4-nitrophenyl group.

The heterocyclic group represented by Rc₁ may be saturated or unsaturated. As the heterocyclic group, a heterocyclic group having 1 to 15 carbon atoms is preferred, and a heterocyclic group having 3 to 10 carbon atoms is more preferred. Examples thereof include 3-pyridyl group, 2-pyridyl group, 2-pyrimidinyl group, 2-pyrazinyl group and 1-piperidinyl group. Moreover, the heterocyclic group may further have a substituent.

The carbamoyl group represented by Rc₁ may be unsubstituted or substituted with a substituent. As the carbamoyl group, a carbamoyl group having 1 to 16 carbon atoms is preferred, and a carbamoyl group having 1 to 12 carbon atoms is more preferred. Examples thereof include carbamoyl group, dimethylcarbamoyl group and dimethoxyethylcarbamoyl group.

The aliphatic oxycarbonyl group represented by Rc₁ may be unsubstituted or substituted with a substituent. The aliphatic oxycarbonyl group may be saturated or unsaturated, and may be cyclic. As the aliphatic oxycarbonyl group, an aliphatic oxycarbonyl group having 2 to 16 carbon atoms is preferred, and an aliphatic oxycarbonyl group having 2 to 10 carbon atoms is more preferred. Examples thereof include methoxycarbonyl group and butoxycarbonyl group.

The aryloxycarbonyl group represented by Rc₁ may be unsubstituted or substituted with a substituent. As the aryloxycarbonyl group, an aryloxycarbonyl group having 7 to 17 carbon atoms is preferred, and an aryloxycarbonyl group having 7 to 15 carbon atoms is more preferred. Examples thereof include phenoxycarbonyl group.

The acyl group represented by Rc₁ may be an aliphatic carbonyl group or an arylcarbonyl group. When the acyl group is an aliphatic carbonyl group, the acyl group may further have a substituent. When the acyl group is an arylcarbonyl group, the acyl group may further have a substituent. The acyl group may be saturated or unsaturated, and may be cyclic. As the acyl group, an acyl group having 2 to 15 carbon atoms is preferred, and an acyl group having 2 to 10 carbon atoms is more preferred. Examples thereof include acetyl group, pivaloyl group and benzoyl group. Moreover, the acyl group may further have a substituent.

The aliphatic oxy group represented by Rc₁ may be unsubstituted or substituted with a substituent. The aliphatic oxy group may be saturated or unsaturated, and may be cyclic. As the aliphatic oxy group, an aliphatic oxy group having 1 to 12 carbon atoms is preferred, and an aliphatic oxy group having 1 to 10 carbon atoms is more preferred. Examples thereof include methoxy group, ethoxyethoxy group, phenoxyethoxy group and thiophenoxyethoxy group.

The aryloxy group represented by Rc₁ may be unsubstituted or substituted with a substituent. As the aryloxy group, an aryloxy group having 6 to 18 carbon atoms is preferred, and an aryloxy group having 6 to 14 carbon atoms is more preferred. Examples thereof include phenoxy group and 4-methylpheoxy group.

The acyloxy group represented by Rc₁ may be unsubstituted or substituted with a substituent. As the acyloxy group, an acyloxy group having 2 to 14 carbon atoms is preferred, and an acyloxy group having 2 to 10 carbon atoms is more preferred. Examples thereof include acetoxy group, methoxyacetoxy group and benzoyloxy group.

The carbamoyloxy group represented by Rc₁ may be unsubstituted or substituted with a substituent. As the carbamoyloxy group, a carbamoyloxy group having 1 to 16 carbon atoms is preferred, and a carbamoyloxy group having 1 to 12 carbon atoms is more preferred. Examples thereof include dimethylcarbamoyloxy group and diisopropylcarbamoyloxy group.

The heterocyclic oxy group represented by Rc₁ may be unsubstituted or substituted with a substituent. As the heterocyclic oxy group, a heterocyclic oxy group having 1 to 15 carbon atoms is preferred, and a heterocyclic oxy group having 3 to 10 carbon atoms is more preferred. Examples thereof include 3-furyloxy group, 3-pyridyloxy group and N-methyl-2-piperidyloxy group.

The aliphatic oxycarbonyloxy group represented by Rc₁ may be unsubstituted or substituted with a substituent. The aliphatic oxycarbonyloxy group may be saturated or unsaturated, and may be cyclic. As the aliphatic oxycarbonyloxy group, an aliphatic oxycarbonyloxy group having 2 to 16 carbon atoms is preferred, and an aliphatic oxycarbonyloxy group having 2 to 10 carbon atoms is more preferred. Examples thereof include methoxycarbonyloxy group and (t)-butoxycarbonyloxy group.

The N-alkylacylamino group represented by Rc₁ may be unsubstituted or substituted with a substituent. As the N-alkylacylamino group, an N-alkylacylamino group having 3 to 15 carbon atoms is preferred, and an N-alkylacylamino group having 3 to 12 carbon atoms is more preferred. Examples thereof include N-methylacetylamino group, N-ethoxyethylbenzoylamino group and N-methylmethoxyacetylamino group.

The carbamoylamino group represented by Rc₁ may be unsubstituted or substituted with a substituent. As the carbamoylamino group, a carbamoylamino group having 1 to 16 carbon atoms is preferred, and a carbamoylamino group having 1 to 12 carbon atoms is more preferred. Examples thereof include N,N-dimethylcarbamoylamino group and N-methyl-N-methoxyethylcarbamoylamino group.

The sulfamoylamino group represented by Rc₁ may be unsubstituted or substituted with a substituent. As the sulfamoylamino group, a sulfamoylamino group having 0 to 16 carbon atoms is preferred, and a sulfamoylamino group having 0 to 12 carbon atoms is more preferred. Examples thereof include N,N-dimethylsulfamoylamino group and N,N-diehtylsulfamoyl group.

The aliphatic oxycarbonylamino group represented by Rc₁ may be unsubstituted or substituted with a substituent. As the aliphatic oxycarbonylamino group, an aliphatic oxycarbonylamino group having 2 to 15 carbon atoms is preferred, and an aliphatic oxycarbonylamino group having 2 to 10 carbon atoms is more preferred. Examples thereof include methoxycarbonylamino group and methoxyethoxycarbonylamino group.

The aryloxycarbonylamino group represented by Rc₁ may be unsubstituted or substituted with a substituent. As the aryloxycarbonylamino group, an aryloxycarbonylamino group having 7 to 17 carbon atoms is preferred, and an aryloxycarbonylamino group having 7 to 15 carbon atoms is more preferred. Examples thereof include phenoxycarbonylamino group and 4-methoxycarbonylamino group.

The aliphatic sulfonylamino group represented by Rc₁ may be unsubstituted or substituted with a substituent. The aliphatic sulfonylamino group may be saturated or unsaturated, and may be cyclic. As the aliphatic sulfonylamino group, an aliphatic sulfonylamino group having 1 to 12 carbon atoms is preferred, and an aliphatic sulfonylamino group having 1 to 8 carbon atoms is more preferred. Examples thereof include methanesulfonylamino group and butanesulfonylamino group.

The arylsulfonylamino group represented by Rc₁ may be unsubstituted or substituted with a substituent. As the arylsulfonylamino group, an arylsulfonylamino group having 6 to 15 carbon atoms is preferred, and an arylsulfonylamino group having 6 to 12 carbon atoms is more preferred. Examples thereof include benzenesulfonylamino group and 4-toluenesulfonylamino group.

The aliphatic thio group represented by Rc₁ may be unsubstituted or substituted with a substituent. The aliphatic thio group may be saturated or unsaturated, and may be cyclic. As the aliphatic thio group, an aliphatic thio group having 1 to 16 carbon atoms is preferred, and an aliphatic thio group having 1 to 10 carbon atoms is more preferred. Examples thereof include methylthio group, ethylthio group and ethoxyehtylthio group.

The arylthio group represented by Rc₁ may be unsubstituted or substituted with a substituent. As the arylthio group, an arylthio group having 6 to 22 carbon atoms is preferred, and an arylthio group having 6 to 14 carbon atoms is more preferred. Examples thereof include phenylthio group and 2-t-butylthio group.

The aliphatic sulfonyl group represented by Rc₁ may be unsubstituted or substituted with a substituent. As the aliphatic sulfonyl group, an aliphatic sulfonyl group having 1 to 15 carbon atoms is preferred, and an aliphatic sulfonyl group having 1 to 8 carbon atoms is more preferred. Examples thereof include methanesulfonyl group, butanesulfonyl group and methoxyethanesulfonyl group.

The arylsulfonyl group represented by Rc₁ may be unsubstituted or substituted with a substituent. As the arylsulfonyl group, an arylsulfonyl group having 6 to 16 carbon atoms is preferred, and an arylsulfonyl group having 6 to 12 carbon atoms is more preferred. Examples thereof include benzenesulfonyl group, 4-t-butylbenzenesulfonyl group, 4-toluenesulfonyl group and 2-toluenesulfonyl group.

The sulfamoyl group represented by Rc₁ may be unsubstituted or substituted with a substituent. As the sulfamoyl group, a sulfamoyl group having 0 to 16 carbon atoms is preferred, and a sulfamoyl group having 0 to 12 carbon atoms is more preferred. Examples thereof include sulfamoyl group and dimethylsulfamoyl group.

The imido group represented by Rc₁ may be unsubstituted or substituted with a substituent. As the imido group, an imido group having 3 to 22 carbon atoms is preferred, and an imido group having 3 to 15 carbon atoms is more preferred. Examples thereof include succinimido group and phthalimido group.

The heterocyclic thio group represented by Rc₁ may be unsubstituted or substituted with a substituent. As the heterocyclic thio group, a 5 to 7-membered heterocyclic thio group having 1 to 20 carbon atoms is preferred, and a 5 to 7-membered heterocyclic thio group having 1 to 12 carbon atoms is more preferred. Examples thereof include 3-furylthio group and 3-pyridylthio group.

In the formula (II), Zc₁ is a nonmetal atom group required in forming a 6-membered ring together with carbon atoms, and four Zc₁'s may be identical with or different from each other. The 6-membered ring, which is formed, may be any one of an aryl ring or a heterocyclic ring. The 6-membered ring may be condensed, and the condensed ring may be further substituted with a substituent. Examples of the 6-membered ring include benzene ring, pyridine ring, cyclohexene ring and naphthalene ring, and a form of the benzene ring is preferred.

In the formula (II), M is two hydrogen atoms, a divalent metal atom, a divalent metal oxide, a divalent metal hydroxide or a divalent metal chloride. Examples of M include VO, TiO, Zn, Mg, Si, Sn, Rh, Pt, Pd, Mo, Mn, Pb, Cu, Ni, Co, Fe, AlCl, InCl, FeCl, TiCl₂, SnCl₂, SiCl₂, GeCl₂, Si(OH)₂ and H₂, and a form of VO, Zn, Mn, Cu, Ni, Co is preferred.

In the formula (II), cm is 0,1 or 2 (preferably 0), and cn is 0 or an integer of 1 to 5 (preferably 0 or 1). Four cn's in a molecule may be identical with or different from each other; while one cn is an integer of 1 to 5, and when there are a plurality of Rc₁'s in a molecule, the plurality of Rc₁'s may be identical with or different from each other.

Furthermore, cr1, cr2, cr3 and cr4 are 0 or 1, and cr1+cr2+cr3+cr4≧1 is satisfied. Among these, cr1+cr2+cr3+cr4 in a form of 3 or 4 is preferred.

Among the dye compounds represented by the formula (II), a pigment represented by the following formula (II-1) is preferred in the viewpoint of obtaining the effect of the invention even more effectively.

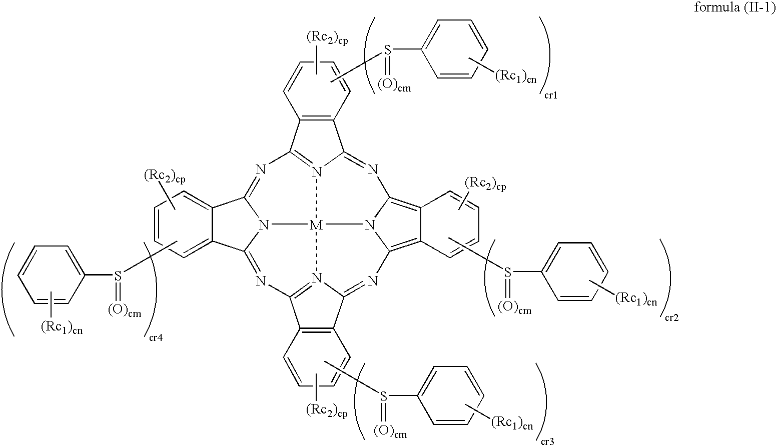

In the formula (II-1), Rc₂ is a substituent. The substituent is acceptable as long as the group is capable of substitution, and the groups exemplified in the paragraph of “substituents” of the above-mentioned formula (II) can be mentioned.

Such substituents are preferably an aliphatic group, an aryl group, a heterocyclic group, a N-alkylacylamino group, an aliphatic oxy group, an aryloxy group, a heterocyclic oxy group, an aliphatic oxycarbonyl group, an aryloxycarbonyl group, a heterocyclic-oxycarbonyl group, a carbamoyl group, an aliphatic sulfonyl group, a sulfamoyl group, an aliphatic sulfonamide group, an arylsulfonamide group, an aliphatic amino group, an arylamino group, an aliphatic oxycarbonylamino group, an aryloxycarbonylamino group, an aliphatic thio group, an arylthio group, a hydroxyl group, a cyano group, a sulfo group, a carboxyl group, a carbamoylamino group, a sulfamoylamino group and a halogen atom, and more preferably, an aliphatic group, a N-alkylacylamino group, an aliphatic oxy group, an aliphatic oxycarbonyl group, an aliphatic sulfonyl group, an aliphatic thio group, an arylthio group, a sulfo group, a carboxyl group and a halogen atom.

In the formula (II-1), cp is an integer of 0 to 4, and preferably 0 or 1; while cp+cr1, cp+cr2, cp+cr3 and cp+cr4 are integers of 0 to 4. When there is a plurality of Rc₂'s in a molecule, the plurality of Rc₂'s may be identical with or different from each other.

Further, in the formula (II-1), Rc₁, M, cm, cn, cr1, cr2, cr3 and cr4 have the same definitions as in the formula (II), and preferable forms also have the same definitions.

Among the dye compound represented by the formula (II-1), a pigment represented by the following formula (II-2) is more preferred in the viewpoint of obtaining the effect of the invention even more effectively.

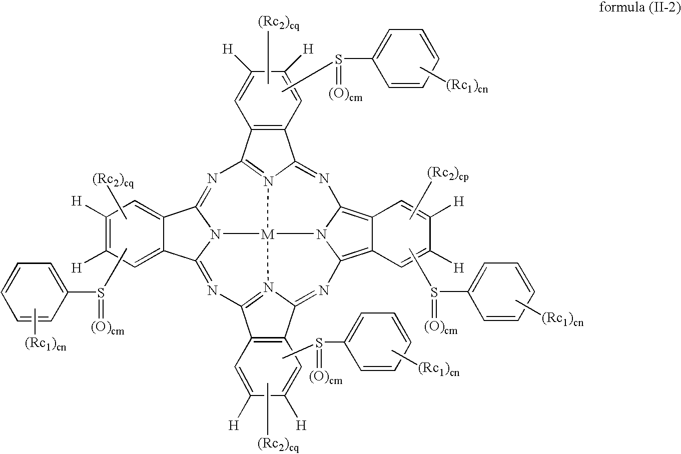

In the formula (II-2), Rc1, Rc2, M, cm and cn, have the same definitions as in the formulas (II) and (II-1), respectively, and the preferable forms also have the same definitions. In the formula (II-2), cq is 0 or 1. The phthalocyanine skeleton has a structure in which four benzene rings are condensed to the outside of the tetraazaporphyrin skeleton. Each benzene ring has four sites (carbon atoms) where substituents can be substituted, but the formula (11-2) has hydrogen atoms bound to the two sites (β position) far from the tetraazaporphyrin skeleton of each benzene ring.

In the formula (11-2), from the viewpoint of exhibiting the effect of the invention more effectively, an embodiment wherein Rc₁ is a halogen atom, aliphatic group, cyano group, carbamoyl group, aliphatic oxycarbonyl group, aryloxycarbonyl group, hydroxyl group, aliphatic oxy group, carbamoyloxy group, heterocyclic oxy group, aliphatic oxycarbonyloxy group, carbamoylamino group, sulfamoylamino group, aliphatic oxycarbonylamino group, aliphatic sulfonylamino group, arylsulfonylamino group, aliphatic thio group, arylthio group, aliphatic sulfonyl group, arylsulfonyl group, sulfamoyl group, imido group or sulfo group, is preferred, an embodiment wherein Rc, is aliphatic group, carbamoyl group, aliphatic oxycarbonyl group, aryloxycarbonyl group, aliphatic oxy group, aliphatic oxycarbonyloxy group, carbamoylamino group, sulfamoylamino group, aliphatic oxycarbonylamino group, aliphatic sulfonylamino group, arylsulfonylamino group, aliphatic sulfonyl group, arylsulfonyl group, sulfamoyl group, imido group or sulfo group, is more preferred, and an embodiment wherein Rc₁ is carbamoyl group, aliphatic oxycarbonyl group, aliphatic oxy group, aliphatic oxycarbonyloxy group, carbamoylamino group, aliphatic oxycarbonylamino group, arylsulfonyl group, imido group or aliphatic sulfonyl group, is the most preferred.

Similarly, from the viewpoint of exhibiting the effect of the invention more effectively, an embodiment wherein Rc₂ is an aliphatic group, N-alkylacylamino group, aliphatic oxy group, aliphatic oxycarbonyl group, aliphatic sulfonyl group, aliphatic thio group, arylthio group, sulfo group, carboxyl group or a halogen atom, is preferred, and an embodiment wherein Rc₂ is an aliphatic group or a halogen atom, is more preferred. Similarly, from the viewpoint of exhibiting the effect of the invention more effectively, an embodiment wherein cq is 0, is preferred. Further similarly, from the viewpoint of exhibiting the effect of the invention more effectively, an embodiment wherein M is VO, Mn, Co, Ni, Cu, Zn or Mg, is preferred, an embodiment wherein M is VO, Co, Cu or Zn, is more preferred, and an embodiment wherein M is Cu, is the most preferred. In addition, an embodiment wherein cm is 0, is preferred, and an embodiment wherein cn is 1 or 2, is preferred and an embodiment wherein cn is 1, is more preferred.

From the viewpoint of exhibiting the effect of the invention even more effectively, in the formula (11-2), an embodiment wherein the Rc₁ is a halogen atom, aliphatic group, cyano group, carbamoyl group, aliphatic oxycarbonyl group, aryloxycarbonyl group, hydroxyl group, aliphatic oxy group, carbamoyloxy group, heterocyclic oxy group, aliphatic oxy carbonyloxy group, carbamoylamino group, sulfamoylamino group, aliphatic oxycarbonylamino group, aliphatic sulfonylamino group, arylsulfonylamino group, aliphatic-thio group, arylthio group, aliphatic sulfonyl group, arylsulfonyl group, sulfamoyl group, imido group or sulfo group; M is VO, Co, Cu or Zn; cq is 0; cm is 0; and cn is 1, is preferred. Moreover, an embodiment wherein Rc₁ is an aliphatic group, carbamoyl group, aliphatic oxycarbonyl group, aryloxycarbonyl group, aliphatic oxy group, aliphatic oxycarbonyloxy group, carbamoylamino group, sulfamoylamino group, aliphatic oxycarbonylamino group, aliphatic sulfonylamino group, arylsulfonylamino group, aliphatic sulfonyl group, arylsulfonyl group, sulfamoyl group, imido group or sulfo group; M is VO, Co, Cu or Zn; cq is 0; cm is 0; and cn is 1, is more preferred.

Similarly, the viewpoint of exhibiting the effect of the invention even more effectively, an embodiment wherein Rc₁ is a carbamoyl group, aliphatic oxycarbonyl group, aliphatic oxy group, carbamoylamino group, aliphatic oxycarbonylamino group, aliphatic sulfonyl group, arylsulfonyl group or imido group; M is Cu; cq is 0; cm is 0; and cn is 1, is the most preferred.

Specific examples of the pigment (dye) represented by the formulas (II) to (II-2) (Exemplary compounds C-1 to C-59) are presented below, while the invention is not limited to these examples.

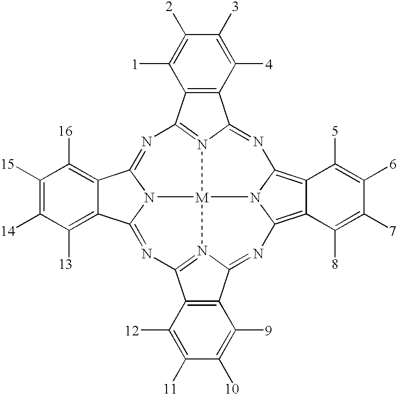

| | | Substituents at positions 1 or 4, 5 or | |
|---|---|---|---|
| Exemplary | | 8, 9 or 12, and 13 or 116 (other four | Substituents of the |
| compound | M | positions are occupied by H) | other eight positions |
| C-1 | Cu | 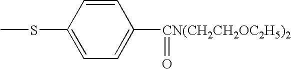 | H |
| C-2 | Cu | 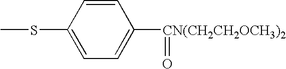 | H |
| C-3 | Cu | 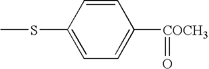 | H |
| C-4 | Cu | 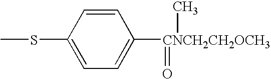 | H |
| C-5 | Cu | 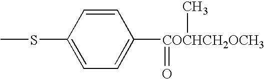 | H |
| C-6 | Cu | 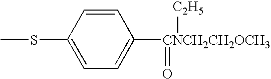 | H |
| C-7 | Cu | 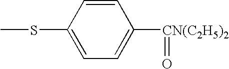 | H |
| C-8 | Cu | 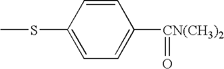 | H |

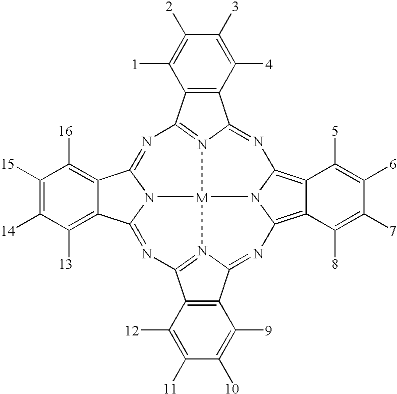

| | | Substituents at positions 1 or 4, 5 or | |
|---|---|---|---|
| Exemplary | | 8, 9 or 12, and 13 or 16 (other four | Substituents of the |
| compound | M | positions are occupied by H) | other eight positions |
| C-9 | Cu | 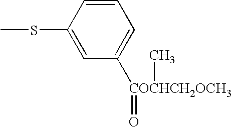 | H |
| C-10 | Cu | 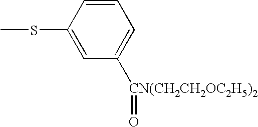 | H |
| C-11 | Cu | 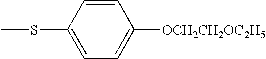 | H |
| C-12 | Cu | 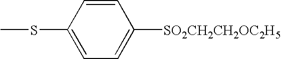 | CH₃ groups at position 2 or 3, 6 or 7, 10 or 11, and 14 or 15, and H at other four positions |
| C-13 | Cu | 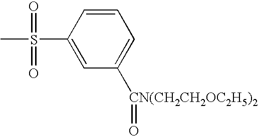 | H |
| C-14 | Cu | 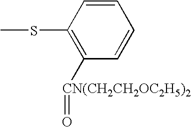 | H |
| C-15 | Cu | 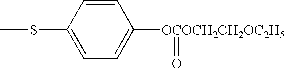 | CH₃ groups at position 2 or 3, 6 or 7, 10 or 11, and 14 or 15, and H at other four positions |

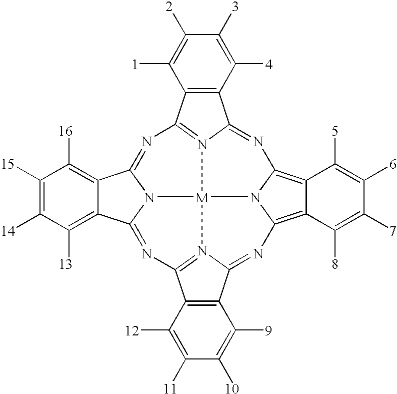

| | | Substituents at positions 1 or 4, 5 or | |
|---|---|---|---|
| Exemplary | | 8, 9 or 12, and 13 or 16 (other four | Substituents of the |
| compound | M | positions are occupied by H) | other eight positions |
| C-16 | Cu | 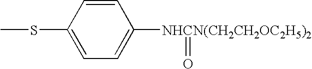 | H |
| C-17 | Cu | 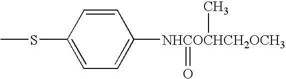 | H |
| C-18 | Cu | 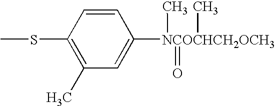 | H |
| C-19 | Cu | 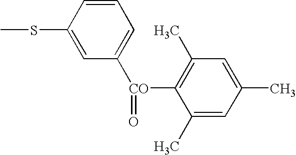 | H |
| C-20 | Cu | 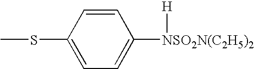 | H |
| C-21 | Cu | 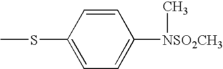 | H |
| C-22 | Cu | 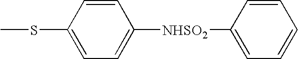 | H |

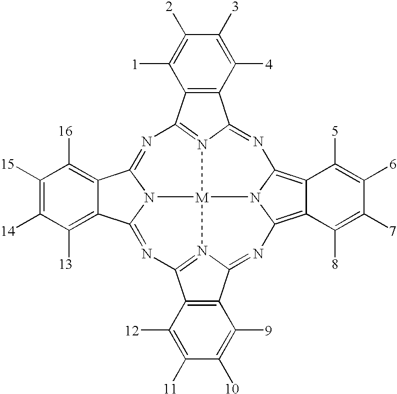

| | | Substituents at positions 1 or 4, 5 or 8, | |
|---|---|---|---|
| Exemplary | | 9 or 12, and 13 or 16 (other four | Substituents of the |
| compound | M | positions are occupied by H) | other eight positions |
| C-23 | Cu | 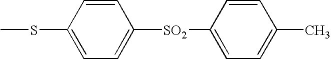 | H |
| C-24 | Cu | 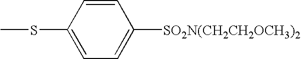 | H |
| C-25 | Cu | 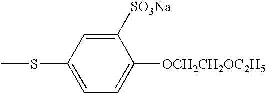 | H |
| C-26 | V═O | 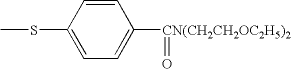 | H |
| C-27 | Co | 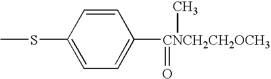 | H |
| C-28 | Co | 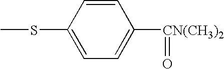 | H |
| C-29 | Zn | 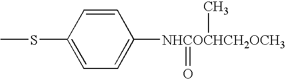 | H |
| C-30 | V═O | 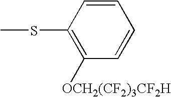 | H |

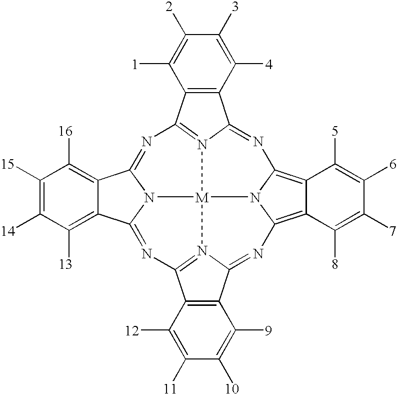

| | | Substituents at positions 1 or 4, 5 or | |
|---|---|---|---|
| Exemplary | | 8, 9 or 12, and 13 or 16 (otheer four | Substituents of the |
| compound | M | positions are occupied by H) | other eight positions |
| C-31 | Cu | 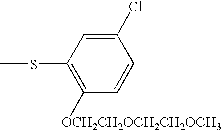 | H |
| C-32 | Cu | 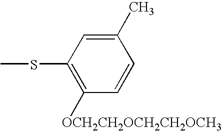 | H |
| C-33 | Cu | 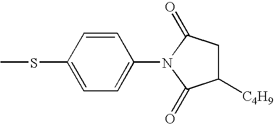 | H |
| C-34 | Cu | 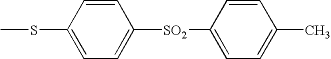 | H |
| C-35 | Cu | 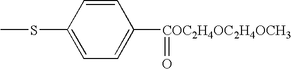 | H |

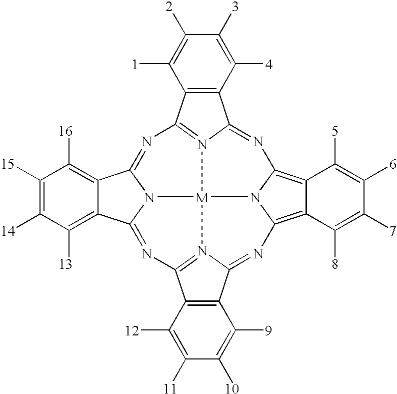

| | | Substituents at positions 2 or 3, 6 | |
|---|---|---|---|
| Exemplary | | or 7, 10 or 11, and 14 or 15 (other | Substituents of the |
| compound | M | four positions are occupied by H) | other eight positions |
| C-41 | Cu | 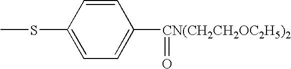 | H |
| C-42 | Cu | 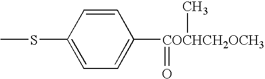 | H |
| C-43 | Cu | 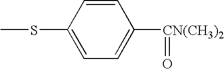 | H |
| C-44 | Cu | 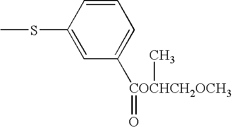 | H |
| C-45 | Co | 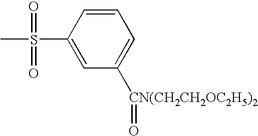 | H |

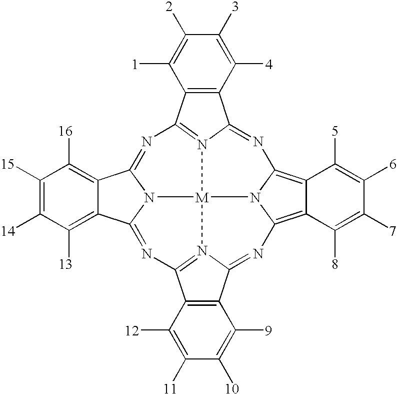

| | | Substituents at positions 2 or 3, 6 or | |
|---|---|---|---|
| Exemplary | | 7, 10 or 11, and 14 or 15 (other four | Substituents of the |
| compound | M | positions are occupied by H) | other eight positions |
| C-46 | Zn | 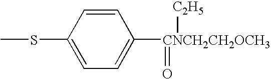 | H |
| C-47 | V═O | 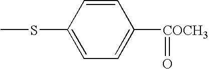 | H |
| C-48 | Cu | 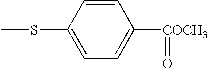 | CH₃ groups at position 1 or 4, 5 or 8, 9 or 12, and 13 or 16, and H at other four positions |
| C-49 | Cu | 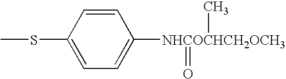 | H |

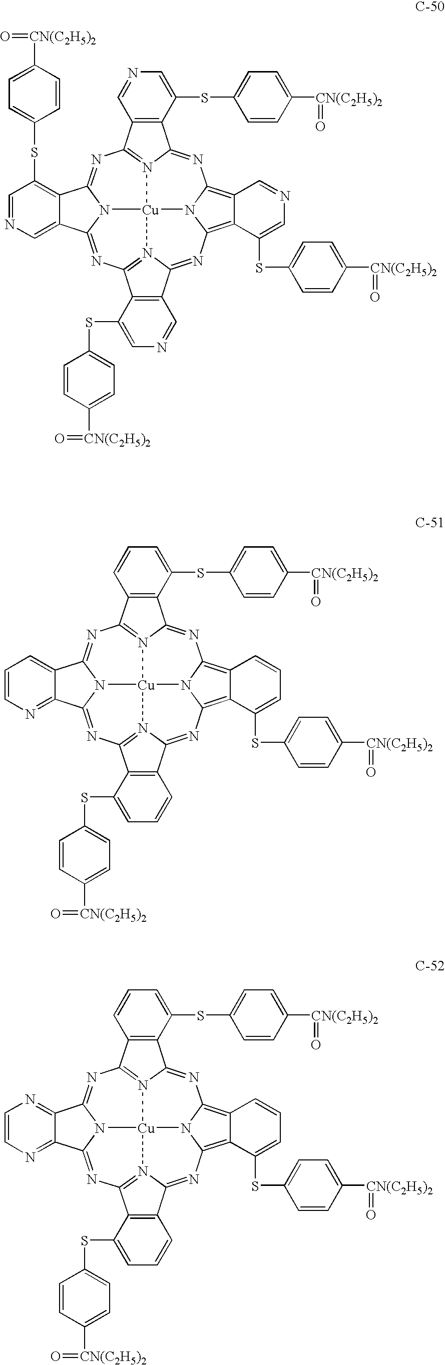

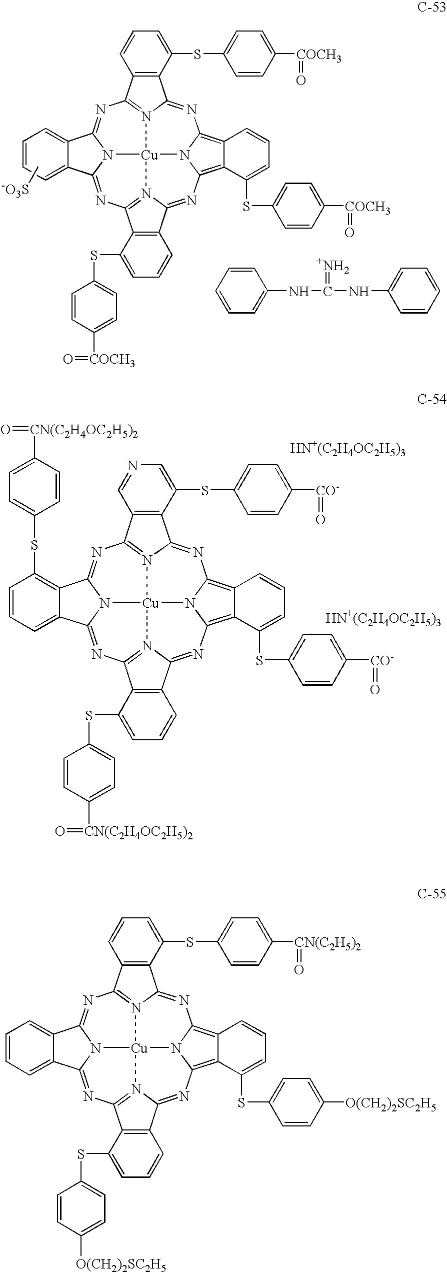

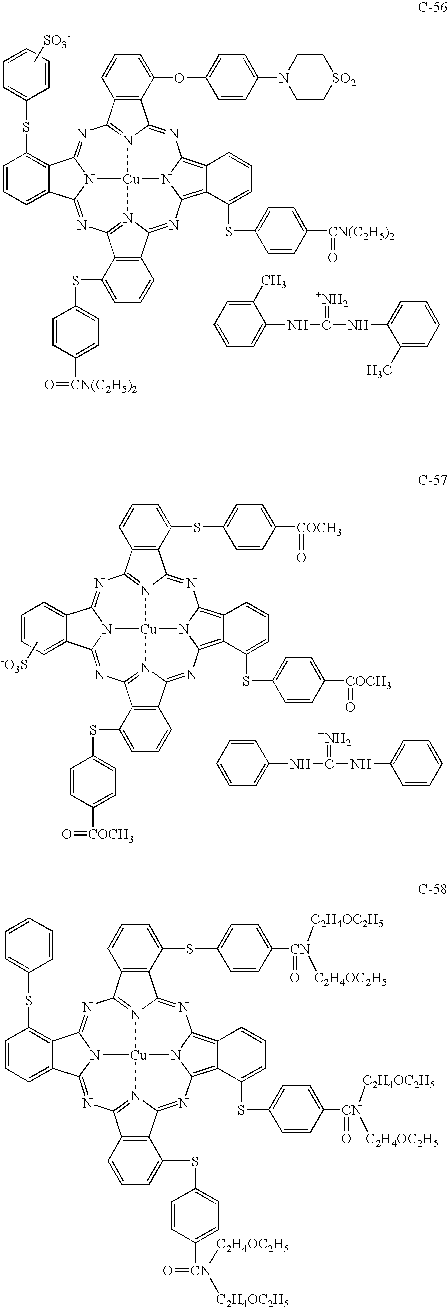

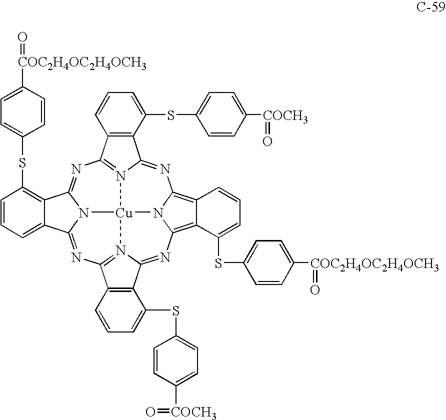

The concentration of an organic solvent-soluble dye accounting the whole solid content of the dye-cdntaining curable composition varies depending on the type of a dye. The concentration is usually 0.5 to 80% by weight, preferably 40 to 75% by weight, and particularly preferably 45 to 70% by weight.

(B) Radiation-sensitive Compound

The dye-containing curable composition of the invention comprises at least one kind selected from the radiation-sensitive compounds. The radiation-sensitive compound is able to effect chemical reactions such as generation of radicals, acids and bases by irradiation of radiation such as UV, deep UV, visible light, infrared light and electron beam. The radiation-sensitive compound is used for making the alkali-soluble binder insoluble by cross-linking, polymerization and decomposition of acidic groups, or for making coating layers insoluble to an alkali developer by inducing polymerization of the polymerizable monomer and oligomer remaining in the coating layer or cross-linking of the cross-linking agent.

It is particularly preferable that the dye-containing curable composition of the invention comprises at least any one of the photopolymerization initiator and the photo-acid generator, when the composition is constructed as a negative working composition. On the other hand, the dye-containing curable composition of the invention preferably contains an o-quinone diazide compound or photo-acid generator when the composition is constructed as a positive working composition.

Photopolymerization Initiator

The photopolymerization initiator is preferably used for constituting the dye-containing curable composition as a negative working composition.

The photopolymerization initiator is not particularly restricted so long as it is able to polymerize the monomer having a polymerizable group. The photopolymerization initiator is preferably selected from the viewpoint of its properties, polymerization initiation efficiency, absorbing wavelength, availability and cost. The photopolymerization initiator may be added to the positive working dye-containing curable composition comprising the o-quinone diazide compound, in the case of hardness of the pattern formed is enhanced.

As the photopolymerization initiator, (tri)halomethyltriazine compounds, oxime compounds, α-aminoketone compounds and acylphosphine (oxide) compounds are preferably used.

Examples of the (tri)halomethyl-triazine compound as the halomethyl-s-triazine compound include vinyl-halomethyl-s-triazine compounds described in JP-B No. 59-1281, 2-(naphto-1-yl)-4,6-bis-halomethyl-s-triazine compounds described in JP-A No. 53-133428, and 4-(p-aminophenyl)-2,6-di-halomethyl-s-triazine compounds.

Other specific examples include 2,4-bis(trichloromethyl)-6-p-methoxystyryl-s-triazine, 2,6-bis(trichloromethyl)-4-(3,4-methylenedioxyphenyl)-1,3,5-triazine, 2,6-bis(trichloromethyl)-4-(4-methoxyphenyl)-1,3,5-triazine, 2,4-bis(trichloromethyl)-6-(1-p-dimethylaminophenyl-1,3-butadienyl)-s-triazine, 2-trichloromethyl-4-amino-6-p-methoxystyryl-s-triazine, 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine 2-[4-(2-ethoxyethyl)-naphtho-1-yl]-4,6-bis-trichloromethyl-s-triazine, 2-[4-(2-butoxyethyl)-naphto-1-yl]-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromehtyl-s-triazine, 2-(6-methoxy-naphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, 4-[p-N,N-di(ethoxycarbonylmethyl)aminophenly]-2,6-di(trichloromethyl)-s-triazine, 4-[o-methyl-p-N,N-di(ethoxycarbonylmethyl)aminophenyl]2,6-di(trichloromethyl)-s-triazine, 4-[p-N,N-di(chloroethyl)aminophenyl]-2,6-di(trichloromethyl)-s-triazine, 2,6-di(trichloromethyl)-s-triazine, 4-(p-N-ethoxycarbonylmethylaminophenol)-2,6-di(trichloromethyl)-s-triazine, 4-[p-N,N-di(phenyl)aminophenyl]-2,6-di(trichloromethyl)-s-triazine, 4-(p-N-chloroethylcarbonylaminophenyl)-2,6-di(trichloromethyl)-s-triazine, 4-[p-N-(p-mehtoxyphenyl)carmonylaminophenyl]-2,6-di(trichloromethyl)-s-triazine, 4-[m-N,N-di(ethoxycarbonylmethyl)aminophenyl]-2,6-di(trichloromethyl)-s-triazine, 4-[m-bromo-p-N,N-di(ethoxycarbonylmethyl)aminophenyl]-2,6-di(trichloromethyl)-s-triazine, 4-[m-chloro-p-N,N-di(ethoxycarbonylmethyl)aminophenyl]-2,6-di(trichloromethyl)-s-triazine, 4-[m-fluoro-p-N,N-di(ethoxycarbonylmethyl)aminophenyl]-2,6-di(trichloromethyl)-s-tri azine,4-[o-bromo-p-N,N-di(ethoxycarbonylmethyl)aminophenyl]-2,6-di(trichloromethyl)-s-triazine, 4-[o-chloro-p-N,N-di(ethoxycarbonylmethyl)aminophenyl]-2,6-di(trichloromethyl)-s-triazine, 4-[o-fluoro-p-N,N-di(ethoxycarbonylmethyl)aminophenyl]-2,6-di(trichloromethyl)-s-triazine, 4-[o-bromo-p-N,N-di(chloroethyl)aminophenyl]-2,6-di(trichloromethyl)-s-triazine, 4-[o-chloro-p-N,N-di(chloroethyl)aminophenyl]-2,6-di(trichloromethyl)-s-triazine, 4-[o-fluoro-p-N,N-di(chloroethyl)aminohenyl]-2,6-di(trichloromethyl)-s-triazine, 4-[m-bromo-p-N,N-di(chloroethyl)aminohenyl]-2,6-di(trichloromethyl)-s-triazine, 4-[m-chloro-p-N,N-di(chloroethyl)aminophenyl]-2,6-di(trichloromethyl)-s-triazine, 4-[m-fluoro-p-N,N-di(chloroethyl)aminophenyl]-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethyl-aminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, and 4-(o-fluoro-p-N-chloroethylaminophenyl)-2,6-di(trichloromethyl)-s-triazine.

Other preferable examples include TAZ-series manufactured by Midori Kagaku Co., Ltd. (for example, trade name: TAZ-107, TAZ-110, TAZ-104, TAZ-109, TAZ-140, TAZ-204, TAZ-113 and TAZ-123).

Examples of the α-aminoketone compound include IRGACURE series manufactured by Ciba Specialty Chemicals (e.g., IRGACURE 907 and IRGACURE 369), 2-methyl-1-phenyl-2-morpholinopropan-1-one, 2-methyl-1-[4-(hexyl)phenyl]-2-morpholinopropan-1-one, and 2-ethyl-2-dimethylamino-1-(4-morpholinophenyl)-butanone-1.

Examples of the oxime compounds include, although not particularly limited hereto, 2-(O-benzoyloxime)-1-[4-(phenylthio)phenyl]-1,2-octandione, 1-(4-methylsulfanyl-phenyl)-butane-1,2-butane-2-oxime-O-acetate, 1-(4-methylsulfanyl-phenyl)-butan-1-oneoxime-O-acetate, hydroxyimino-(4-methylsulfanyl-phenyl)-acetic acid ethyl ester-O-acetate, hydroxyimino-(4-methylsulfanyl-phenyl)-acetic acid ethyl ester-O-benzoate, and 1-[6-(2-methylbenzoyl)-9-ethyl-9.H.-carbazol-3-yl]-ethan-1-oneoxime-O-acetate.

The acylphosphine (oxide) compounds are not particularly limited. Examples of the acylphosphine (oxide) compounds include IRGACURE 819, DAROCUR 4265 and DAROCUR TPO manufactured by Ciba Specialty Chemicals.

Known Photopolymerization initiators other than those described above may be used together with the dye-containing curable composition of the invention. Examples of them include vicinal polyketolaldonyl compounds described in U.S. Pat. No. 2,367,660, α-carbonyl compounds described in U.S. Pat. Nos. 2,367,661 and 2,367,670, acyloin ether compounds described in U.S. Pat. No. 2,448,828, aromatic acyloin compounds substituted with α-carbohydrates described in U.S. Pat. No. 2,722,512, polynuclear quinone compounds described in U.S. Pat. Nos. 3,046,127 and 2,951,758, combinations of trially imidazole dimer and p-aminophenyl ketone described in U.S. Pat. No. 3,549,367, and bemzothiazole compounds/trihalomethyl-s-triazine compounds described in JP-B No. 51-48516.

Specific examples include at least one of active halogen compounds selected from halomethyloxadiazole compounds and halomethyl-s-triazine compounds, 3-aryl-substituted coumalin compounds, lophine dimmers, benzophenone compounds, acetophenone compounds and their derivatives, and cyclopentadiene-benzene-iron complex and their salts.

Examples of the active halogen compound as the halomethyl oxadiazole compound include 2-halomethyl-5-vinyl-1,3,4-oxadiazole compounds described in JP-B No. 57-6096, 2-trichloromethyl-5-styryl-1,3,4-oxadiazole, 2-trichloromethyl-5-(p-cyanostyryl)-1,3,4-oxadiazole, and 2-trichloromethyl-5-(p-methoxystyryl)-1,3,4-oxadiazole.

Further, T series manufactured by PANCHIM, Ltd. are available; examples thereof include T-OMS, T-BMP, T-R, and T-B.

Also, IRGACURE series manufactured cy Ciba Specialty Chemicals are available; examples thereof include IRGACURE 651, IRGACURE 184, IRGACURE 500, IRGACURE 1000, IRGACURE 149, IRGACURE 261, and DAROCUR 1173.

In addition, 4,4′-bis(diethylamino)-benzophenone, 2-(O-benzoyloxime)-1-[4-(phenylthio)phenyl]-1,2-octandione, 2-benzyl-2-dimethylamino-4-morpholinobutyrophenone, 2,2-dimethoxy-2-phenylacetophenone, 2-(o-chlorophenyl)-4,5-diphenylimidazolyl dimer, 2-(o-fluorophenyl)-4,5-diphenylimidazolyl dimer, 2-(o-methoxyphenyl)-4,5-diphenylimidazolyl dimer, 2-(p-methoxyphenyl)-4,5-diphenylimidazolyl dimer, 2-(p-dimethoxyphenyl)-4,5-diphenylimidazolyl dimer, 2-(2,4-dimethoxyphenyl)-4,5-diphenylimidazolyl dimer, 2-(p-methylmercaptophenyl)-4,5-diphenylimidazolyl dimer, benzoin isopropyl ether and the like are suitably used.

Sensitizers and light stabilizers may be used together with these photopolymerization initiators. Specific examples of them include benzoin, benzoin methylether, 9-fluorenone, 2-chloro-9-fluorenone, 2-methyl-9-fluorenone, 9-anthrone, 2-bromo-9-anthrone, 2-ethyl-9-anthrone, 9,10-anthraqunone, 2-ethyl-9,10-anthraquinone, 2-t-butyl-9,10-anthraquinone, 2,6-dichloro-9,10-anthraquinone, xanthone, 2-methylxanthone, 2-methoxyxanthone, thioxanthone, 2,4-diethylthioxanthone, acrydone, 10-butyl-2-chloroacrydone, benzyl, banzalacetone, p-(dimethylamino)phenylstyrylketone, p-(dimethylamino)phanyl-p-methylstyrrylketone, dibenzophenone, p-(dimethylamino)benzophenone (or Michler's ketone), p-(diethylamino)benzophenone, benzoanthrone, and benzothiazole compounds described in JP-B No. 51-48516, Tinuvin 1130 and Tinuvin 400.

The content of the photopolymerization initiator in the dye-containing curable composition is preferably 0.01 to 50% by weight, more preferably 1 to 30% by weight, and particularly preferably 1 to 20% by weight based on the solid content of a monomer (weight). When the content of the photopolymerization initiator is less than 0.01% by weight, it is difficult to process the polymerization. On the other hand, when the content of the photopolymerization initiator exceeds 50% by weight, the polymerization rate is increased, but the molecular weight may be decreased and the coating strength may be weakened.

Heat Polymerization Inhibitor

A heat polymerization inhibitor is preferably added on addition to the additives above, and preferable examples thereof include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol) and 2-mercaptobenzimidazole.

O-Quinone Diazide Compounds

The o-Quinone diazide compounds suitable for constructing the dye-containing curable composition into a positive composition will be described below. The o-quinone-diazide compound has at least one o-quinone-diazide group.

Examples of the o-quinone-diazide compound include ester of 1,2-naphthoquinone-2-diazide-5-sulfonylchloride and phenol-formaldehyde resin or cresol-formaldehyde resin; ester of 1,2-naphthoquinone-2-diazide-5-sulfonylchloride and pyrogallol-acetone resin described in U.S. Pat. No. 3,635,709; ester of 1,2-naphthoquinone-2-diazide-5-sulfonylchloride and resorcin-benzaldehyde resin described in JP-B No. 63-13528; ester of 1,2-naphthoquinone-2-diazide-5-sulfonylchloride and resorcin-pyrogallol-acetone co-condensation resin described in JP-B No. 62-44257; esterified products of polyester having hydroxyl groups at the terminals with 1,2-naphthoquinone-2-diazide-5-sulfonylchloride described in JP-B No. 56-45127; esterified products of homopolymers of N-(4-hydroxyphenyl)methacrylamide or copolymers of the monomer with other copolymerizable monomers with 1,2-naphthoquinone-2-diazide-5-sulfonylchloride described in JP-B No. 50-24641; esters of 1,2-naphthoquinone-2-diazide-5-sulfonylchloride with bisphenol-formaldehyde resins described in JP-B No. 54-29922; esterified products of homopolymers of p-hydroxystyrene or copolymers of the monomer with other copolymerizable monomers with 1,2-naphthoquinone-2-diazide-5-sulfonylchloride described in JP-B No. 52-36043; and esters of 1,2-naphthoquinone-2-diazide-5-sulfonylchloride and polyhydroxybenzophenone.

Examples of known o-quinone-diazide compounds that can be used in the invention include those described in JP-A Nos. 63-80254, 58-5737, 57-111530, 57-111531, 57-114138, 57-142635 and 51-36129, JP-B Nos. 62-3411, 62-51459 and 51-483.

The content of the o-quinone-diazide compound in the dye-containing curable coinposition. is usually 5 to 60% by mass, preferably 10 to 40% by mass, relative to the total solid content (mass) of the composition.

Photo-acid Generator

The photo-acid generator generates an acid by decomposition by irradiate of an active light or a radiation. The photo-acid generator will be described below. Known agents may be used as the photo-acid generator.

Examples of the photo-acid generator include diazonium salts described in S. I. Schlesinger, Photogr. Sci. Eng., 18, 387 (1974) and T. S. Bal et al., Polymer, 21, 423 (1980); ammonium salts described in U.S. Pat. Nos. 4,069,055 and 4,069,056 and JP-A No. 3-140140; phosphonium salts described in D. C. Necker et al., Macromolecules, 17, 2468 (1984), C. S. Wen et al., Teh. Proc. Conf. Rad. Curing ASIA, p.478, Tokyo, Oct (1988), U.S. Pat. Nos. 4,069,055 and 4,069,056; iodonium salts described in J. V. Crivello et al., Macromolecules, 10(6), 1307 (1977), Chem. & Eng. News, Nov. 28, p.31(1988), EP No. 104,143, U.S. Pat. Nos. 339,049 and 410,201, and JP-A Nos. 2-150848 and 2-296514; and sulfonium salts described in J. V. Crivello et al., Polymer J., 17, 73 (1985), J. V. Crivello et al., J. Org. Chem., 43, 3055 (1978), W. R. Wattetal, J. Polymer Sci., Polymer Chem. Ed., 22, 1789 (1984), J. V. Crivello et al., Polymer Bull., 14, 279 (1985), J. V. Crivello et al., Macromolecules, 14(5), 1141 (1981), J.V. Crivello et al., J. Polymer Sci. Polymer Chem. Ed., 17, 2877 (1979), EP Nos. 370,693, 233,567, 297,443 and 297,442, U.S. Pat. Nos. 3,902,114, 4,933,377, 410,201, 339,049, 4,760,013, 4,734,444 and 2,833,827, DE Nos. 2,904,626, 3,604,580 and 3,604,581;

selenonium salts described in J. V. Crivello et al., Macromolecules, 10(6), 1307 (1977), J. V. Crivello et al., and J. Polymer Sci., Polymer Chem. Ed., 17, 1047 (1979); onium salts such as arsonium salts described in C. S. Wen et al., Teh. Proc. Conf. Rad. Curing ASIA, p478, Tokyo, Oct. (1988); organic halogenated compounds described in U.S. Pat. No. 3,905,815, JP-B No. 46-4605, JP-A Nos. 48-36281, 55-32070, 60-239736, 61-169835, 6-169837, 62-58241, 62-212401, 63-70243 and 63-298339; organic metals or organic halides described in K. Meier et, al., J. Rad. Curing, 13(4), 26 (1986), T. P. Gill et al., Inorg. Chem., 19, 3007 (1980), D. Astruc, ACC. Chem. Res., 19(12), 377 (1896), and JP-A No. 2-161445; photo-acid generators having o-nitrobenzyl protective groups described in S. Hayase et al., J. Polymer Sci., 25, 753 (1987), E. Reichmanis et al., J. Polymer Sci., Polymer Chem. Ed., 23, 1 (1985), Q. Q. Zhu et al., J. Photochem., 36, 85, 39, 317 (1987), B. Amit et al., Tetrahedron Lett., (24), 2205 (1973), D. H. R. Barton et al., J. Chem. Soc., 3571 (1965), P. M. Collins et al., J. Chem. Soc., Perkin I, 1695 (1975), M. Rudinstein et al., Tetrahedron Lett., 17, 1445 (1975), J. W. Walker et al., J. Am. Chem. Soc., 110, 7170 (1988), S. C. Busman et al., J. Imaging Technol., 11(4), 191 (1985), H. M. Houlihan et al., Macromolecules, 21, 2001 (1988), P. M. Collinsetal, J. Chem. Soc., Chem. Commun., 532 (1972), S. Hayase et al., Macromolecules, 18, 1799 (1985), E. Reichmanis et al., J. Electrochem. Soc., Solid State Sci. Technol., 130(6), F. M. Houlihan et al., Macromolecules, 21, 2001 (1988), EP Nos. 0,290,750, 046,083, 156,535, 271,851 and 0,388,343, U.S. Pat. Nos. 3,901,710 and 4,181,531, and JP-A Nos. 60-198538 and 53-133022; and compounds that generate sulfonic acid by photodecomposition represented by iminosulfnate described in M. Tunooka et al., Polymer Preprints Japan, 35(8), G. Bemer et al., J. Rad. Curing, 13(4), W. J. Mijs et al., Coating technol., 55(697), 45(1983), Akzo, H. Adachi et al., Polymer Preprints, Japan, 37(3), EP Nos. 0,199,672, 84,515, 199,672, 044,115 and 0,101,122, U.S. Pat. Nos. 4,618,564, 4,371,605 and 4,431,774, and JP-A Nos. 64-18143, 2-245756 and 4-365048; and disulfone compounds described in JP-A No. 61-166544.

The content of the photo-acid generator in the dye-containing curable composition is usually 0.001 to 40% by mass, preferably 0.01 to 20% by mass, and more preferably 0.1 to 5% by mass relative to the total mass (solvent is excluded) of the composition.

(C) Transition Metal Complex

The dye-containing curable composition of the invention comprises at least one kind selected from transition metal complex in which the maximum value of a molar absorption coefficient ε in a visible light range is smaller than that of the organic solvent-soluble dye. Negative-type, neutral or positive monofunctional ligands or polyfunctional ligands are coordinated around a transition metal atom or transition metal ion at the center in transition metal complex. Using transition metal complex permits light fastness of the dye-containing curable composition and of the color filter constructed by using the composition to be effectively improved.

In the present invention, the maximum value of a molar absorption coefficient ε in a visible light range (380 to 780 nm) of transition metal complex is smaller than that of the organic solvent-soluble dye.

Transition metal complex preferably has the maximum value of a molar absorption coefficient ε in the visible light range (380 to 780 nm) of 0 to 8,000 from the viewpoint of clearness of the color. More preferably transition metal complex has the maximum value of a molar absorption coefficient ε of 0 to 6,000, most preferably 0 to 3,000.

Examples of the transition metal atoms in transition metal complexs, and transition metals constituting the transition metal ions include scandium (Sc), titanium (Ti), vanadium (V), chromium (Cr), manganese (Mn), iron (Fe), cobalt (Co), nickel (Ni), copper (Cu), yttrium (Y), zirconium (Zr), niobium (Nb), molybdenum (Mo), technetium (Tc), ruthenium (Ru), rhodium (Rh), palladium (Pd), silver (Ag), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), iridium (Ir), platinum (Pt) and gold (Au).

Preferable examples of transition metal complex include those constructed by transition metals belonging to the first series (or fourth period), for example, those constructed by scandium (Sc), titanium (Ti), vanadium (V), chromium (Cr), manganese (Mn), iron (Fe), cobalt (Co), nickel (Ni) and copper (Cu).

Among these, transition metal complex constructed by Mn, Fe, Co, Ni and Cu is preferred.

More preferable examples of transition metal complexs include those constructed by the transition metals belonging to the fourth period and forming divalent transition metal ions, or those constructed by Ti²⁺, V²⁺, Cr²⁺, Mn²⁺, Fe²⁺, Co²⁺, Ni²⁺ and CU²⁺.

Particularly preferable examples of transition metal complexs include those constructed by Mn²⁺, Fe²⁺, Co²⁺, Ni²⁺ and Cu²⁺, even more preferable examples include those constructed by Co²⁺ and Ni²⁺, and the most preferable examples include those constructed by Co²⁺.

Transition metal complex is preferably obtained by coordinating a ligand in which the maximum value of a molar absorption coefficient ε in the visible light range is 0 to 3000 by the single ligand, on a transition metal. The ligand has the maximum value of a molar absorption coefficient ε in a visible light range of more preferably 0 to 2000 by the single ligand, further preferably 0 to 1000.

The molecular weight of a ligand in transition metal complex is preferably 20 or more but less than 300 from the viewpoint of having light-fastness and alkali developability.

Commonly used ligands may be used for the ligand in transition metal complex, and either monodentate ligands, for example, bidentate ligands may be suitably used.

Specific example of the above-mentioned ligand includes fluoro, chloro, bromo, iodo, hydroxo, aqua, tetrahydrofuran, ethylene glycol dimethyl ether, acetonitrile, benzonitrile, oxo, peroxyo, carbonyl, carbonate, oxalato, acetato, ethanolato, 1-butanethiolato, thiophenolato, 2,2′-thiobis(4-t-octyl)phenolate, acetylacetonato, 2,2,6,6-tetramethyl-3,5-heptadionato, trifluoroacetylacetonato, hexafluoroacetylacetonato, ethylacetoacetonato, thiocyanato, isothiocyanato, diethyldithiocarbamate, di-n-butyldithiocarbamate, cyano, amine, dimethylamine, diethylamine, tetraethylammonium, piperidine, N-methylaniline, pyridine, 2-phenylpyridine, ethylenediamine, N,N,N′,N′-tetramethylethylenediamine, 1,2-diaminocyclohexane, 2,2′-pyridine, 1,10-phenanthroline, ethylenediamine tetraacetate, 1,4,8,11-tetraazacyclotetradecane, tris(2-aminoethyl)amine, sulfato, nitro, nitrite, phosphato, diisopropyldithiophosphate, diethyldithiophosphate, triethylphosphine, tributylphosphine, tricyclohexylphosphine, dimethylphenylphosphine, triphenylphosphine, diphenylphosphine, tricyclohexylphosphine, cyclopentadiene, pentamethylcyclopentadiene, cyclooctene, 1,5-cyclooctadiene, bicyclo[2,2,1]hepta-2,5-diene, benzene, naphthalene, aryl and the like.

As preferable ligands among the above-mentioned ligands, ligands not containing an aromatic ring therein are mentioned. Specific examples include fluoro, chloro, bromo, iodo, hydroxo, aqua, tetrahydrofuran, ethylene glycol dimethyl ether, acetonitrile, oxo, peroxyo, carbonyl, carbonato, oxalato, acetato, ethanolato, 1-butanethiolato, acetylacetonato, 2,2,6,6-tetramethyl-3,5-heptadionato, trifluoroacetylacetonato, hexafluoroacetylacetonato, ethylacetoacetonato, thiocyanato, isothiocyanato, diethyldithiocarbamate, diethyldithiocarbamate, cyano, amine, dimethylamine, diethylamine, tetraethylammonium, ethylenediamine, N,N,N′,N′-tetramethylethylenediamine, 1,2-diaminocyclohexane, ethylenediamine tetraacetato, 1,4,8,11-tetraazacyclotetradecane, tris(2-aminoethyl)amine, sulfato, nitro, nitrito, phosphato, diisopropyldithiophosphate, diethyldithiophosphate, triethylphosphine, tributylphosphine, tricyclohexylphosphine, cyclooctene, 1,5-cyclooctadiene, bicyclo[2,2,1]hepta-2,5-diene, aryl and the like.

More preferable examples of ligands include acetate, acetylacetonate, trifluoroacetylacetonate, hexafluoroacetylacetonate, thiocyanate, diethyldithiocarbamate and di-n-butyldithiocarbamate.

The content of transition metal complex in the dye-containing curable composition is preferably 40% by mass or less, more preferably 30% by mass or less, further preferably 20% by mass or less, and most preferably 0.5 to 15% by mass with respect to the organic solvent-soluble dye.

While specific examples of transition metal complex are listed below, the invention is not restricted to these examples.

Examples of transition metal complex include α-methylferrocene methanol, titanium(III) chloride tetrahydrofuran complexes, titanium(IV) chloride tetrahydrofuran complex, zirconium(IV) chloride tetrahydrofuran complex, hafnium chloride tetrahydrofuran complex, vanadium(III) chloride tetrahydrofuran complex, 1-butanethiol copper(I) salt, tetra(dimethylamino)titanium, tetra(diethylamino)titanium, thiophenol copper(I) salt, μ-dichlorotetraethylene dirhodium, potassium trichloro(ethylene)platinate(II) monohydrate, allylpalladium chloride dimer, chloro(1,5-hexadiene)rhodium(I) dimer, chlorobis(cyclooctene)rhodium(I) dimer, chlorobis(cyclooctene)iridium(I) dimer, (1,5-cyclooctadiene)dimethylplatinum(II), dichloro(1,5-cyclooctadiene)ruthenium(I) polymer, dicyclo(1,5-cyclooctadiene)palladium(II), dichloro(1,5-cyclooctadiene)platinum(II), dibromo(1,5-cyclooctadiene)platinum(II), (1,5-cyclooctadiene)diiodoplatinum(II), bis(1,5-cyclooctadiene)rhodium(I) tetrafluoroboron, bis(1,5-cyclooctadiene)nickel(0), chloro(1,5-cyclooctadiene)rhodium(I) dimer, chloro(1,5-cyclooctadiene)iridium(I) dimer, (bicyclo[2.2.1]hepta-2,5-diene)dichlororuthenium(II) polymer, bis(bicyclo[2.2.1]hepta-2,5-diene)rhodium(I) perchlorate, (bicyclo[2.2.1]hepta-2,5-diene)chlororhodium(I) dimer, (bicyclo[2.2.1]hepta-2,5-diene)dichloropalladium(II), titanium(III) chloride ethyleneglycol dimethylether complex, niobium(III) chloride ethyleneglycol dimethylether complex, niobium(III) bromide ethyleneglycol dimethylether complex, nickel(II) bromide ethyleneglycol dimethylether complex, niobium(IV) chloride tetrahydrofuran complex, chromium(III) chloride tetrahydrofuran complex, copper(I) bromide dimethylsulfide complex, cis-bis(diethylsufide)platinum(II) chloride, (dimethylsulfide)gold(I) chloride, tris(ethylenediamine)cobalt(III) chloride dihydrate, tris(ethylenediamine)rhodium(III) chloride trihydrate, dichloro(ethylenediamine)palladium(II), dichloro(ethylenediamine)platinum(II), dichlorobis(ethylenediamine)palladium(II), dichloro(N,N,N′,N′-tetramethylethylenediamine)palladium (II), bis(cis-1,2-diaminocyclohexane)nickel(II) chloride, (1,2-diaminocyclohexane)platinum(II) chloride, titanium(IV)(triethanolaminate)isopropoxide, bis(tetraethylammonium)tetrabromocopper(II), bis(tetraethylammonium)tetrabromomanganese(II), bis(tetraethylammonium)tetrabromocobalt(II), tetraphenylphosphonium acetate dichlorodioxoruthenium(IV), Copper(II) acetylacetonate, lanthanum acetylacetonate hydrate, cerium(III) acetylacetonate hydrate, europium(III) acetylacetonate hydrate, gadolinium (III) acetylacetonate hydrate, yttrium acetylacetonate hydrate, titanium(IV) oxide acetylacetonate, zirconium(IV) acetylacetonate, vanadium(III) acetylacetonate, vanadyl acetylacetonate, chromium(III) acetylacetonate, bis(acetylacetonate) molybdenum (IV) dioxide, manganese(II) acetylacetonate, manganese(III) acetylacetonate, iron(III) acetylacetonate, cobalt(II) acetylacetonate, cobalt(III) acetylacetonate, nickel(II) acetylacetonate, ruthenium(III) acetylacetonate, rhodium(III) acetylacetonate, palladium(II) acetylacetonate, iridium(III) acetylacetonate, platinum(II) acetylacetonate, (1,5-cyclooctadiene)(2,4-pentadionato) rhodium(I), (bicyclo[2.2.1 ]hepta-2,5-diene)(2,4-pentadionato) rhodium(I), titanium diisopropoxybis(2,4-pentanedionato), copper bis(2,2,6,6-tetramethyl-3,5-heptanedionato), yttrium tris(2,2,6,6-tetramethyl-3,5-heptanedionato), neodymium tris(2,2,6,6-tetramethyl-3,5-heptanedionato), erbium tris(2,2,6,6-tetramethyl-3,5-heptanedionato), samarium tris(2,2,6,6-tetramethyl-3,5-heptanedionato), thulium tris(2,2,6,6-tetramethyl-3,5-heptanedionato), nickel(II) bis(2,2,6,6-tetramethyl-3,5-heptanedionato), lanthanum tris(2,2,6,6-tetramethyl-3,5-heptanedionato), praseodymium tris(2,2,6,6-tetramethyl-3,5-heptanedionato), europium tris(2,2,6,6-tetramethyl-3,5-heptanedionato), gadolinium tris(2,2,6,6-tetramethyl-3,5-heptanedionato), dysprosium tris(2,2,6,6-tetramethyl-3,5-heptanedionato), holmium tris(2,2,6,6-tetramethyl-3,5-heptanedionato), ytterbium tris(2,2,6,6-tetramethyl-3,5-heptanedionato), thallium(I) trifluoroacetylacetonate, copper(II) trifluoroacetylacetonate, zirconium(IV) trifluoroacetylacetonate, thallium(I) hexafluoroacetylacetonate, copper(II) hexafluoroacetylacetonate hydrate, yttrium hexafluoroacetylacetonate dihydrate, manganese(II) hexafluoroacetylacetonate trihydrate, cobalt(II) hexafluoroacetylacetonate hydrate, nickel(II) hexafluoroacetylacetonate hydrate, palladium(II) hexafluoroacetylacetonate, (acetylacetonate)(1,5-cyclooctadiene)iridium(I), praseodymium tris[3-(trifluoro-methylhydroxymethylene)-(+)-camphorate], europium tris[3-(trifluoro-methylhydroxymethylene)-(+)-camphorate], erbium tris[3-(trifluoro-methylhydroxymethylene)-(+)-camphorate], ytterbium tris[3-(trifluoro-methylhydroxymethylene)-(+)-camphorate], bis[3-(heptafluoropropylhydroxymethylene)-(+)-camphorate]oxo vanadium, praseodymium tris[3-(heptafluoropropylhydroxymethylene)-(+)-camphorate], preseodymium tris[3-heptafluoropropylhydroxymethylene]-(−)-camphorate, europium tris[3-heptafluoropropylhydroxymethylene]-(+)-camphorate, europium tris[3-heptafluoropropylhydroxymethylene]-(−)-camphorate, erbium tris[3-heptafluoropropylhydroxymethylene]-(+)-camphorate, erbium tris[3-heptafluoropropylhydroxymethylene]-(−)-camphorate, ytterbium tris[3-heptafluoropropylhydroxymethylene]-(+)-camphorate, ytterbium tris[3-heptafluoropropylhydroxymethylene]-(−)-camphorate, diamine(1,1-cyclobutanedicarboxylate) platinum(II), titanium(IV) bis(ammonium lactate)dihydroxide, titanium(IV) bis(ethylacetoacetate)diiopropoxide, [1,2,3,4-tetrakis(methoxycarbonyl)-1,3-butadiene-1,4-diyl]platinum, bis(acetnitrile)dichloro palladium(II), bis(acetnitrile)chloronitro palladium(II), bis(acetonitrile) molybdenum(IV) chloride, tetrakis(acetonitrile) palladium(II) tetrafluoroborate, cis-bis(acetnitrile)dichloro platinum(II), tetrekis(acetnitrile) copper(I) heafluorophosphate, tetraethylammonium bis(acetnitrile)tetrachloro ruthenium(III), bis(diethyldithiocarbamate)dioxo molybdenum(VI), dichlorobis(triethylphosphine) palladium(II), cis-dichlorobis(triethylphosphine) platinum(II), trans-dichlorobis(triethylphosphine) platinum(II), dichlorobis(tributylphosphine) nickel(II), dibromobis(tributylphosphine) nickel(II), oxalate bis(triethylphosphine) platinum(II) hydrate, dichlorobis(tricyclohexylphosphine) pafladium(II), iodo(trimethylphosphite) copper(I), iodo(triethylphosphite) copper(I), chloro(pyridine)bis(deimehtylglyoximate) cobalt(III), benzene ruthenium(II) chloride dimer, dichloro(p-cimene) ruthenium(II) dimer, (+)-di-μ-chlorobis{2-[1-(dimethylamino)]ethyl}phenyl-C,N-dipalladium, di-μ-chlorobis{2-[1-(diethylamino)]ethyl}phenyl-C,N-dipalladium, di-μ-chlorobis{2-(dimethylamino)]methyl}phenyl-C,N-dipalladium, bis(salicylaldehyde) cobalt(II) dihydrate, tris(dibenzylideneacetone) dipalladium(O), tris(dibenzoylmethanate) iron(III), bis(benzonitrile)dichloro palladium(II), cis-bis(benzonitrile)dichloro platinum(II), trichlorotris(dimethylphenylphosphine) rhenium(III), [tris(dimethylphenylphosphine)](2,5-norbornadiene) rhodium(I) hexafluorophosphate, tetrakis(methyldiphenylphosphine) palladium(0), (1,5-cyclooctadiene)bis(methyldiphenylphosphine) iridium(I) hexafluorophosphate, tris(triphenylphosphine) copper(I) chloride, bis(triphenylphosphine) copper(I) nitrate, chloro(triphenylphosphine) gold(I), trichlorooxobis(triphenylphosphine) rhenium(V), iododioxobis(triphenylphosphine) rhenium(V), dichlorobis(triphenylphosphine) cobalt(II), chlorotris(triphenylphosphine) cobalt(I), tetrakis(triphenylphosphine) nickel(0), dichlorobis(triphenylphosphine) nickel(II), dibromobis(triphenylphosphine) nickel(II), dichlorotris(triphenylphosphine) ruthenium(II), dichlorotetrakis(triphenylphosphine) ruthenium(II), trans-dibromobis(triphenylphosphine) palladium(II), chlorotris(triphenylphosphine) rhodium(I), bromotris(triphenylphosphine) rhodium(I), nitrosyltris(triphenylphosphine) rhodium(I), dichlorobis(triphenylphosphine) palladium(II), tetrakis(triphenylphosphine) palladium(0), tetrakis(triphenylphosphine) platinum(0), cis-dichlorobis(triphenylphosphine) platinum(II), trans-dichlorobis(triphenylphosphine) platinum(II), dioxobis(triphenylphosphine) platinum(IV), ethylenebis(triphenylphosphine) platinum(0), (bocyclo[2.2.1 ]hepta-2,5-diene)[bis(triphenylphosphine)]rhodium(I) hexafluorophosphate, bis(acetate)bis(triphenylphosphine) palladium(II), trans-benzyl(chloro)bis(triphenylphosphine) palladium(II), dichlorobis[methylenebis(diphenylphosphine)]dipalladium, [1,2-bis(triphenylphosphino)ethane]iron(II) chloride, [1,2-bis(diphenylphosphino)ethane]cobalt(II) chloride, [1,2-bis(diphenylphosphino)ethane]nickel(II) chloride, [1,2-bis(diphenylphosphino)ethane]palladium(II) chloride, bis[1,2-bis(diphenylphosphino)ethane]palladium(0), [1,1,1-tris(diphenylphosphinomethyl)ethane]rhodium(I) chloride, (N-3-allyl)[(2S,3 S)-(+)-bis(diphenylphosphino)butane]palladium(II) perchlorate, (bicyclo[2.2.1 ]hepta-2,5-diene)[(2S,3 S)-(+)-bis(diphenylphosphino)butane]rhodium(I) perchlorate, [1,3-bis(diphenylphosphino)propane]dichloro nickel(II), [(R)-(+)-2,2′-bis(diphenylphosphino)1,1′-binaphthyl]chloro(p-cumene) ruthenium chloride, [(S)-(−)-2,2′-bis(diphenylphosphino) 1,1′-binaphthyl]chloro(p-cumene) ruthenium chloride, bis[(R)-(−)-2,2′-bis(diphenylphosphino)1,1′-binaphtyl]rhodium (I) perchlorate, [(R)-(+)-2,2′-bis(diphenylphosphino)1,1′-binaphthyl](1,5-cyclooctadiene) rhodium(I) perchlorate, [(S)-(−)-2,2′-bis(diphenylphosphino)1,1′-binaphthyl](1,5-cyclooctadiene) rhodium(I) perchlorate, [(R)-(+)-2,2′-bis(diphenylphosphino) 1,1′-binaphthyl]palladium(II) chloride, tetrakis(triphenylphosphite) nickel(0), tris[N-(diohenylphosphinyl)-p,p-diphenylphosphinic amidate-O,O′]praseodymium, bis(1,5-cyclooctadiene)bis(1H-pyrazolate) diiridium, tetrakis(pyridine)cobalt(II) bis(chromate), cis-dichlorobis(pyridine) platinum (II), (1,5-cyclooctadiene)(Pyridine)(tricyclohexylphosphine) iridium(I) hexafluorophosphate, trichlorobis(2-phenylpyridine) rhodium(III) dimer, tris(2,2′-bipyridine) iron(II) hexafluorophosphate, cis-bis(2,2′-bipyridine)dichloro ruthenium(II) hydrate, tris(2,2′-bipyridyl) ruthenium(II) chloride hexahydrate, (2,2′-bipyridine)dichloro palladium(II), (2,2′-bipyridine)dichloro platinum(II), dichloro(2,2′,6′,2″-terpyridine) platinum(II) dihydrate, dichloro(1,10-phenanthroline) copper(II), dibromo(1,10-phenanthroline) copper(II), dinitrate(1,10-phenanthroline) copper(II), tris(1,10-phenanthroline) iron(II) hexafluorophosphate, tris(1,10-phenanthroline) iron(III) hexafluorophosphate, tris(1,10-phenanthroline) ruthenium(II) chloride hydrate, dichloro(1,10-phenanthroline) palladium(II), dichloro(1,10-phenanthroline) platinum(II), N,N′-bis(salicylidene)ethylenediamino-cobalt(II), N,N′-bis(salicylidene)ethylenediamino nickel(II), bis(salicylideneiminate-3-peopyl)methylamino cobalt(II), (R,R)-(−)-N,N′-bis(3,5-di-t-butylsalicylidene)-1,2-cyclohexanediamino manganese(III) chloride, (S,S)—(+)-N,N′-bis(3,5-di-t-butylsalicylidene)-1,2-cyclohexanediamino manganese (III) chloride, N,N′-bis(salicylidene)dianilino cobalt(II), N,N′-bis(salicylidene)-1,2-phenylenediamino cobalt(II) hydrate, tris(cyclopentadienyl) scandium, bis(cyclopentadienyl) vanadium, bis(cyclopentadienyl) chromium, ferrocene, ferrocenium hexafluorophosphate, ferrocenium hexafluoroborate, bis(cyclopentadienyl) cobalt, bis(cyclopentadienyl)nickel, bis(cyclopentadienyl) ruthenium, cyclopentadienyl titanium trichloride, bis(cyclopentadienyl) titanium dichloride, bis(cyclopentadienyl) titanium pentasulfide, bis(cyclopentadienyl ) titanium bis(trifluoromethanesulfonate), bis(cyclopentadienyl) zircnium dichloride, bis(cyclopentadienyl) zirconium bis(trifluoromethane sulfonate), bis(cyclopentadienyl ) hafnium dichloride, bis(cyclopentadienyl) vanadium dichloride, bis(cyclopentadienyl) niobium dichloride, bis(cyclopentadienyl) molybdenum dichloride, bis(pentamethylcyclopentadienyl) manganese, 1,1′-dimethylferrocene, bis(pentamethylcyclopentadienyl) iron, 1,2-deferrocene ethane, butylferrocene, vinylferrocene, bis(2,4-cyclopentadiene-1-yl)[(4-methylbicyclo[2.2.1]heptane)-2,3-diyl]methylene]titanium, ferrocene methanol, 1,1′-ferrocenedimethanol, (dimethylaminomethyl)ferrocene, (R)-(+)-N,N-dimethy-1-ferrocenylethylamine, (S)-(−)-N,N,dimethyl-1-ferrocenylethylamine, ferrocene carboxyaldehyde, acetylferrocene, 1,1′-diacetylferrocene, ferrocene carboxylic acid, 1,1′-ferrocene dicarboxylic acid, dimethyl-1,1′-ferrocene dicarboxylate, 1,1″-[(4,4′-bipyperidine)-1,1′-diyldicarbonyl]bis[1′-(methoxycarbonylferrocene)], ferrocene acetonitrile, benzoylferrocene, 1,1′-bis(diphenylphosphino) ferrocene, (−)-(R)-1-[(S)-2-(diphenylphosphino)ferrocenyl]ethymethyl ether, (+)-(S)-1-[(R)-2-(diphenylphosphino)ferrocenyl]ethylmethylether, [1,1′-bis(diphenylphosphino)ferrocene]dichloropalladium(II), (−)-(R)-N,N-dimethyl-1-[(S)-2-(diphenylphosphino)ferrocenyl]ethylamine, (+)-(S)-N,N-dimethyl-1-[(S)-2-(diphenylphosphino)ferrocenyl]ethylamine, dichloro[(R)-N,N-dimethyl-1-[(S)-2-(dipenylphosphino)ferrocenyl]ethylamine]palladium, dichloro[(S)-N,N-dimehtyl-1-[(R)-2-(diphenylphosphino)ferrocenyl]ethylamine]palladium, (−)-(R)-N,N,-dimethyl-1-[(S)-1′,2-bis(diphenylphosphino)ferrocenyl]ethylamine, (+)-(S)-N,N-dimethyl-1-[(R)-1′,2-bis(diphenylphosphino)ferrocenyl]ethylamine, trans-4-[2-(1-ferrocenyl)-vinyl]-1-methylpyridinium iodide, chlorocyclopentanedienylbis(triphenylphosphine) ruthenium(II), (bicyclo[2.2.1]hepta-2,5-diene)[1,1′-bis(diphenilphosphino)ferrocene]ruthenium(I) perchlorate, bis(pentamethylcyclopentadienyl) zirconium dichloride, pentamethylcyclopentadienyl ruthenium(III) chloride polymer, pentamethylcyclopentadienyl rhodium chloride dimer, pentamethylcyclopentadienyl iridium(III) chloride dimer, cyclohexadienyl iron(0) tricarbonyltetrafluoroborate, cycloheptatriene chromium tricarbonyl, cycloheptatriene molybdenum tricarbonyl, cyclooctatetraene iron tricarbonyl, bicyclo[2.2.1]hepta-2,5-diene molybdenum tetracerbonyl, tricarbonyl(4-methoxy-1-methylcyclohexadene) iron tetrafluoroborate, tricarbonyl(2-methoxycyclohexadiene) iron tetrafluoroborate, tetramethylammonium(1-hydroxyethylidene)pentacarbonyl chromium, cis-tetracerbonylbis(pyperidine) molybdenum, (acetylacetonate)dicarbonyl rhodium(I), (acetylacetonate)dicarbonyl illidium(I), cyclopentadienyl molybdenum tricarbonyl dimer, cyclopentadienyl tungsten tricarbonyl dimer, cyclopentadienyl manganese tricarbonyl, cyclopentadienyl rhenium tricarbonyl, cyclopentadienyl iron dicarbonyl iodide, cyclopentadienyl iron dicarbonyl dimer, cyclopentadienyl cobalt dicarbonyl, cyclopentadienyl nickel carbonyl dimer, methylcyclopentadienyl molybdenum tricarbonyl dimer, (methylcyclopentadienyl)-manganese tricarbonyl, dicarbonylcyclopentadienyl(dimehtylsulfoniumethylide) iron tetrafluoroborate, benzene chromium tricarbonyl, mesitylene chromium tricarbonyl, mesitylene tungsten tricarbonyl, 1,2,3,4-tetrahydronaphthalene chromium tricarbonyl, naphthalene chromium tricarbonyl, anisole chromium tricarbonyl, N-methylaniline chromium tricarbonyl, o-toluidine chromium tricarbonyl, (methylbenzoate) chromium tricarbonyl, di-n-butylthiocarbamate nickel(II), n-butylamino[2,2′-thiobis(4-t-octyl)phenolate]nickel(II), n-butylamino[2,2′-thiobis(4-t-octyl)phenolate]cobalt(II), bis[2,2′-thiobis(4-t-octyl)phenolate]nickel(II), [2,2′-thiobis(4-t-octyl)phenolate]nickel(II) hydrate, [2,2′-thiobis(4-t-octyl)phenolate]nickel(II) ethylamine, bis(butyl-3,5-di-t-butyl-4-hydroxobenzylphosphonate) nickel(II), nickel chloride hexahydrate, cobalt chloride hexahydrate, manganese chloride tetrahydrate, di-n-butyldithiocarbamate cobalt(II), di-n-butyldithiocarbamate copper(II), diisopropyldithiophosphate nickel(II), diethyldithiophosphate palladium, diethyldithiophosphate platinum, tetrakispyridine iron(II) chloride, tetrakispyridine iron(II) bromide, tetrakisisoquinoline iron(II) chloride, tetrakisisoquinoline iron(II) bromide, tetrakisisoquinoline iron(II) iodide, tetrakispyridine iron(II) isocyanate, tetrakisβ-picoline iron(II) bromide, and tetrakis-γ-picoline iron(II) bromide.

The preferable transition metal complex comprises fourth period transition metals.

Specific examples of the preferable transition metal complex include α-methylferrocene methanol, titanium(III) chloride tetrahydrofuran complex, titanium(IV) chloride tetrahydrofuran complex, vanadium(III) chloride tetrahydrofuran complex, 1-butanethiol copper(I) salt, tetra(dimethylamino) titanium, tetra(diethylamino) titanium, thiophenol copper(I) salt, bis(1,5-cyclooctadiene) nickel(0), titanium(III) chloride ethyleneglycol dimethylether complex, nickel(II) bromide ethyleneglycol dimethylether complex, chromium(III) chloride tetrahydrofuran complex, Copper(I) bromide dimethylsulfide complex, tris(ethylenediamine) cobalt(II) choride dihydrate, bis(cis-1,2-diaminocyclohexane) nickel(II) chloride, titanium(IV) (triethanolaminato)isopropoxide, bis(tetraethylammonium)tetrabromo copper(II), bis(tetraethylammonium)tetrabromo manganese(II), bis(tetraethylammonium)tetrabromo manganese(II), Copper(II) acetylacetonate, titanium(IV) oxide acetylacetonate, vanadium(III) acetylacetonate, vanadylacetylacetonate, chromium(III) acetylacetonate, manganese(II) acetylacetonate, manganese(III) acetylacetonate, iron(III) acetylacetonate, cobalt(II) acetylacetonate, cobalt(III) acetylacetonate, nickel(II) acetylacetonate, titanium diisopropoxidebis(2,4-pentandionato), copper bis(2,2,6,6-tetramethyl-3,5-heptanedionato), nickel(II) bis(2,2,6,6-tetramethyl-3,5-heptanedionato), copper(II) trifluoroacetylacetonate, copper(II) hexafluoroacetylacetonate hydride, manganese(II) hexafluoroacetylacetonate trihydrate, cobalt(II) hexafluoroacetylacetonate hydrate, nickel(II) hexafluoroacetylacetonate hydrate, bis[3-(heptafluoropropylhydroxymethylene)-(+)-camphorate]oxovanadium, titanium(IV) bis(ammoniumlactate)dihydroxide, titanium(IV) bis(ethylacetoacetate)diisopropoxide, tetrakis(acetonitrile)copper(I) hexafluorophosphate, dichlorobis(tributylphosphine) nickel(II), dibromobis(tributylphosphine) nickel(II), iodo(trimethylphosphite) copper(I), iodo(triethylphosphite) copper(I), chloro(pyridine)bis(dimethylglyoximate) cobalt(III), bis(salicylaldehyde)cobalt(II) dihydrate, tris(benzoylmethanate) iron(III), tris(triphenylphosphine) copper(I) chloride, bis(triphenylphosphine) copper(I) nitrate, dichlorobis(triphenylphosphine) cobalt(II), chlorotris(triphenylphosphine) cobalt(I), tetrakis(triphenylphosphine) nickel(0), dichlorobis(triphenylphosphine)nickel(II), dibromobis(triphenylphosphine) nickel(II), [1,2-bis(triphenylphosphino)ethane]iron(II) chloride, [1,2-bis(diphenylphosphino)ethane]cobalt(II) chloride, [1,2-bis(diphenylphosphino)ethane]nickel(II) chloride, tetrakis(pyridine)cobalt(II) bis(chromate), tris(2,2′-bipyridine)iron(II) hexafluorophosphate, dichloro(1,10-phenanthroline) copper(II), dibromo(1,10-phenanthroline) copper(II), dinitrate (1,10-phenanthroline)copper(II), tris(1,10-phenanthroline) iron(II) hexafluorophosphate, tris(1,10-phenanthroline) iron(III) hex afluoropho sph ate, N,N′-bis(salicylidene)ethylenediamine cobalt(II), N,N′-bis(salicylidene)ethylenediamine nickel(II), bis(salicylideneininate-3-propyl)methylamino cobalt(II), (R,R)-(−)-N,N′-bis(3,5-di-t-butylsalicylidene)-1,2-cyclohexanediamino manganese(III) chloride, (S,S)-(+)-N,N′-bis(3,5-di-t-butylsalicylidene)-1,2-cyclohexanediamino manganese(III) chloride, N,N′-bis(salicylidene)dianilino cobalt(II), N,N′-bis(salicylidene)-1,2-phenylenediamino cobalt(III) monohydrate, tris(cyclopentadienyl)scandium, bis(cyclopentadienyl) vanadium, bis(cyclopentadienyl) chromium, ferrocene, ferrocenium hexafluorophosphate, ferrocenium hexafluoroborate, bis(cyclopentadienyl)cobalt, bis(cyclopentadienyl) nickel, cyclopentadienyl titanium trichloride, bis(cyclopentadienyl)titanium dichloride, bis(cyclopentadienyl) titanium pentasulfide, bis(cyclopentadienyl) titanium bis(trifluoromethanesulfonate), bis(cyclopentadienyl) vanadium dichloride, bis(pentamethylcyclopentadienyl) manganese, 1,1′-dimethylferrocene, bis(pentamethylcyclopentadienyl) iron, 1,2-deiferrocene ethane, butylferrocene, vinylferrocene, bis(2,4-cyclopentadiene-1-yl)[(4-methylbicyclo[2.2.1]heptane-2,3-diyl)methylene]titanium, ferrocene methanol, 1,1′-ferrocene dimethanol, (dimethylaminomethyl)ferrocene, (R)-(+)-N,N-dimethyl-l-ferrocenyl ethylamine, (S)-(−)-N,N-dimethyl-l-ferrocenyl ethylamine, ferrocene carboxyaldehyde, acetylferrocene, 1,1′-diacetylferrocene, ferrocene carboxylic acid, acetylferrocene, 1,1′-ferrocene dicarboxylic acid, dimethyl-1,1′-ferrocene dicarboxylate, 1,1″-[(4,4′-bipyperidine)-1,1′-diyldicarbonyl]bis[1′-(methoxyxarbonyl)ferrocene], ferrocene acetonitrile, benzoylferrocene, 1,1′-bis(diphenylphosphino)ferrocene, (−)-(R)—1-[(S)-2-(diphenylphosphino)ferrocenyl]ethylmethlether, (+)-(S)—1-[(R)-2-(diphenylphosphino)ferrocenyl]ethylmethylether, (−)-(R)-N,N-dimethyl-l-[(S)-2-(diphenylphosphino)ferrocenyl]ethylamine, (+)-(S)-N,N-dimethyl-1-[(S)-2-(diphenylphosphino)ferrocenyl]ethylamine, (−)-(R)-N,N-dimethyl-1-[(S)-1′,2-bis(diphenylphosphino)ferrocenyl]ethylamine, (+)-(S)-N,N-dimethyl-1-[(R)-1′,2-bis(diphneylphosphino)ferrocenyl]ethylamine, trans-4-[2-(1-ferrocenyl)vinyl]-1-methylpyridinium iodide, cyclohexadienyl iron(0) tricarbonyltetrafluoroborate, cycloheptatriene chromium tricarbonyl, cyclooctatetraene iron tricarbonyl, tricarbonyl(4-methoxy-1-methylhexadiene) iron tetrafluoroborate, tricarbonyl(2-methoxycyclohexadiene) iron tetrafluoroborate, tetramethylammonium(1-hydroxyethylidene)pentacarbonyl chromium, cyclopentadienyl manganese tricarbonyl, cycropentadienyl iron dicarbonyl iodide, cyclopentadienyl iron dicarbonyl dimer, cyclopentadienyl cobalt dicarbonyl, cyclopentadienyl nickel carbonyl dimer, (methylcyclopentadienyl)-manganese tricarbonyl, dicarbonyl cyclopentadienyl(dimethylsulfoniumethylide) iron tetrafluoroborate, benxene chromium tricarbonyl, mesitylene chromium tricarbonyl, 1,2,3,4-tetrahydronaphthalene chromium tricarbonyl, naphthalene chromium tricarbonyl, anisol chromium tricarbonyl, N-methylaniline chromium tricarbonyl, o-toluidine chromium tricarbonyl, (methylbenzoate) chromium tricarbonyl, di-n-butyldithiocarbamate nickel(II), n-butylamino[2,2′-thiobis(4-t-octyl)phenolate]nickel(II), n-butylamino[2,2′-thiobis(4-t-octyl)phenolate]cobalt(II), bis[2,2′-thiobis(4-t-octyl)phenolate]nickel(II), [2,2′-thiobis(4-t-octyl)phenolate]nickel(II) hydrate, [2,2′-thiobis(4-t-octyl)phenolate]nickel(II) ethylamine, bis(butyl-3,5-di-t-butyl-4-hydroxobenzylphosphate) nickel(II), nickel chloride hexahydrate, cobalt chloride hexahydrate, manganese chloride tetrahydrate, di-n-butyldithiocarbamate cobalt(II), di-n-butyldithiocarbamate copper(II), diiospropyldithiophosphate nickel(II), tetrakispyridine iron(II) chloride, tetrakispyridine iron(II) bromide, tetrakisisoquinoline iron(II) chloride, tetrakisisoquinoline iron(II) bromide, tetrakisisoquinoline iron(II) iodide, tetrakispyridine iron(II) isocyanate, tetrakis-, -picoline iron(II) bromide, and tetrakis-γ-picoline iron(II) bromide.

Divalent transition metal ions are more preferable. Specific examples of the divalent transition metal include α-methylferrocene methanol, nickel(II) bromide ethyleneglycol dimethylether complex, bis(cis-1,2-diaminocyclohexane) nickel(II) chloride, bis(tetraethylammonium)tetrabromo copper(II), bis(tetraethylammonium)tetrabromo manganese(II), bis(tetraethylammonium)tetrabromo cobalt(II), copper(II) acetylacetonate, manganese(II) acetylacetonate, cobalt(II) acetylacetonate, nickel(II) acetylacetonate, copper bis(2,2,6,6-tetramethyl-3,5-heptanedionato), nickel(II) bis(2,2,6,6-tetramethyl-3,5-heptanedionato), copper(II) trifluoroacetylactonate, copper(II) hexafluoroacetylactonate hydrate, manganese(II) hexafluoroacetylactonate trihydrate, cobalt(II) hexafluoroacetylactonate hydrate, nickel(II) hexafluoroacetylactonate hydrate, dichlorobis(tributylphosphine) nickel(II), dibromobis(tributylphosphine) nickel(II), bis(salicylaldehyde) cobalt(II) dihydrate, dichlorobis(triphenylphosphine) cobalt(II), dichlorobis(triphenylphosphine) nickel(II), dibromobis(triphenylphosphine) nickel(II), [1,2-bis(triphenylphosphino)ethane]iron(II) chloride, [1,2-bis(triphenylphosphino)ethane]cobalt(II) chloride, [1,2-bis(diphenylphosphino)ethane]nickel(II) chloride, tetrakis(pyridine) cobalt(II) bis(chromate), tris(2,2′-bipyridine)iron(II) hexafluorophosphate, dichloro(1,10-phenanthrolone) copper(II), dibromo(1,10-phenanthrolone) copper(II), dinitrate(1,10-phenanthrolone) copper(II), tris(1,10-phenanthrolone) iron (II) hexafluorophosphate, N,N′-bis(salicylidene)ethylenediamino cobalt(II), N,N′-bis(salicylidene)ethylenediamino nickel(II), bis(salicylideneiminate-3-propyl)methylamino cobalt(II), N,N′-bis(salicylidene)dianilino cobalt(II), N,N′-bis(salicylidene)-1,2-phenylenediamino cobalt(II) monohydrate, bis(cyclopentadienyl) vanadium, bis(cyclopentadienyl) chromium, ferrocene, bis(cyclopentadienyl) cobalt, bis(cyclopentadienyl)nickel, bis(pentamethylcyclopentadienyl) manganese, 1,1′-dimethylferrocene, bis(pentamethylcyclopentadienyl) iron, 1,2-deiferrocene ethane, butylferrocene, vinylferrocene, ferrocene methanol, 1,1-ferrocene dimethanol, (dimethylaminomethyl)ferrocene, (R)-(+)-N,N-dimethyl-1-ferrocenyl ethylamine, (S)-(−)-N,N-dimethyl-1-ferrocenyl ethylamine, ferrocene carboxyaldehyde, acetylferrocene, 1,1′-diacetylferrocene, ferrocene carboxylic acid, acetylferrocene, 1,1′-ferrocene dicarboxylic acid, dimethyl-1,1′-ferrocene dicarboxylate, 1,1″-[4,4′-bipiperidine]-1,1′-diyl dicarbonyl]bis[1′-(methoxycarbonyl)ferrocene], ferrocene acetonitrile, benzoylferrocene, 1,1′-bis(diphenylphosphino)fer (−)-(R)-1-[(S)-2-(diphenylphosphino)ferrocenyl]ethylmethyl ether, (+)-(S)-1-[(R)-2-(diphenylphosphino)ferrocenyl]ethylmethyl ether, (−)-(R)-N,N-dimethyl-1-[(S)-2-(diphenylphosphino)ferrocenyl]ethylamine, (+)-(S)-N,N-dimethyl-l-[(S)-2-(diphenylphosphino)ferrocenyl]ethylamine, (−)-(R)-N,N-dimethyl-1-[(S)-1′,2-bis(diphenylphosphino)ferrocenyl]ethylamine, (+)-(S)-N,N-dimethyl-1-[(R)-1′,2-bis(diphenylphosphino)ferrocenyl]ethylamine, trans-4-[2-(1-ferrocenyl)-vinyl]-1-methylpyridinium iodide, cycropentadienyl iron carbonyl iodide, cyclopentadienyl iron dicarbonyl dimer, di-n-butyldithiocarbamate nickel(II), n-butylamino[2,2′-thiobis(4-t-octyl)phanolate]nickel(II), n-butylamino[2,2′-thiobis(4-t-octyl)phanolate]cobalt(II), bis[2,2′-thiobis(4-t-octyl)phanolate]nickel(II), [2,2′-thiobis(4-t-octyl)phanolate]nickel(II) hydrate, [2,2′-thiobis(4-t-octyl)phanolate]nickel(II) ethylamine, bis(butyl-3,5-di-t-butyl-4-hydroxyobenzylphosphonate)nickel(II), nickel chloride hexahydrate, cobalt chloride hexahydrate, manganese chloride tetrahydrate, di-n-butyldithiocarbamate cobalt(II), di-n-butyldithiocarbamate copper(II), diiopropyl dithiophosphate nickel(II), tetrakispyridine iron(II) chloride, tetrakispyridine iron(II) bromide, tetrakisisoquinoline iron (II) chloride, tetrakisisoquinoline iron (II) bromide, tetrakisisoquinoline iron (II) iodide, tetrakispyridine iron (II) isocyanate, tetrakisβ-picoline iron(II) bromide, and tetrakisγ-picoline iron(II) bromide.

Transition metal complex in which the transition metal is Co²⁺and Ni²⁺is more preferable. Specific examples include nickel(II)bromide ethylene glycol dimethyl ether complex, bis(cis-1,2-diaminocyclohexane)nickel(II)chloride, bis(tetraethylammonium)tetrabromocobalt(II), cobalt(II)acetylacetonate, nickel(II)acetylacetonate, nickel(II)bis(2,2,6,6-tetramethyl-3,5-heptadionate), cobalt(II)hexafluoroacetylacetonate hydrate, nickel(II)hexafluoroacetylacetonate hydrate, dichlorobis(tributylphosphine)nickel(II), dibromobis(tributylphosphine)nickel(II), bis(salicylaldehyde)cobalt(II)dihydrate, dichlorobis(triphenylphosphine)cobalt(II), dichlorobis(triphenylphosphine)nickel(II), dibromobis(triphenylphosphine)nickel(II), [1,2-bis(diphenylphosphino)ethane]cobalt(II)chloride, [1,2-bis(diphenylphosphino)ethane]nickel(II)chloride, tetrakis(pyridine)cobalt(II)bis(chromate), N,N′-bis(salicylidene)ethylenediaminocobalt(II), N,N′-bis(salicylidene)ethylenediaminonickel(II), bis(salicylideneiminate-3-propyl)methylaminocobalt(II), N,N′-bis(salicylidene)dianilinocobalt(II), N,N′-bis(salicylidene)-1,2-phenylenediaminocobalt(II)hydrate, bis(cyclopentadienyl)cobalt, bis(cyclopentadienyl)nickel, di-n-butyldithiocarbamatenickel(II), n-butylamino[2,2′-thiobis(4-t-octyl)phenolate]nickel(II), n-butylamino[2,2′-thiobis(4-t-octyl)phenolate]cobalt(II), bis[2,2′-thiobis(4-t-octyl)phenolate]nickel(II), [2,2′-thiobis(4-t-octyl)phenolate]nickel(II)hydrate, [2,2′-thiobis(4-t-octyl)phenolate]nickel(II)ethylamine, bis(butyl-3,5-di-t-butyl-4-hydroxobenzylcarbonate)nickel(II), nickel chloride hexahydrate, cobalt chloride hexahydrate, di-n-butyldithiocarbamatecobalt(II), diisopropyldithiophosphatenickel(II) and the like.

Ligands not containing an aromatic ring therein are more preferably mentioned. Specific examples include nickel(II)bromide ethylene glycol dimethyl ether complex, bis(cis-1,2-diaminocyclohexane)nickel(II)chloride, bis(tetraethylammonium)tetrabromocobalt(II), cobalt(II)acetylacetonate, nickel(II)acetylacetonate, nickel(II) bis(2,2,6,6-tetramethyl-3,5-heptadionate), cobalt(II)hexafluoroacetylacetonate hydrate, nickel(II) hexafluoroacetylacetonate hydrate, dichlorobis(tributylphosphine)nickel(II), dibromobis(tributylphosphine)nickel(II), di-n-butyldithiocarbamatenickel(II), nickel chloride hexahydrate, cobalt chloride hexahydrate, di-n-butyldithiocarbamatecobalt(II), and diisopropyldithiophosphatenickel(II).

Among these, the particularly preferable transition metal complex is cobalt(II)acetylacetonate, cobalt(II)hexafluoroacetylacetonate hydrate, nickel(II)acetylacetonate, and di-n-butyldithiocarbamatenickel(II).

The most preferable transition metal complex is cobalt(II)acetylacetonate and cobalt(II)hexafluoroacetylacetonate hydrate. (D) Compound containing at least two functional groups having an unshared electron pair per molecule

The dye-containing curable composition of the invention comprises a compound containing at least two functional groups having an unshared electron pair per molecule (hereinafter, referred to as the component (D)). The component (D) is other than the components (A) to (C) or the additional component (E) described below such as an alkali-soluble binder, a monomer, a cross-linking agent, and an organic solvent. The component (D) can effectively improve stability of the dye-containing curable composition over time.

Examples of the functional groups having an unshared electron pair contained in the component (D) include those containing an oxygen atom, a nitrogen atom or a sulfur atom. Specific examples of the functional group include an alcoholic hydroxyl group, an ether group, a ketone group, a carboxyl group, an ester group, a carbonate group, a phenolic hydroxyl group, an amido group, an urethane group, an urea group, an amino group, a mercapto group, a thio ether group, a thio ester group, a thio amido group, a thio urea group, a dithio ester group, and a trithio carbonate group.

As the component (D), those containing at least two functional groups selected from among the above-mentioned functional groups such as a carboxyl group, an ester group, a carbonyl group, an alcoholic hydroxyl group, a phenolic hydroxyl group, an amido group, a mercapto group and a thio ether group are preferred, those containing at least two functional groups selected from a carboxyl group, a phenolic hydroxyl group and an amido group are more preferred, and those containing at least two carboxyl groups per molecule is even more preferred.

The component (D) having at least a ring structure per molecule is preferred. Examples of the ring structure include an aliphatic ring structure (alicyclic structure), and an aromatic ring structure. The ring structure may be monocyclic or polycyclic, and a hetero atom such as an oxygen atom, a nitrogen atom or a sulfur atom can be contained in the ring structure. The total number of carbon atoms to form a ring is usually 3 to 30, preferably 4 to 20, and more preferably 5 to 15. Specific examples of the ring structure include cyclobutane, cyclopentane, cyclohexane, [2.2.1]bicycloheptane (norbornane), and [2.2.2]bicyclooctane, adamantine.

The ring structure may further have a substituent at an arbitrary position. Examples of the substituent include a straight chained or branched alkyl group having 1 to 10 carbon atoms which may be substituted with a halogen atom, a halogen atom, a hydroxyl group, and an alkoxy group.

In this case, the functional group having an unshared electron pair may be contained in an atomic group which forms the ring structure, or may be substituted at an arbitrary position on the ring structure or in the substituent which is further substituted on the ring structure.

The molecular weight of the component (D) is usually 80 to 1500, preferably 100 to 1000, and more preferably 120 to 600. When the molecular weight is less than 80, the elution in the step of development after pattern exposure using the dye-containing curable compositions increases, and the pattern strength decreases. When the molecular weight is higher than 1500, the residue during development is increased and the resolution is deteriorated.

The boiling point of the component (D) is selected such that the component (D) is not vaporized by the heating (baking) process when coating the dye-containing curable composition on a substrate. Specifically, the boiling point of the component (D) is usually 180° C. or higher, preferably 200° C. or higher, and more preferably 250° C. or higher. When the boiling point is lower than 180° C., vaporization by baking during coating becomes remarkable, thus reducing the effect of the invention.

The reason why the component (D) can effectively improve the stability over time of the dye-containing curable composition is not clear. However, it can be assumed that by coordinating the component (D) with the transition metal in the component (C) or by interacting through positioning the component (D) in the vicinity of the transition metal, the component (C) servesas as a catalyst, and the decomposing reaction of each elemental material in the dye-containing curable composition is inhibited.

Based on the above assumption, there is a possibility that the stability constant (also known as the complexation constant) of the component (D) with the transition metal in the component (C) becomes important. The stability constant of the metal complex is described in detail in “Chemistry of Organic Metal Complex,” Kodansha Scientific (written by Yoshikazu Matsushima and Masao Hisatome) 2.7.

That is, the stability constant of a metal is equilibrium constant in the reaction between a ligand and a metal ion. The larger the stability constant of the ligand L with respect to the metal ion M, the easier it is to form a complex between the ligand L and the metal ion M. Further, in the case of polydendate ligand, depending on the coordination state (monodendate, bidendate, . . . , n-dendate), it is defined as the first stability constant, the second stability constant, . . . , the nₜₕ stability constant. The stability constant value between a ligand and a metal can be known by the database (SC-Database) complied by The Commission of Stability Constant (V6 Commission) of International Union of Pure and Applied Chemistry (IUPAC). Also, the value can be calculated through the experiment by the method described in “Chelate Chemistry (6): Experimental Chemistry of Complex [II]”, Nankodo, p.4.3-4.4.

The relationship between the effect of the invention, and the stability constant of the component (D) in the invention and the transition metal in the component (C), is not clear. However, the first stability constant of the component (D) and the transition metal of the component (C) is generally −2 to 17.

Preferable examples of the component (D) include the followings.

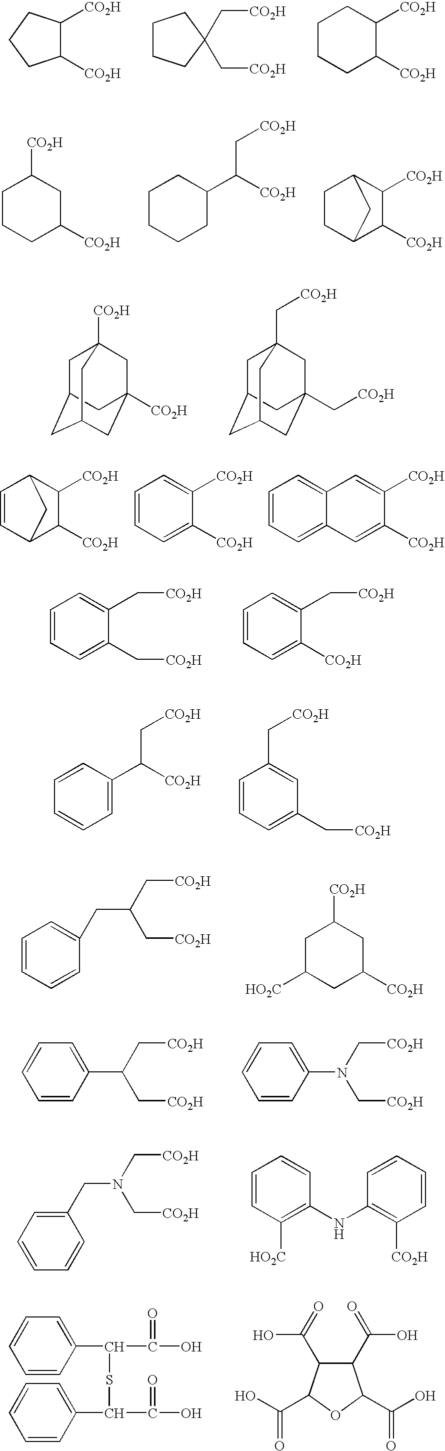

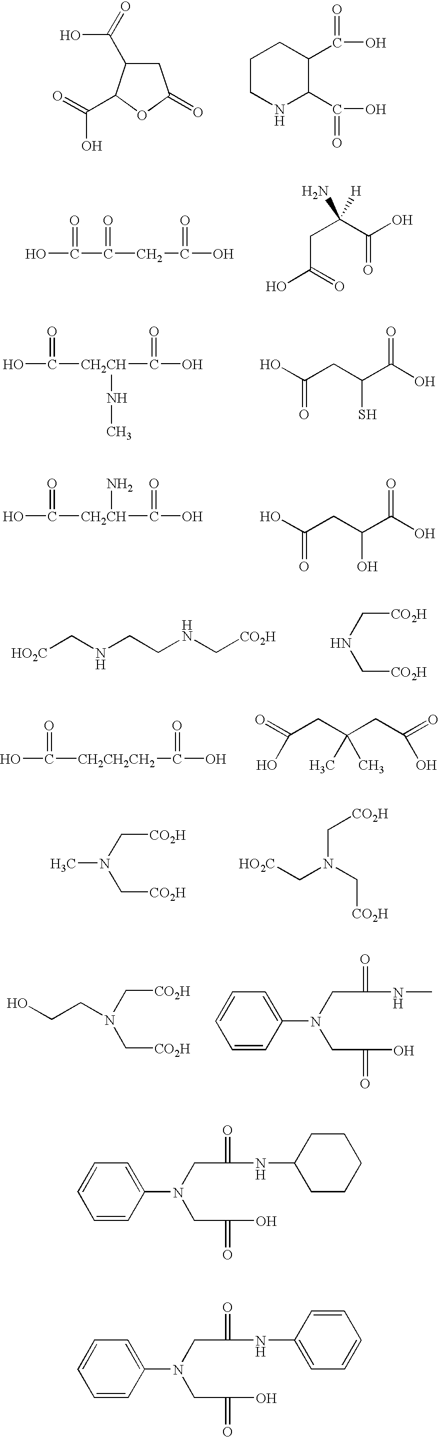

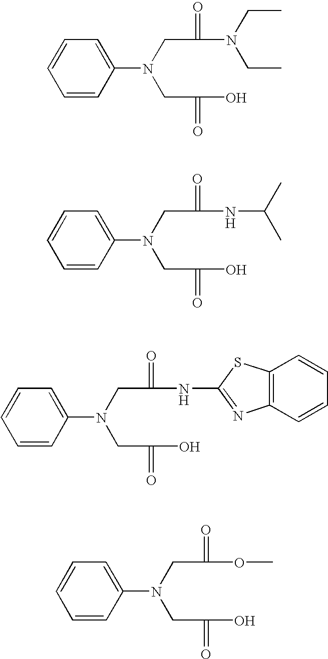

Other specific examples of the component (D) in addition to the above are mentioned, while the invention is not limited to these examples.

Other specific examples include thioglycolic acid, picolinic acid (pyridine 2-carboxylic acid), 3,5-dibromosalicylic acid, 1-hydroxy-2-naphtoic acid, N,N′-ethylene (dianthranilic acid), glycolic acid, diglycolic acid, 3-hydroxypropanoic acid, L-lactic acid, ascorbic acid (vitamin C), citric acid, mandelic acid, 2,4-dihydroxybenzoic acid, 3-hydroxypyridine, salicylic aldehyde, 2,3-dihydroxypyridine, 4-nitrocatechol, catechol, 3,4-dihydroxybenzene sulfonic acid, 3,5-dibromosalicylic acid, salicylic aldehyde, salicylic acid, salicylaldoxime, 8-hydroxyquinoline, 1-hydroxy-2-naphtoic acid, 2,4-dihydroxybenzaldehyde-2-hydroxy-4,6-dimethoxyacetphenone, glycine, alanine, methionine, arginine, phenyl alanine, cystein, asparatic acid, proline, histidine, piperidine-2,6-dicarboxylic acid, ethylenediamine tetracetic acid, N-(2-hydroxyethyl)ethylenediamine-N,N′,N″-triacetic acid, 2,3-butandione monoxime, 2,3-butandione dioxime, cyclohexan-1,2-dione dioxime, acetylacetone, hexafluoroacetylacetone, heptan-3,5-dione, anthranilic acid, and N-methylanthranilic acid.

The content of the component (D) in the dye-containing curable composition is preferably 0.1 to 40% by weight, more preferably 0.3 to 30% by weight, and particularly preferably 0.5 to 20% by weight based on the total solid content of the composition.

The molar ratio (D/C) of the component (D) and the component (C) is usually 0.1/1 to 100/1, preferably 0.2/1 to 50/1, and more preferably 0.4/1 to 30/1. (E) Alkali-soluble binder

The dye-containing curable composition of the invention comprises at least one alkali-soluble binder. The alkali-soluble binder used in the invention is not particularly restricted so long as it is soluble in an alkali. The alkali-soluble binder is preferably selected from the viewpoint of heat resistance, development ability and availability. The alkali-soluble binder will be described hereinafter.

The alkali-soluble binder is preferably a linear organic polymer, soluble in organic solvents, and is able to be developed with a weak aqueous alkali solution. Such linear organic polymers include polymers having carboxylic acids at the side chains. Examples of the polymer having carboxylic acids at the side chains include methacrylic acid copolymers, acrylic acid copolymers, itaconic acid copolymers, crotonic acid copolymers, maleic acid copolymers and partially esterified maleic acid copolymers as described in JP-A Nos. 59-44615, 59-53836 and 59-71048, and Japanese Patent Application Publication (JP-B) Nos. 54-34327, 58-12577 and 54-25957.

Otherwise, acidic cellulose derivatives having carboxylic acids at the side chains are preferable as the alkali-soluble binder.

Other preferable alkali-soluble binders include adducts of acid anhydrides to polymers having hydroxyl groups, polyhydroxystyrene resins, polysiloxane resins, poly(2-hydroxyethyl(meth)acrylate), polyvinyl pyrrolidone, polyethylene oxide and polyvinyl alcohol.

A Hydrophilic monomer may be copolymerized with the alkali-soluble binder. Examples of such monomer include alkoxyalkyl (meth)acrylate, hydroxyalkyl (meth)acrylate, glycerol (meth)acrylate, (meth)acrylamide, N-methylol acrylamide, secondary or tertiary alkyl acrylamide, dialkylaminoalkyl (meth)acrylate, morpholine (meth)acrylate, N-vinyl pyrrolidone, N-vinyl caprolactam, vinyl imidazole, vinyl triazole, methyl (meth)acrylate, ethyl (meth)acrylate, branched or linear propyl (meth)acrylate, branched or linear butyl (meth)acrylate, and phenoxyhydroxypropyl (meth)acrylate.

Other preferable hydrophilic monomers include those containing tetrahydrofurfulyl group, phosphate, phosphate ester, quaternary ammonium salt, ethyleneoxy chain, propyleneoxy chain, sulfonic acid group and salts thereof, and morpholinoethyl groups.

The alkali-soluble binder may have polymerizable groups at the side chain for improving the cross-linking efficiency when the dye-containing composition of the invention is structured as a negative working composition. Polymers having allyl group, (meth)acrylic or allyloxyalkyl groups at the side chains are also preferable. Examples of the polymer having such polymerizable group will be described below. The polymers having the polymerizable group are not restricted to those shown below, so long as they contain alkali soluble groups such as COOH, OH and ammonium groups, and carbon-carbon unsaturated bonds.

Specific examples of the polymer having the polymerizable group include a compound having an epoxy ring reactive to the OH group and carbon-carbon unsaturated double bonds (for example, glycidyl acrylate) to react with a copolymer of a compound having OH groups (for example 2-hydroxyethyl acrylate), a compound having COOH groups (for example methacrylic acid), and a monomer of an acrylic or a vinyl compound copolymerizable with these compounds.

The compounds having a group reactive to the OH group available include an epoxy ring as well as compounds having acid hydride, isocyanate group or acryloyl groups. A reaction product obtained by allowing a saturated or unsaturated polybasic acid anhydrate to react with a compound obtained by allowing an unsaturated carboxylic acid such as acrylic acid to react with a compound having an epoxy ring as disclosed in JP-A Nos. 6-102669 and 6-1938 may be also used.

Examples of the compound having the alkali soluble group such as COOH group and carbon-carbon unsaturated bond together include Dianal NR series (trade name) manufactured by Mitsubishi Rayon Co., Ltd., Photomer 6173 (trade name; COOH group containing polyurethane acrylic oligomer) manufactured by Diamond Shamrock Co., Ltd., Biscoat R-264 and KS Resist 106 (trade names) manufactured by Osaka Organic Chemical Industry Ltd., Cyclomer-P series and Plakcel CF200 series (trade names) manufactured by Daicel Chemical Industries, Ltd.), and Ebecry 13800 (trade name) manufactured by Daicel UBC Co., Ltd.

For constructing the dye-containing curable composition of the invention as a positive working composition, the alkali-soluble binder available include phenol-formaldehyde resin, cresol-formaldehyde resin, phenol-cresol-formaldehyde condensation resin, phenol modified xylene resin, copolymers of polyhydroxystyrene, polyhalogenated hydroxystyrene and N-(4-hydroxyphenyl)methacrylamide, and hydroquinone-monomethacrylate copolymers.

Other alkali-soluble binders include sulfonylimide polymers described in JP-A No. 7-28244, and carboxyl group containing polymers described in JP-A No. 7-36184. Various alkali-soluble polymer compounds such as acrylic resins having phenolic hydroxyl groups as described in JP-A No. 51-34711, acrylic resins having sulfonamide groups as described in JP-A No. 2-866, and urethane resins may be also used. These alkali-soluble binders may be used alone, or as a combination of two or more.

A resin in which the alkali soluble group is protected with an acid cleavable group may be used together with the photo-acid generator. This resin is a compound having a —C—O—C— or —C—O—Si—bond, and examples thereof include the following compound (a) to (i):

(a) a compound containing at least one selected from orthocarboxylic acid ester and carboxylic acid amide acetal, which is polymerizable, and having the group as a cross-linking element in the main chain or as a side chain substituent;

(b) an oligomer compound or a polymer compound containing a group selected from repeated acetal groups and ketal groups in the main chain;

(c) a compound containing at least one enol ester group or N-acylaminocarbonate group;

(d) cyclic acetal or ketal of β-ketoester or β-ketoamide;

(e) a compound containing silyether groups;

(f) a compound containing silylenol ether groups;

(g) monoacetal or monoketal having aldehyde or ketone components having a solubility of 0.1 to 100 g/liter in a developer;

(h) ether of tertiary alcohols; and

(i) carboxylate and carbonate of a tertiary allyl or benzyl alcohol.

The acid cleavable compounds in the (a) are described in German Patent Laid-Open (DE-A) Nos. 2,610,842 and 2,928,636. Mixtures containing the compounds in the (b) are described in DE-A Nos. 2,306,248 and 2,718,254. The compounds in the (c) are described in EP Laid-Open (EP-A) Nos. 0,006,626 and 0,006,627. The compounds in the (d) are described in EP-A No. 0,202,196. The compounds in the (e) are described in DE-A Nos. 3,544,165 and 3,601,264. The compounds in the (f) are described in DE-A Nos. 3,730,785 and 3,730,783. The compounds in the (g) are described in DE-A No. 3,730,783. The compounds in the (h) are described in U.S. Pat. No. 4,603,101. The compounds in the (i) are described in U.S. Pat. No. 4,491,628 and the report by M. Frechet et al. (J. Imaging Sci., 30, 59-64, 1986).

The content of these compounds protected with the acid cleavable groups in the dye-containing curable composition is usually I to 60% by mass, preferably 5 to 40% by mass, relative to the total solid content.

Polyhydroxystyrene resins, polysiloxane resins, acrylic resins, acrylamide resins and acrylic/acrylamide copolymer resins are preferable among these binders, and acrylic resins, polyhydroxystyrene resins and polysiloxane resins are more preferable from the viewpoint of heat resistance. The acrylic resins, acrylamide resins and acrylic/acrylamide copolymer resins are preferable from the viewpoint of development controlling ability.

The acrylic resins (binders that may contain polymerizable groups) are particularly preferable. Preferable examples of the acrylic resin include copolymers comprising the monomers selected from benzyl(meth)acrylate, (meth)acrylic acid, hydroxyethyl(meth)acrylate and (meth)acrylamide; Cyclomer P series and Prakcel CF200 series (manufactured by Daicel Chemical Industry Co.); Ebecryl 13800 (manufactured by Daicel UBC Co.); Dianal NR series (manufactured by Mitsubishi Rayon Co., Ltd.); and Biscoat R264 and KS Resist 106 (manufactured by Osaka Organic Chemical Industry Ltd.

The alkali-soluble binder is preferably polymers having a weight average molecular weight by of 1000 to 2×10⁵, more preferably polymer having an average molecular weight of 2000 to 1×10⁵, and particularly polymer having a average molecular weight of 5000 to 5×10⁴ measured by GPC and converted into polystyrene.

The content of the alkali-soluble binder in the dye-containing curable composition is preferably 0.5 to 90% by mass relative to the total solid content of the composition.

(F) Other Components

[Monomer]

The dye-containing curable composition of the invention suitably contains a monomer when the composition is constructed as a negative working composition. The monomer is preferably a compound comprising ethylenic unsaturated groups containing at least one ethylene group capable of addition polymerization and a boiling point of 100° C. or more at normal pressures. Examples of the monomer-containing compounds include monofunctional acrylate and methacrylate such as polyethyleneglycol mono(meth)acrylate, polypropyleneglycol mono(meth)acrylate, phenoxyethyl (meth)acrylate; (meth)acrylate compounds prepared after an addition reaction of ethylene oxide or propylene oxide to polyfunctional alcohols such as polyethyleneglycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl) isocyanulate, glycerine and trimethylolethane; urethane acrylates described in JP-B Nos. 48-41708 and 50-6034, and JP-A No. 51-37193; polyester acrylates described in JP-A No. 48-64183 and JP-B No. 49-43191 and 52-30490; polyfunctional acrylate and methacrylate of epoxyacrylate as a reaction product of an epoxy resin and (meth)acrylic acid; and mixtures thereof. The compounds described in Nihon Secchaku Kyokai-shi Vol. 20, No. 7, pp.300-308 as a photo-curable monomer and an oligomer are also included in the compounds of the invention.

In addition to the above, radical polymerizable monomers containing a carboxyl group such as the following formulas (VI-1) and (VI-2) can be preferably used. In the formulas (VI-1) and (VI-2), when T or G is an oxyalkylene group, the carbon atom end is bound to R, X and W.

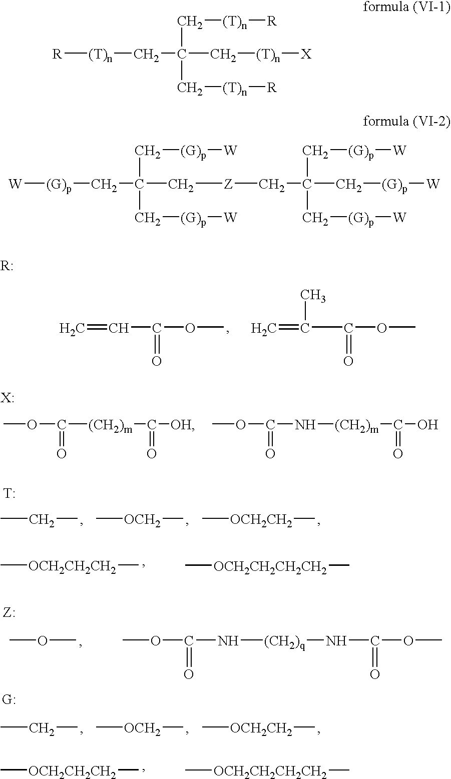

In the formula (VI-1), n is 0 to 14 and m is 1 to 8. In the formula (VI-2), W has the same definition as R or X of the formula (VI-1), and among the six W's, three or more W is R. p is 0 to 14 and q is 1 to 8. A plurality of R, X, T and G existing in a molecule are individually identical with or different from each other.

Among radical polymerizable monomers represented by the formulas (VI-1) or (VI-2), as specific examples, those represented by the following formulas (M-1) to (M-12) are preferred. Among these, the formula (M-2), the formula (M-3) and the formula (M-5) are preferred as radical polymerizable monomers.

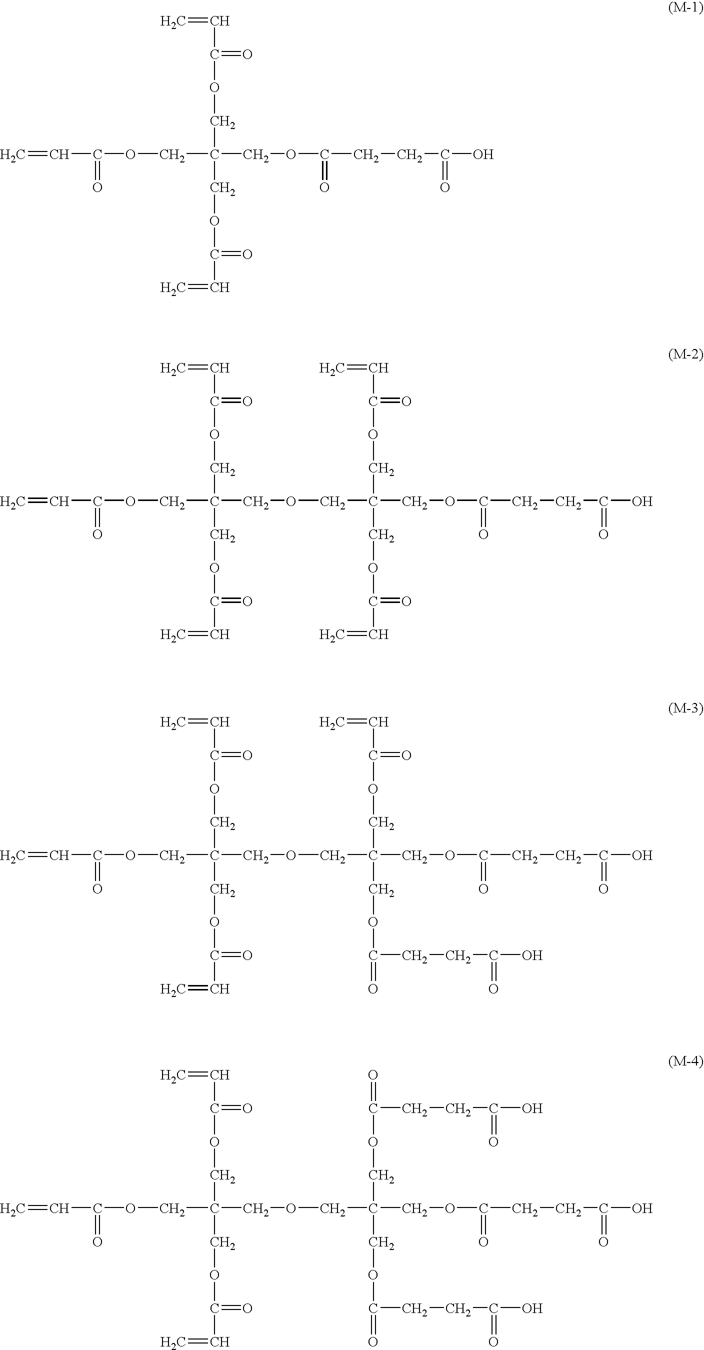

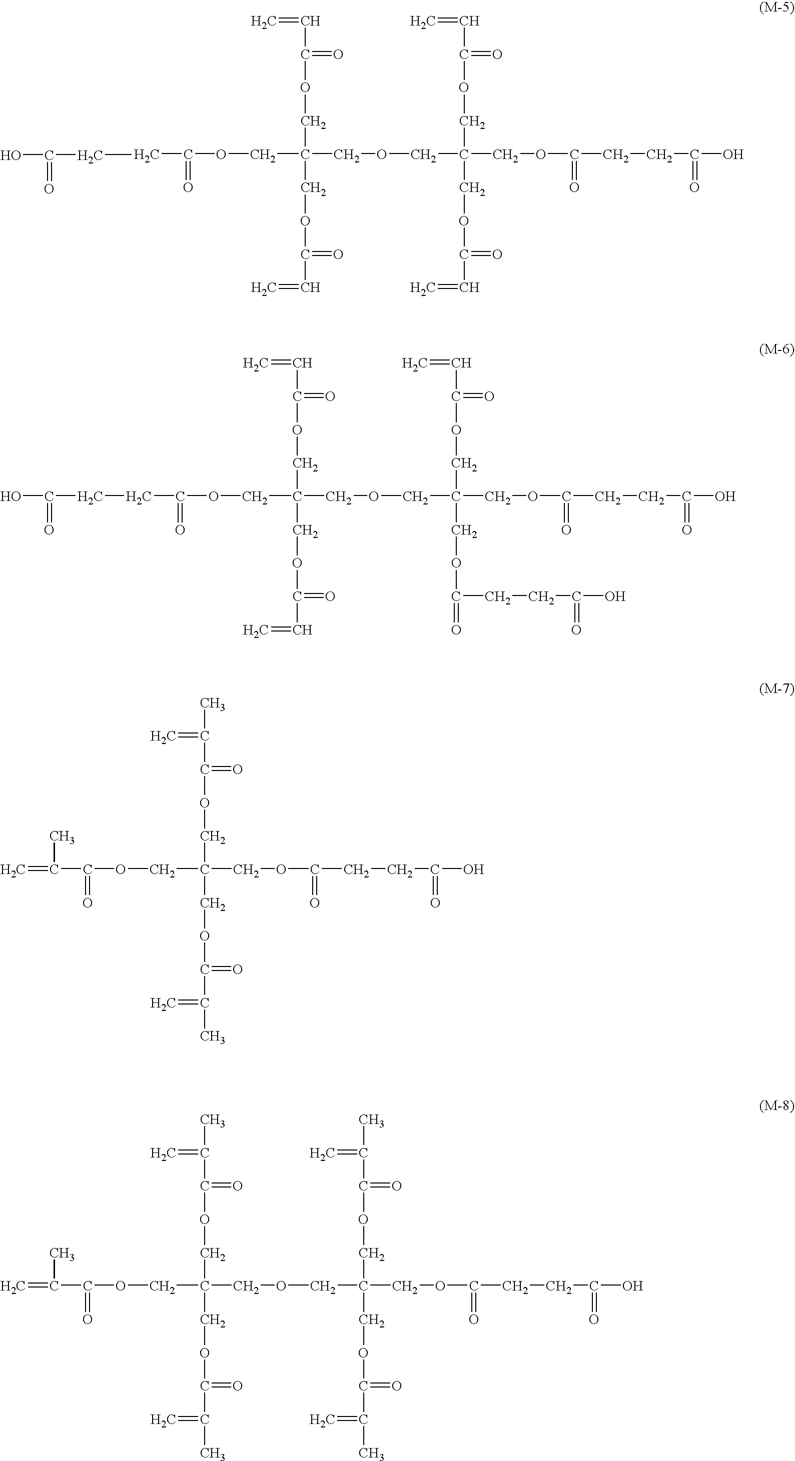

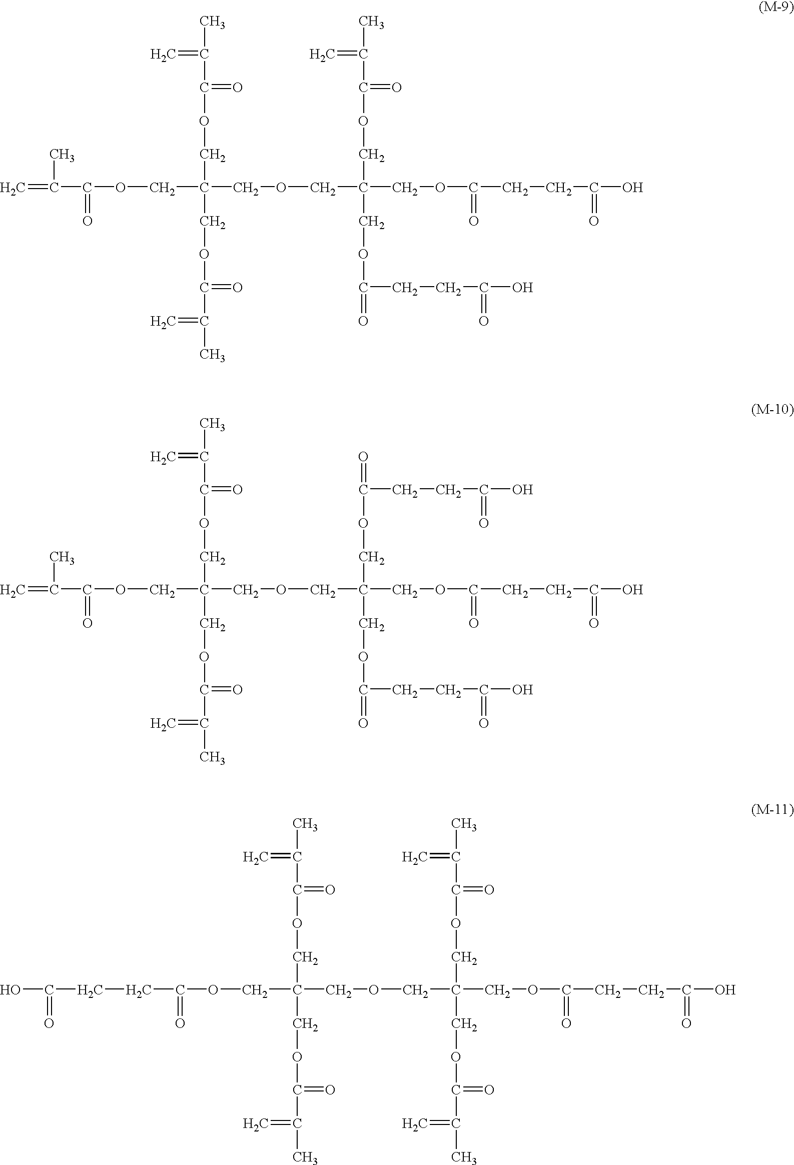

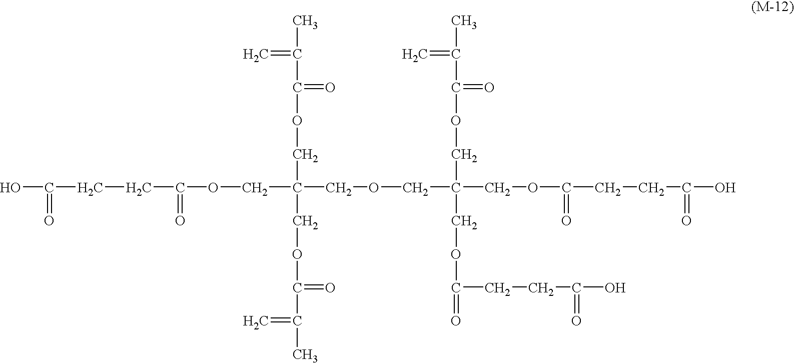

The content of the monomer in the dye-containing curable composition is preferably 0.1 to 90% by mass, more preferably 1.0 to 80% by mass, and particularly 2.0 to 70% by mass relative to the solid content of the composition.

[Cross-linking agent]

The hardness of a layer may be enhanced by using an auxiliary cross-linking agent in the invention. The cross-linking agent will be described below.

The cross-linking agent available in the invention is not particularly restricted, so long as it is able to cure the layer with the cross-linking agent, and examples of the cross-linking agent include (a) epoxy resins, (b) melamine compounds, guanamine compounds, glycoluryl compounds or urea compounds substituted with at least one substituent selected from methylol group, alkoxymethyl group and acyloxymethyl group, and (c) phenol compounds, naphthol compounds or hydroxyanthrathene compounds substituted with at least one substituent selected from methylol group, alkoxymethyl group and acyloxymethyl group. A multifunctional epoxy resins are particularly preferable.

Any resins may be used as the epoxy resin in the (a) so long as the resin comprises epoxy groups and has a cross-linking property. Examples of the epoxy resin include glycidyl group-containing divalent low molecular weight compounds such as bisphenol A diglycidyl ether, ethyleneglycol diglycidyl ether, butanediol diglycidyl ether, hexanediol diglycidyl ether, dihydroxybiphenyl diglycidyl ether, diglycidyl phthalate and N,N-glycidylaniline; glycidyl group-containing trivalent low molecular weight compounds represented by trivalent trimethylolpropane triglycidyl ether, trimethylolphenol triglycidyl ether and tris P-PA triglycidyl ether; glycidyl group-containing tetravalent low molecular weight compounds represented by pentaerythritol tetraglycidyl ether and tetramethylol bisphenol A tetraglycidyl ether; glycidyl group-containing polyvalent low molecular weight compounds such as dipentaerythritol pentaglycidyl ether and dipentaerythritol hexaglycidyl ether; and glycidyl group-containing high molecular weight compounds represented by polyglycidyl (meth)acrylate and 1,2-epoxy-4-(2-oxylanyl)cyclohexane adduct of 2,2-bis(hydroxymethyl)-1-butanol.

The numbers of the methylol groups, alkoxymethyl groups and acyloxymethyl groups substituting the melamine compounds in the (b) above are preferably 2 to 6, and the numbers of the groups above substituting the glycoluryl compounds, guanamine compounds and urea compounds, respectively, are preferably 2 to 4. More preferably, the numbers of the groups substituting the melamine compounds are 5 to 6, and the numbers of the groups substituting the glycoluryl compounds, guanamine compounds and urea compounds, respectively, are 3 to 4.

The melamine compounds, guanamine compounds, glycoluryl compounds and urea compounds are collectively named as the compounds according to (b) (methylol group-containing compounds, alkoxymethyl group-containing compounds or acyloxymethyl group-containing compounds) hereinafter.

The methylol group-containing compounds according to (b) can be obtained by heating the alkoxymethyl group-containing compounds according to (b) in an alcohol in the presence of an acid catalyst such as hydrochloric acid, sulfuric acid, nitric acid and methanesulfonic acid. The acyloxymethyl group-containing compounds according to (b) can be obtained by mixing acyl chloride with the methylol group-containing compounds according to (b) in the presence of a base catalyst.

Specific examples of the compounds according to (b) having the substituents above will be listed below.

Examples of the melamine compound include hexamethylol melamine, hexamethoxymethyl melamine and compounds having 1 to 5 methylol groups of hexamethylol melamine substituted with methoxymethyl groups, or a mixture thereof; and hexamethoxyethyl melamine, hexaacyloxymethyl melamine and compounds having 1 to 5 methylol groups of hexamethylol melamine substituted with acyloxymethyl groups, or a mixture thereof.

Examples of the guanamine compound include tetramethylol guanamine, tetramethoxymethyl guanamine and compounds having 1 to 3 methylol groups of tetramethylol guanamine substituted with methoxymethyl groups, or a mixture thereof; and tetramethoxyethyl guanamine, tetraacyloxymethyl guanamine and compounds having 1 to 3 methylol groups of tetramethylol guanamine substituted with acyloxymethyl groups, or a mixture thereof.

Examples of the glycoluryl compound include tetramethylol glycoluryl, tetramethoxymethyl glycoluryl and compounds having 1 to 3 methylol groups of tetramethylol glycoluryl substituted with methoxymethyl groups, or a mixture thereof; and compounds having 1 to 3 acyloxymethyl groups of tetramethylol glycoluryl substituted with acyloxymethyl groups, or a mixture thereof.

Examples of the urea compound include tetramethylol urea, tetramethoxymethyl urea and compounds having 1 to 3 methylol groups of tetramethylol urea substituted with methoxymethyl groups, or a mixture thereof; and tetramethoxyethyl urea.

The compounds according to (b) may be used alone, or as a combination thereof.

The compounds in the (c), that is, phenol compounds, naphthol compounds or hydroxyanthracene compounds substituted with at least one group selected from the methylol group, alkoxymethyl group and acyloxymethyl group can suppress inter-mixing of the curable resin composition with a overcoat photoresist by forming cross-links by heating as the case of the compounds in the (b), and the strength of the layer is enhanced. These compounds are collectively named as the compounds according to the (c) (methylol group-containing compounds, alkoxymethyl group-containing compounds or acyloxymethyl group-containing compounds).

At least two methylol groups, acyloxymethyl groups or alkoxymethyl groups should be contained per one molecule of the cross-linking agent in the (c). Compounds in which both the 2-position and 4-position of the phenol compound as a frame compound are substituted are preferable from the viewpoint of cross-linking ability by heating and preservation stability. Compounds in which both the ortho-position and para-position relative to the OH group of the naphthol compound or hydroxyanthracene compound as a frame compound are substituted are also preferable. The 3-position or 5-position of the phenol compound may be either substituted or unsubstituted.

Positions except the ortho-position relative to the OH group may be either substituted or unsubstituted in the naphthol compound.

The methylol group-containing compound according to the (c) may be obtained using a compound having a hydrogen atom at the ortho- or para-position (2- or 4-position) relative to the phenolic OH group as a starting material, and by allowing the material to react with formalin in the presence of a base catalyst such as sodium hydroxide, potassium hydroxide, ammonia or tetraalkylammonium hydroxide.

The alkoxymethyl group-containing compound according to the (c) may be obtained by heating the methylol group-containing compound according to the (c) in an alcohol in the presence of an acid catalyst such as hydrochloric acid, sulfuric acid, nitric acid or methanesulfonic acid.

The acyloxymethyl group-containing compound according to the (c) may be obtained by allowing the methylol group-containing compound according to the (c) to react with an acyl chloride in the presence of a base catalyst.

Examples of the frame compound of the cross-linking agent (c) include phenol, naphthol and hydroxyanthracene compounds in which the ortho- or para-position relative to the phenolic OH group is unsubstituted. Examples of the frame compound available include phenol, isomers of cresol, 2,3-xylenol, 2,5-xylenol, 3,4-xylenol, 3,5-xylenol, bisphenols such as bisphenol A, 4,4′-bishydroxybiohenyl, Tris P-PA (manufactured by Honshu Chemical Industry Co., Ltd.), naphthol, dihydroxynaphthalene and 2,7-dihydroxyanthracene.

Specific examples of the phenol compound or naphthol compound as the cross-linking agent (c) include trimethylolphneol, tri(methoxymethyl)phenol, and compounds having 1 to 2 methylol groups of trimethylol phenol substituted with methoxymethyl groups; trimethylol-3-cresol, tri(methoxymethyl)-3-cresol and compounds having 1 to 2 methylol groups of trimethylol-3-cresol substituted with methoxymethyl groups; dimethylcresol such as 2,6-dimethylol-4-cresol, tetramethylol bisphenol A, tetramethoxymethyl bisphenol A and compounds having 1 to 3 methylol groups of tetramethylol bisphenol A substituted with methoxymethyl groups; tetramethylol-4,4′-bishydroxybiphenyl, tetramethoxymethyl-4,4′-bishydroxybiphenyl, hexamethylol compounds of Tris P-PA, hexamethoxymethyl compounds of Tris P-PA, and compounds having 1 to 5 methylol groups of hexamethylol compound of Tris P-PA substituted with methoxymethyl groups; and bishydroxymethyl naphtalnediol.

Examples of the hydroxyanthracene compound include 1,6-dihydroxymethyl-2,7-dihydroxyanthracene.

Examples of the acyloxymethyl group-containing compound include methylol group-containing compounds in which a part or all the methylol groups are substituted with acyloxymethyl groups.

Preferable compounds among the compounds above include trimethylol phenol, bis hydroxymethyl-p-cresol, tetramethylol bisphenol A, and hexamethylol compounds of Tris P-PA (manufactured by Honshu Chemical Industry Co., Ltd.), or phenol compounds in which the methylol groups are substituted with the alkoxymethyl groups, and in which the methylol groups are substituted with both methylol groups and alkoxymethyl groups.

The compounds according to the (c) may be used alone, or as a combination thereof.

The cross-linking agent is not always contained in the curable composition according to the invention. The total content of the cross-linking agent, if any, according to (a) to (c) in the dye-containing curable composition is preferably 1 to 70% by mass, more preferably 5 to 50% by mass, and particularly 7 to 30% by mass, relative to the solid content (mass) of the curable composition, although the content differs depending on the materials used.

[Organic Solvent]

The dye-containing curable composition of the invention usually requires an organic solvent (simply referred to a solvent in the specification) for preparation. The solvent is not particularly restricted provided that it satisfies solubility of each component and coating ability of the dye-containing curable composition. The organic solvent is preferably selected considering solubility of the dye and alkali-soluble binder, coating ability and safety.

Examples of the preferable organic solvent include esters such as ethyl acetate, n-butyl acetate, isobutyl acetate, amyl formate, isoamyl acetate, butyl propionate, isopropyl butylate, ethyl butylate, butyl butylate, alkyl esters, methyl lactate, ethyl lactate, methyl oxylactate, ethyl oxylactate, butyl oxylactate, methyl methoxyacetate, ethyl methoxyacetate, butyl methoxyacetate, methyl ethoxyacetate, ethyl ethoxyacetate;
3-oxypropionic acid alkyl esters such as methyl 3-oxypropionate and ethyl 3-oxypropionate including methyl 3-methoxypropionate, ethyl 3-methoxypropionate, methyl 3-ethoxypropionate and ethyl 3-ethoxypropionate; 2-oxypropionic acid alkyl esters such as methyl 2-oxypropionate, ethyl 2-oxypropionate and propyl 2-oxypropionate including methyl 2-methoxypropyonate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate; methyl pyruvate, ethyl pyruvate, propyl pyruvate, methyl acetoacetate, ethyl acetoacetate, methyl 2-oxobutanate and ethyl 2-oxobutanate;
ethers such as diethyleneglycol dimethylether, tetrahydrofuran, ethyleneglycol monomethylether, ethyleneglycol monoethylether, methyl cellosolve acetate, ethyl cellosolve acetate, diethyleneglycol monomethylether, diethyleneglycol monoethylether, diethyleneglycol monobutylether, propyleneglycol methyl ether, propyleneglycol methylether acetate, propyleneglycol ethylether acetate, and propyleneglycol propylether acetate; ketones such as methylethyl ketone, cyclohexanone, 2-heptanone and 3-heptanone; and aromatic hydrocarbons such as toluene and xylene.

Methyl 3-ethoxypropionate, ethyl 3-ethoxypropionate, ethyl cellosolve acetate, ethyl lactate, diethyleneglycol dimethylether, butyl acetate, methyl 3-methoxypropionate, 2-heptanone, cyclohexanone, cyclopentanone, ethylcarbitol acetate, butylcarbitol acetate, propyleneglycol methylether and propyleneglycol methylether acetate are more preferable among them.

[Additives]

Various additives such as fillers, polymer compounds other than those above, surfactants, adherence enhancing agents, antioxidants, ultraviolet absorbing agents and antiflocculants may be added, if necessary, to the dye-containing curable composition of the invention.

Specific examples of the additives include fillers such as glass and alumina; polymer compounds other than the binding resins such as polyvinyl alcohol, polyacrylic acid, polyethyleneglycol monoalkylether and polyfluoroalkyl acrylate; surfactants such as nonionic, cationic and anionic surfactants; adherence enhancing agents such as vinyl trimethoxy silane, vinyl triethoxy silane, vinyl tris(2-methoxyethoxy)silane, N-(2-aminoethyl)-3-aminopropylmethylmetoxy silane, N-(2-aminoethyl)-3-aminopropyltrimethoxy silane, 3-aminopropyltriethoxy silane, 3-glycidoxypropyl trimethoxy silane, 3-glycidoxypropyl methyldimethoxy silane, 2-(3,4-epoxycyclohexyl)ethyl trimethoxy silane, 3-chloropropylmethyl dimethoxy silane, 3-chloropropyl trimethoxy silane, 3-methacryloxypropyl trimethoxy silane, and 3-mercaptopropyl trimethoxy silane; antioxidants such as 2,2-thiobis(4-methyl-6-t-butylphanol) and 2,6-di-t-butylphenol; ultraviolet absorbing agents such as 2-(3-t-butyl-5-methyl-2-hydroxydiphenyl)-5-chlorobenzotriazole and alkoxybenzophenone; and antiflocculants such as sodium polyacrylate.

Organic carboxylic acids, preferably low molecular weight organic carboxylic acids with a molecular weight of 1000 or less may be added for enhancing alkali solubility of non-cured parts to further improving development ability of the dye-containing curable composition of the invention.

Examples of the organic carboxylic acid include aliphatic monocarboxylic acids such as formic acid, acetic acid, propionic acid, butyric acid, valeric acid, pivalic acid, caproic acid, diethylacetic acid, enanthic acid and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimetylmalonic acid, methylsuccinic acid, tetramethylsuccinic acid and citraconic acid; aliphatic tricarboxylic acid such as tricarbailylic acid, aconitic acid and camphoronic acid; aromatic monocarboxylic acid such as benzoic acid, toluic acid, cuminic acid, hemelitic acid and mesitylenic acid; aromatic polycarboxylic acid such as phthalic acid, isophthalic acid, terephthalic acid, trimellitic acid, trimesic acid, mellophanic acid and pyromellitic acid; and other carboxylic acid such as phenylacetic acid, hydroatropic acid, hydrocinnamic acid, mandelic acid, phenylsuccinic acid, atropic acid, cinnamic acid, methyl cinnamate, benzyl cinnamate, cinnamilydenic acid, cumalic acid and umbelic acid.

Among the component (D), specific examples can include those having a carboxyl group.

The dye-containing curable composition of the invention may be suitably used for color filters used for liquid crystal displays (LCD) and solid state image pick-up elements (for example CCD and CMOS), for forming colored pixels such as electroluminescence color filters, and for preparing printing inks, ink-jet inks and paints.

Color Filter and Method of Producing thereof

The process of producing the color filter of the invention will be described in detail hereinafter.

The color filter can be suitably produced by using the dye-containing curable composition of the invention in the method of producing the color filter of the invention.

When the dye-containing curable composition of the invention is constructed as a negative working composition, a radiation-sensitive composition layer is formed by applying the negative working dye-containing curable composition on a substrate by a coating process such as rotation coating, drip coating and roll coating. Then, the layer is exposed through a given mask pattern followed by developing with a developer to consequently form a negative-type colored pattern (image forming step). A curing step may be applied, if necessary, for curing the colored pattern formed by either heating or exposure at least.

When the dye-containing curable composition of the invention is constructed as a positive working composition, a radiation-sensitive composition layer is formed by applying the positive working dye-containing curable composition on a substrate by a coating process such as rotation coating, flow casting coating and roll coating. Then, the layer is exposed through a given mask pattern followed by developing with a developer. Consequently, the colored pattern formed is cured by heating (post-baking) after forming a positive-type colored pattern (image forming step).

The negative-type color filter comprising desired hues may be prepared by repeating the plural times of the image forming steps (and curing step, if necessary) corresponding to the number of the hues. The positive-type color filter comprising desired hues may be prepared by repeating the plural times of the image forming steps and post-baking steps corresponding to the number of the hues.

Particularly preferable light or radiation used for the purpose above is an ultraviolet light such as g-ray, h-ray and i-ray.

Examples of the substrate include a soda glass, Pyrex (R) glass and quartz glass, which are used for a liquid crystal displays those on which a transparent conductive film is adhered, and the substrate of photoelectric conversion elements used for the imaging element such as, for example, a silicone substrate and complementary metal oxide film semiconductor (CMOS). Black stripes for isolating each pixel may be formed on these substrates.

An undercoat layer may be provided on the substrate for improving adhesive property to the upper layers, for preventing diffusion of substances, and for planarizing the surface of the substrate.

Any developers may be used so long as they comprise a composition that is able to dissolve non-cured portions of the dye-containing curable composition of the invention while the cured portions are left undissolved. Specifically, a combination of various organic solvents and an aqueous alkali solution may be used. The organic solvents used for preparing the dye-containing curable composition of the invention may be also used for the developer.

As the aqueous alkali solution, an aqueous alkali solution which dissolved an alkali compound in the concentration of 0.001 to 10% by weight (preferably 0.01 to 1% by weight) is preferred. Examples of the alkali compound include sodium hydroxide, potassium hydroxide, sodium carbonate, sodium silicate, sodium methanesilicate, ammonia water, ethylamine, diethylamine, dimethylethanolamine, tetramethylammonium hydroxide, tetraethylammonium hydroxide, choline, pyrrole, piperidine, and 1,8-diazabicyclo-[5.4.0]-7-undecene. When a developing solution prepared from such an aqueous alkali solution was used, generally after the development, the developing solution is washed with water.

The color filter of the invention can be used for the liquid crystal display (LCD) and solid state image pick-up element (for example CCD and CMOS). The color filter is suitable for a high resolution CCD element and CMOS having 1,000,000 pixels or more. The color filter of the invention may be used by disposing between the light-receiving part of the pixels constituting the CCD and micro-lenses for converging the light.

### EXAMPLES

Hereinbelow, the invention will be described in detail by way of Examples. However, the invention is not limited to these Examples as long as the scope of the invention is not impaired. Unless noted differently, the “part” is based on the weight.

(Examples 1 to 15 and Comparative Examples 1 to 2)

1) Preparation of resist solution

The compounds in the following composition were mixed and dissolved to prepare a resist solution.
Ethyl lactate: 75 parts
Binder: 7.0 parts

[benzylmethacrylate/methacrylic acid copolymer (=7/3 [molar ratio])]
Polymerization inhibitor (p-methoxyphenol): 0.005 part
Fluorine-based surfactant: 0.4 part

(F-78 1, manufactured by DAINIPPON INK AND CHEMICALS, INC.)
Dipentaerythritol hexaacrylate: 9.8 parts

(photopolymerizable compound)
Photopolymerization initiator (TAZ-107, manufactured by Midori kagaku Co., Ltd.): 1.2 parts

2) Production of undercoat layer-bearing glass substrate

A glass substrate (Corning 1737) was ultrasonic washed with an aqueous solution of 1% NaOH, and then washed with water and dehydration bake (200° C./30 minutes) was carried out. Next, the resist solution obtained in 1) was subjected to filtration using a filter. Then, on the glass substrate, which was washed, the resist solution was coated in the thickness of 2 μm using a spin coater and dried under heat at 220° C. for 1 hour to form a cured film (undercoat layer).

3) Production of a negative working dye-containing curable compositions N-1 to N-17

The elements presented in the following Table 1 (the amounts are listed in Table 1), 0.05 part of a fluorine-based surfactant (F-781, manufactured by DAINIPPON INK AND CHEMICALS, INC.) and 0.02 part of p-methoxyphenol (polymerization inhibitor) were dissolved in a mixture of 180 parts of propyleneglycol monomethyl ether acetate and 120 parts of cyclohexanone to produce the negative working dye-containing curable compositions N-1 to N-17.

4) Exposure and development of dye-containing curable composition (image forming process)

The dye-containing curable compositions N-1 to N-17 obtained in 3) were subjected to filtration using a filter, the filtered dye-containing curable compositions N-1 to N-17 were coated on the undercoat of the undercoat layer-bearing glass substrates obtained in 2) in the thickness of 1.3 μm using a spin coater, and then the glass substrates were pre-baked at 120° C. for 120 seconds.

Subsequently, by using an i-ray reduced projection exposure apparatus, the coated film was exposed at the wavelength of 365 nm through a mask with the linewidth of 2 μm while changing the exposure amount in every 100 mJ. After the exposure, the development was carried out under the conditions of 23° C. for 60 seconds using 60% CD-200 developing solution (manufactured by FUJI FILM Electronic Materials Co., Ltd.). Next, after rinsing with the flowing water for 20 seconds, the colored filter film (color filter) was obtained by spray drying. The image formation was confirmed by a typical method such as observation of an optical microscope and a SEM photograph.

5) Evaluation

With respect to the above-obtained dye-containing curable compositions N-1 to N-17, the evaluations on the rate of linewidth variability by changing the exposure amount and the rate of sensitivity variability by the duration time was carried out as in the following. The evaluation results are listed in the following Table 1.

1. Evaluation of the Rate of Linewidth Variability by Changing the Exposure Amount

The rate of linewidth variability was calculated by obtaining the exposure amount, in which the width between a dot and a space becomes 1:1 in the pattern with the width of 2 μm, as the adequate exposure amount (sensitivity), and increasing the exposure amount in every 100 mJ from the adequate exposure amount. Moreover, “||” in the following equation represents an absolute value.

Rate of linewidth variability (%)=|(linewidth* when changed in every 100 mJ from the adequate exposure amount)−(linewidth of the adequate exposure amount)|/(linewidth of the adequate exposure amount)×100
Here, between the linewidth of increasing in every 100 mJ from the adequate exposure amount and decreasing in every 100 mJ from the adequate exposure amount, the linewidth which was more deviated from the linewidth of the adequate exposure amount was used. The rate of linewidth variability with the smaller value showed good performances.
   2. Evaluation of the Rate of Sensitivity Variability by the Duration Time

The dye-containing curable compositions N-1 to N-17 obtained in 3) were stored at 25° C. for 2 weeks, and then coating, exposure, development and evaluation were carried out in the same manner. The exposure amount, in which the width between a dot and a space becomes 1:1 in the pattern with the width of 2 μm, as the sensitivity was obtained. Then, the rate of sensitivity variability by the duration time was calculated from the following equation. Moreover, “||” in the following equation represents an absolute value. The rate of sensitivity variability with the smaller value showed good performances.

Rate of sensitivity variability (%)=|(sensitivity after 2 weeks duration time)−(sensitivity with no duration time)|/(sensitivity with no duration time)×100

TABLE 1

| | | | | | | | | (B) | | (C) | | | | | |
|---|---|---|---|---|---|---|---|---|---|---|---|---|---|---|---|
| | | | | | | | | Radiation- | | Transition | | | | Rate of | Rate of |
| | | (E) | | | | (A) | | sensitive | | metal | | Component | | variation | variation |
| | | Binder | | Monomer | | Dye | | compound | | complex | | (D) | | in | in |
| | | | Added | | Added | | Added | | Added | | Added | | Added | linewidth | sensitivity |
| | No. | Name | amount | Name | amount | Name | amount | Name | amount | Name | amount | Name | amount | (%) | (%) |
| Example 1 | N-1 | E-1 | 9.02 | M-1 | 45.09 | A-1 | 30 | B-1 | 10.82 | C-1 | 2.5 | D-1 | 2.5 | 1.14 | 7.5 |
| Example 2 | N-2 | E-1 | 0 | M-1 | 40 | A-1 | 35 | B-1 | 11.5 | C-2 | 8.06 | D-2 | 5.37 | 1.12 | 7.1 |
| Example 3 | N-3 | E-1 | 4 | M-1 | 38 | A-1 | 36 | B-1 | 9.4 | C-3 | 5.01 | D-3 | 7.52 | 1.35 | 7.8 |
| Example 4 | N-4 | E-2 | 5 | M-1 | 35 | A-1 | 37 | B-1 | 11.3 | C-4 | 4.65 | D-4 | 6.98 | 1.1 | 6.9 |
| Example 5 | N-5 | E-1 | 5.5 | M-1 | 43 | A-2 | 30 | B-2 | 11.6 | C-5 | 5.9 | D-5 | 3.93 | 1.17 | 6.5 |
| Example 6 | N-6 | E-2 | 2.5 | M-1 | 39 | A-2 | 35 | B-2 | 11.5 | C-6 | 5.97 | D-6 | 5.97 | 1.37 | 7.7 |
| Example 7 | N-7 | E-1 | 0 | M-1 | 40 | A-2 | 38 | B-2 | 14 | C-7 | 4.76 | D-7 | 3.17 | 1.36 | 8.6 |
| Example 8 | N-8 | E-2 | 11.3 | M-1 | 35 | A-3 | 35 | B-2 | 15 | C-8 | 1.09 | D-8 | 2.54 | 1.48 | 9.7 |
| Example 9 | N-9 | E-2 | 8.5 | M-1 | 40 | A-3 | 35 | B-2 | 13.5 | C-9 | 1.47 | D-9 | 1.47 | 1.46 | 9.4 |
| Example 10 | N-10 | E-1 | 5 | M-1 | 34 | A-3 | 36 | B-3 | 10.7 | C-10 | 8.54 | D-2 | 5.69 | 1.11 | 7.2 |
| Example 11 | N-11 | E-2 | 0 | M-1 | 35 | A-4 | 18.5 | B-1 | 12.7 | C-1 | 0.45 | D-3 | 1.78 | 1.07 | 5.3 |
| | | | | | | A-5 | 11.5 | | | | | | | | |
| | | | | | | A-6 | 20 | | | | | | | | |
| Example 12 | N-12 | E-2 | 0 | M-1 | 33 | A-7 | 25.7 | B-1 | 13.5 | C-12 | 3.79 | D-4 | 4.64 | 1.01 | 5.4 |
| | | | | | | A-8 | 19.3 | | | | | | | | |
| Example 13 | N-13 | E-1 | 5.8 | M-1 | 38 | A-9 | 31.5 | B-4 | 9.7 | C-2 | 4.48 | D-5 | 10.45 | 1.15 | 6.3 |
| Example 14 | N-14 | E-2 | 0 | M-1 | 34 | B-10 | 28 | B-1 | 14.7 | C-2 | 6..0 | D-10 | 5.3 | 1.01 | 4.4 |
| | | | | | | B-11 | 12 | | | | | | | | |
| Example 15 | N-15 | E-2 | 0 | M-1 | 34 | B-12 | 28 | B-1 | 14.7 | C-2 | 6.0 | D-11 | 5.3 | 1.01 | 4.8 |
| | | | | | | B-13 | 12 | | | | | | | | |
| Comparative | N-16 | E-1 | 9.02 | M-1 | 45.09 | A-1 | 30 | B-1 | 10.82 | C-1 | 2.5 | D-1 | — | 5.67 | 64.5 |
| Example 1 | | | | | | | | | | | | | | | |
| Comparative | N-17 | E-1 | 9.022 | M-1 | 45.09 | A-1 | 30 | B-1 | 10.82 | C-1 | — | D-1 | 2.5 | 6.31 | 15.7 |
| Example 2 | | | | | | | | | | | | | | | |

(Unit of added amount: part)
(E) in the Table 1 is an alkali-soluble binder.
(A) in the Table 1 is an organic solvent-soluble dye.
(B) Radiation-sensitive compound in the Table 1 is a polymerization initiator.
The names in Table 1 are listed below.
E-1: allylmethacrylate/methacrylic acid copolymer (molar ratio: 50/50)
E-2: benzylmethacrylate/methacrylic acid copolymer (molar ratio: 70/30)
M-1: dipentaerythritol hexaacrylate (contains a partial pentaacrylate)
A-1: Valifast Yellow 1101
A-2: C. I. Acid Red 249
A-3: C. I. Acid Red 80
A-4: Acid Red 97
A-5: Solvent Orange 26
A-6: Solvent Yellow 14
A-7: Acid Yellow 74
A-8: Valifast Blue 2620
A-9: Solvent Blue 37

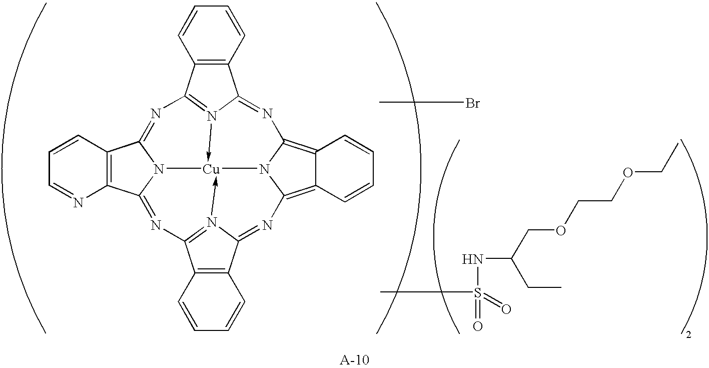

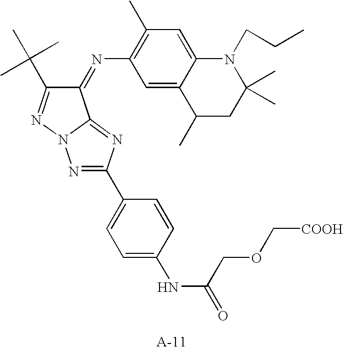

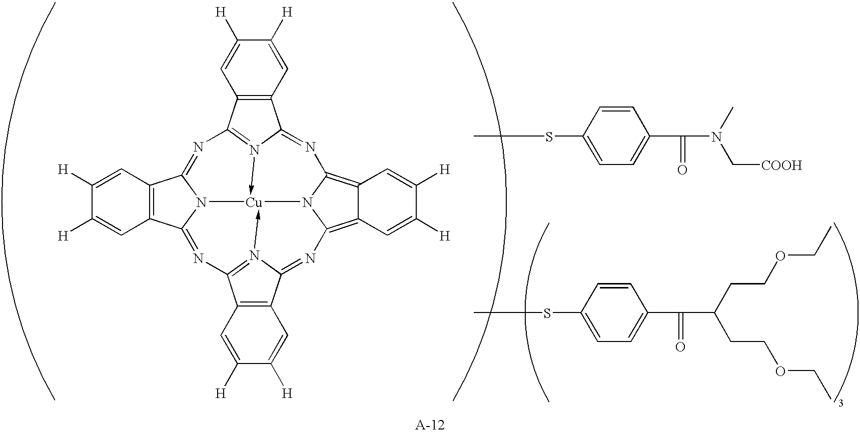

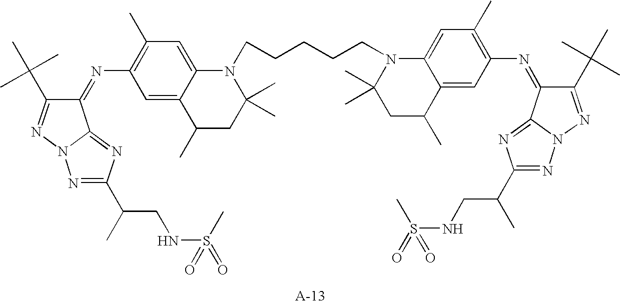

B-1: 2-(O-benzoyloxime)-1-[4-(phenylthio)phenyl -1,2-octandione (manufactured by Ciba Specialty Chemicals)
B-2: IRGACURE 369 (manufactured by Ciba Specialty Chemicals)
B-3: TAZ-107 (manufactured by Midori kagaku Co., Ltd.)
B-4: 1-(O-acetyloxime)-1-[9-ethyl-6-(2-methylbenzoyl)-9H-carbazol-3-yl]ethanone (manufactured by Ciba Specialty Chemicals)
C-1: Nickel (II) acetylacetonate
C-2: Cobalt (II) acetylacetonate
C-3: dichloroteetrakis(triphenylphosphine)ruthenium (II)
C-4: tris(triphenylphosphine)cupper (I) chloride
C-5: bis(cis-2-diaminocyclohexane)Nickel (II) chloride
C-6: ddi-n-butyldithiocarbamate cupper (II)
C-7: dichlorobis(triethylphosphine)palladium (II)
C-8: tetrakispyridine iron (II) bromide
C-9: tris(2,2′-bipyrridyl) ruthenium chloride hexahydrate
C-10: manganese chloride tetrahydrate
C-11: di-n-butyldithiocarbamate nickel (II)
C-12: Cobalt (II) hexafluoroacetonate hydrate
D-1: cyclohexyl succinate
D-2: cis-1,2-cyclohexane carboxylic acid
D-3: cis-5-norbornene-endo-2,3-dicarboxylic acid
D-4: 2,2′-iminodibenzoic acid
D-5: N-phenyliminodiacetic acid
D-6: picolinic acid
D-7: 1,2-phenylene diacetic acid
D-8: 22,3-dihydroxybenzoic acid
D-9: aspartic acid

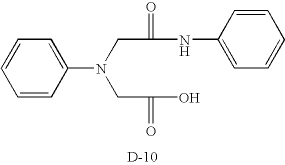

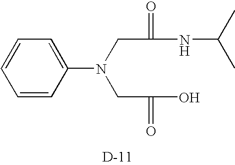

As shown in Table 1, the Examples which used the negative working dye-containing curable compositions N-1 to N-15 of the invention had low rates of variation in linewidth and variation in sensitivity. On the other hand, Comparative Examples which used the dye-containing curable compositions N-16 to N-17 had high rates of variation in linewidth and variation in sensitivity.

(Examples 16 to 18 and Comparative Examples 3 to 4)

6) Production of positive working dye-containing curable compositions P-1 to P-5

The elements presented in the following Table 2 (the amounts are listed in Table 2) and 0.05 part of a fluorine-based surfactant (F-781, manufactured by DAINIPPON INK AND CHEMICALS, INC.) were dissolved in a mixture of 180 parts of propyleneglycol monomethyl ether acetate and 120 parts of cyclohexanone to produce the positive working dye-containing curable compositions P-1 to P-5.

Then, the negative working dye-containing curable composition N-1 in Example 1 was substituted with the above-produced positive working dye-containing curable compositions P-1 to P-5. Also, the exposure wavelength was changed to 193 nm in the “4) Exposure and development of dye-containing curable composition (image forming process)”. Except for that, the formation of the colored filter film and the same evaluations. The evaluation results are presented in the following Table 2.

TABLE 2

| | | | | | (B) | | (C) | | | | | |
|---|---|---|---|---|---|---|---|---|---|---|---|---|
| | | | | | Radiation- | | Transition | | | | rate of | rate of |
| | (E) | | (A) | | sensitive | | metal | | Componeent | | variation | variation |
| | Binder | | Dye | | compound | | complex | | (D) | | in | in |
| | | Added | | Added | | Added | | Added | | Added | linewidth | sensitivity |
| No. | Name | amount | Name | amount | Name | amount | Name | amount | Name | amount | (%) | (%) |

| | | | | | | | | | | | | | |
|---|---|---|---|---|---|---|---|---|---|---|---|---|---|
| Example 16 | P-1 | PA-1 | 55 | A-9 | 24 | B-5 | 13 | C-1 | 4 | D-3 | 4 | 1.34 | 6.8 |
| Example 17 | P-2 | PA-1 | 50 | A-10 | 35 | B-5 | 10 | C-2 | 1.5 | D-4 | 3.5 | 1.29 | 7.5 |
| Example 18 | P-3 | PA-2 | 45 | A-11 | 28 | B-6 | 13 | C-12 | 5 | D-5 | 9 | 1.35 | 7.8 |
| Comparative | P-4 | PA-1 | 55 | A-9 | 24 | B-5 | 13 | C-1 | 4 | D-3 | — | 6.79 | 54.7 |
| Example 3 | | | | | | | | | | | | | |
| Comparative | P-5 | PA-1 | 55 | A-9 | 24 | B-5 | 13 | C-1 | — | D-3 | 4 | 7.85 | 23.5 |
| Example 4 | | | | | | | | | | | | | |

(Unitt of added amount: part)
(E) in the Table 2 is an alkali-soluble binder.
(A) in the Table 2 is an organic solvent-soluble dye.
The names in Table 2 are listed below.
PA-1:

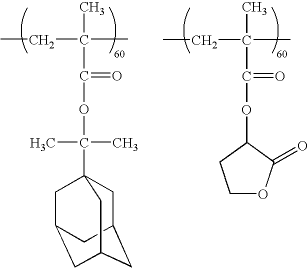

PA-2: benzylmethacrylate/methacrylic acid/methacrylic acid-2-hydroxyethyl copolymer (molar ratio: 60/30/10)
A-9: Solvent Blue 37
A-10: C. I. Acid Yellow 29
A-11: C. I. Acid Red 143
B-5:

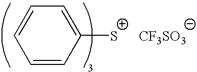

B-6: ester of 2,3,4-trihydroxybenzophenone and o-naphtoquinonediazide-5-sulfonyl chloride (esterification rate: 80 mol %;
quinonediazide compound)
C-1: Nickel (II) acetylacetonate
C-2: Cobalt (II) acetylacetonate
C-12: Cobalt (II) hexafluoroacetylacetonate hydrate
D-3: cis-5-norbornene-endo-2,3-dicarboxylic acid
D-4: 2,2′-iminodibeenzoic acid
D-5: N-phenyliminodiacetic acid

As shown in Table 2, the Examples which used the positive working dye-containing curable compositions P-1 to P-3 of the invention had low rates of variation in linewidth and variation in sensitivity. On the other hand, Comparative Examples which used the dye-containing curable compositions P-4 to P-5 had high rates of variation in linewidth and variation in sensitivity.

According to the invention, a dye-containing curable composition having a good stability over time and low rate of variation in the pattern linewidth due to fluctuation in exposure amounts, a color filter with excellent color hue and resolution, and a method of producing a color filter which has a high stability over time and a reduced rate of variation in pattern linewidth due to fluctuation in exposure amounts and which has good color hue and resolution, can be provided.

The invention includes embodiments listed below.

<1> A dye-containing curable composition comprising at least the following components (A) to (D).

(A) an organic solvent-soluble dye;

(B) a radiation-sensitive compound;

(C) a transition metal complex, wherein in the visible light range the maximum value of the molar absorption coefficient ε is lower than the maximum value of molar absorption coefficient ε of the organic solvent-soluble dye; and

(D) a compound other than the (A) to (C), containing at least two functional groups having an unshared electron pair per molecule.

<2> The dye-containing curable composition as described in <1>, wherein at least one of the functional groups having an unshared electron pair of the component (D) is selected from a carboxyl group, an ester group, a carbonyl group, an alcoholic hydroxyl group, a phenolic hydroxyl group, an amido group, a mercapto group or a thio ether group.

<3> The dye-containing curable composition as described in <1>, wherein the component (B) is a photopolymerization initiator and the dye-containing curable composition is a negative working composition.

<4> The dye-containing curable composition as described in <3>, wherein the photopolymerization initiator is at least a compound selected from the group consisting of (tri)halomethyltriazine compounds, oxime compounds and α-aminoketone compounds.

<5> The dye-containing curable composition as described in <1>, wherein at least one transition metal in the component (C) is Mn, Fe, Co, Ni or Cu.

<6> The dye-containing curable composition as described in <1>, wherein the content of the component (A) is 40% to 75% by weight based on the total solid content of the composition.

<7> The dye-containing curable composition as described in <1>, wherein at least one of the functional groups having an unshared electron pair of the component (D) is a carboxyl group.

<8> The dye-containing curable composition as described in <1>, wherein the component (D) is a compound having a morecular weight of 100 to 1000.

<9> The dye-containing curable composition as described in <1>, wherein the component (D) is a compound having at least one ring structure per molecule.

<10> The dye-containing curable composition as described in <1>, wherein the component (D) is a compound having at least two carboxyl groups per molecule.

<11> The dye-containing curable composition as described in <1>, wherein the component (C) is a transition metal complex of which the molecular weight of one ligand is 20 or more but less than 300.

<12> The dye-containing curable composition as described in <1>, wherein the component (A) is at least one selected from organic solvent-soluble dyes based on azos, azomethines, anthraquinones, anthrapyridones or phthalocyanines.

<13> The dye-containing curable composition as described in <1>, wherein the component (A) is at least one selected from organic solvent-soluble dyes based on phthalocyanines.

<14> The dye-containing curable composition as described in <1>, wherein the content of the component (A) is 45% to 70% by weight based on the total solid content of the composition.

<15> A color filter formed by using at least one dye-containing curable composition described in any one of <1>to <14>.

<16> A method of producing a color filter comprising:

coating the dye-containing curable composition described in any one of <1>to <14>on a support; then

exposing through a mask; and

developing to form a patterned image.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. A dye-containing curable composition comprising at least the following components (A) to (D):
(A) an organic solvent-soluble dye;
(B) a radiation-sensitive compound;
(C) a transition metal complex, wherein in the visible light range the maximum value of the molar absorption coefficient ε is lower than the maximum value of molar absorption coefficient ε of the organic solvent-soluble dye; and
(D) a compound other than the (A) to (C), containing at least two functional groups having an unshared electron pair per molecule.

2. The dye-containing curable composition of claim 1, wherein at least one of the functional groups having an unshared electron pair of the component (D) is selected from a carboxyl group, an ester group, a carbonyl group, an alcoholic hydroxyl group, a phenolic hydroxyl group, an amido group, a mercapto group or a thio ether group.

3. The dye-containing curable composition of claim 1, wherein at least one transition metal in the component (C) is Mn, Fe, Co, Ni or Cu.

4. The dye-containing curable composition of claim 1, wherein the component (D) is a compound having a morecular weight of 100 to 1000.

5. The dye-containing curable composition of claim 1, wherein the component (D) is a compound having at least one ring structure per molecule.

6. The dye-containing curable composition of claim 1, wherein the component (A) is at least one selected from organic solvent-soluble dyes based on azos, azomethines, anthraquinones, anthrapyridones or phthalocyanines.

7. A color filter formed by using the dye-containing curable composition according to claims 1.

8. A method of producing a color filter comprising:
coating the dye-containing curable composition according to claim 1 on a support; then
exposing through a mask; and
developing to form a patterned image.
